(19) United States
(12) Patent Application Publication
(10) Pub. No.: US 2017/0109667 A1
(43) Pub. Date: Apr. 20, 2017

(54) Automaton-Based Identification of Executions of a Business Process

(71) Applicant: Panaya Ltd., Hod Hasharon (IL)

(72) Inventors: Nir Marcu, Hod HaSharon (IL); Avichay Libeskind Mulyan, Tel Aviv (IL); Doron Tauber, Even Yehuda (IL); Shir Uziely, Raanana (IL); Alexandra Zhmudyak, Rehovot (IL); Nurit Dor, Raanana (IL)

(73) Assignee: Panaya Ltd., Hod Hasharon (IL)

(21) Appl. No.: 15/391,875

(22) Filed: Dec. 28, 2016

Related U.S. Application Data
(63) Continuation-in-part of application No. 15/067,225, filed on Mar. 11, 2016.
Application No. 15/067,225 is a continuation of application No. 14/141,514, filed on Dec. 27, 2013, now Pat. No. 9,317,404.
Application No. 14/141,514 is a continuation-in-part of application No. 13/103,078, filed on May 8, 2011, now Pat. No. 8,739,128.
(60) Provisional application No. 62/373,479, filed on Aug. 11, 2016.
(60) Provisional application No. 61/747,313, filed on Dec. 30, 2012.
(60) Provisional application No. 61/814,305, filed on Apr. 21, 2013.
(60) Provisional application No. 61/919,773, filed on Dec. 22, 2013.

(51) Int. Cl. G06Q 10/06; G06N 99/00; G06F 9/48; G06F 17/50

(52) U.S. Cl. CPC G06Q 10/067; G06F 17/5009; G06N 99/005; G06F 9/4843

(57) ABSTRACT

Described herein are systems, methods, and computer programs that may be utilized to identify a sequence corresponding to an execution of a Business Processes (BP) using an automaton. In one embodiment, a monitoring agent generates a stream of steps that were performed during interactions with an instance of a software system belonging to a certain organization, and a simulation module simulates a running of an automaton on an input comprising a sequence of steps. Optionally, parameters that define a behavior of the automaton are generated based on sequences of steps corresponding to executions of the BP associated with other organizations. Responsive to running the automaton on the stream, the automaton arrives at an accepting state at least once following a certain subsequence of steps that corresponds to a nonconsecutive execution of the BP, and the simulation module generates an indication indicative of a detection of an execution of the BP.

### CROSS-REFERENCE TO RELATED APPLICATIONS

This application claims priority to U.S. Provisional Patent Application No. 62/373,479, filed Aug. 11, 2016 that is herein incorporated by reference in its entirety. This application is also a Continuation-In-Part of U.S. application Ser. No. 15/067,225, filed Mar. 11, 2016 that is herein incorporated by reference in its entirety. U.S. Ser. No. 15/067,225 is a Continuation of application U.S. Ser. No. 14/141,514, filed Dec. 27, 2013, now U.S. Pat. No. 9,317,404 that is herein incorporated by reference in its entirety. U.S. Ser. No. 14/141,514 is a Continuation-In-Part of application U.S. Ser. No. 13/103,078, filed May 8, 2011, now U.S. Pat. No. 8,739,128. U.S. Ser. No. 14/141,514 claims priority to U.S. Provisional Patent Application No. 61/747,313, filed Dec. 30, 2012, and U.S. Provisional Patent Application No. 61/814,305, filed Apr. 21, 2013. U.S. Ser. No. 14/141,514 also claims priority to U.S. Provisional Patent Application No. 61/919,773, filed Dec. 22, 2013 that is herein incorporated by reference in its entirety.

### BACKGROUND

Analyzing Many organizations' activity may be viewed in the context of the Business Processes (BPs) they execute. However, a large organization's activity can be complex and involve many users that interact with large software systems, executing millions of transactions (or more) on a daily bases. With modern software systems, it is possible to collect through various forms of monitoring a lot of data describing steps performed as part of interactions with instances of software systems. Some examples data that may be collected through monitoring include logs generated by software systems, communications exchanged between clients and servers, and data extracted from user interfaces used to communicate with the software systems. However, interpreting this data can be a challenging task since it may not always be clear to which BPs various steps correspond. Thus, there is a need for a way to utilize data collected from monitoring an organization's activity in order to identify which BPs are executed by the organization in a systematic way.

### SUMMARY

Some aspects of this disclosure involve various applications involving data obtained by monitoring interactions with instances of one or more software systems. A “software system”, as used in this disclosure, may refer to one or more of various types of prepackaged business applications, such as enterprise resource planning (ERP), supply chain management (SCM), supplier relationship management (SRM), product lifecycle management (PLM), and customer relationship management (CRM), to name a few. Additionally, a “software system” may refer to a computer system with which a user and/or a computer program (e.g., a software agent) may communicate in order to receive and/or provide information, and/or in order to provide and/or receive a service.

In some embodiments, the monitoring is performed by one or more monitoring agents. Each monitoring agent generates a stream comprising steps performed as part of an interaction with an instance of a software system. Optionally, data collected through monitoring may include one or more of the following types of data: data provided by a user (e.g., as input in fields in screens), data provided by a software system (e.g., messages returned as a response to operations), data exchanged between a user interface and a server used to run an instance of a software system (e.g., network traffic between the two), logs generated by an operating system (e.g., on a client used by a user or a server used by an instance of a software system), and logs generated by the instance of the software system (e.g., “event logs” generated by the software system).

One aspects of this disclosure involve utilizing an automaton to identify executions of a BP in a stream of steps describing interactions with an instance of a software system. In some embodiments, the identification is done by simulating the running of the automaton on an input that includes the stream and/or candidate sequences selected from the stream. Optionally, an execution of the BP is identified when the automaton reaches an accepting state. Optionally, when given the stream as an input, the automaton reaches an accepting state at least once following a certain subsequence of the stream that corresponds to a nonconsecutive execution of the BP. For example, the certain subsequence may include both steps that are involved in the execution of the BP and steps that are not involved in it, such as steps that are involve in a different execution of the BP and/or steps involved in an execution of a different BP. In some embodiments, parameters that define the behavior of the automaton are generated based on examples comprising a positive set of sequences that correspond to executions of the BP and a negative set that comprises sequences of steps that do not correspond to executions of the BP.

Another aspect of this disclosure involves identifying executions of a BP by a certain organization utilizing an automaton generated based on data describing executions of the BP associated with other organizations. Herein, an execution of a BP is associated with an organization if at least one of the following statements is true: (i) at least some of the steps involved in the execution of the BP are performed by a user belonging to the organization, and (ii) at least some of the steps involved in the execution of the BP are executed on a certain instance of a software system belonging to the organization. By utilizing an automaton generated based on executions of other organizations, the certain organization may be able to benefit from certain knowledge of the other organizations (“crowd knowledge”) regarding what steps are involved in executing the BP. Such an automaton may be able to identify what is generally considered the essence of executing the BP (as determined based on how multiple other organizations execute the BP).

### BRIEF DESCRIPTION OF THE DRAWINGS

The embodiments are herein described by way of example only, with reference to the accompanying drawings. No attempt is made to show structural details of the embodiments in more detail than is necessary for a fundamental understanding of the embodiments. In the drawings:

FIG. 1 illustrates an embodiment of a system configured to identify executions of a Business Process (BP) utilizing a crowd-based model of the BP;

FIG. 2 illustrates an embodiment of a method for identifying executions of a BP utilizing a crowd-based model of the BP;

FIG. 3 illustrates an embodiment of a system configured to generate a model useful for identifying nonconsecutive executions of a certain BP;

FIG. 4 illustrates an embodiment of a method for generating a model useful for identifying nonconsecutive executions of a certain BP;

FIG. 5 illustrates an embodiment of a system configured to perform pattern-based identification of sequences corresponding to executions of Business Processes (BPs);

FIG. 6 illustrates an embodiment of a method for performing pattern-based identification of sequences corresponding to executions of a BPs;

FIG. 7 illustrates an embodiment of a system configured to utilize an automaton to identify a sequence corresponding to an execution of a BP;

FIG. 8 illustrates an embodiment of a method for utilizing an automaton to identify a sequence corresponding to an execution of a BP;

FIG. 9 illustrates an embodiment of a system configured to utilize a machine learning-based model to identify a sequence corresponding to an execution of a BP;

FIG. 10 illustrates an embodiment of a method for utilizing a machine learning-based model to identify a sequence corresponding to an execution of a BP;

FIG. 11 illustrates an embodiment of a system configured to perform an ensemble-based identification of sequences corresponding to executions of a BP;

FIG. 12 illustrates an embodiment of a method for performing an ensemble-based identification of sequences corresponding to executions of a BP;

FIG. 13 illustrates an example of linkage of nonconsecutively performed steps;

FIG. 14 illustrates an embodiment of a system configured to generate a model for linking between steps performed when executing a BP;

FIG. 15 illustrates an embodiment of a method for generating a (specific) model for linking between steps performed when executing a certain BP;

FIG. 16 illustrates an embodiment of a method for generating a general model for linking between steps performed when executing BPs;

FIG. 17 illustrates an embodiment of a system configured to generate candidate sequences of steps utilizing links between steps that are nonconsecutively performed;

FIG. 18 illustrates an embodiment of a method for generating candidate sequences of steps utilizing links between steps that are performed nonconsecutively;

FIG. 19 illustrates an embodiment of a system configured to extract a seed comprising steps common in executions of a BP and to utilize the seed to identify other executions of the BP;

FIG. 20 illustrates an embodiment of a method for extracting a seed comprising steps common in executions of a BP and utilizing the seed to identify other executions of the BP;

FIG. 21 illustrates some of the different monitoring agents that may be utilized in some of the embodiments described in this disclosure;

FIG. 22 illustrates an example of selection of sequences by the sequence parser module;

FIG. 23 illustrates an example of selection of sequences from multiple streams of steps by the sequence parser module;

FIG. 24a is a schematic illustration of selection of consecutively performed sequences of steps;

FIG. 24b is a schematic illustration of selection of a sequence comprising nonconsecutively performed steps from the same stream;

FIG. 24c is a schematic illustration of selection of a sequence comprising nonconsecutively performed steps from different streams; and

FIG. 25 is a schematic illustration of a computer that is able to realize one or more of the embodiments discussed herein.

### DETAILED DESCRIPTION

Following are descriptions of various embodiments of systems in which data is collected from monitoring interactions with instances of one or more software systems in order to create a model of a BP based on sequences of steps corresponding to executions of the BP, which are described in the data.

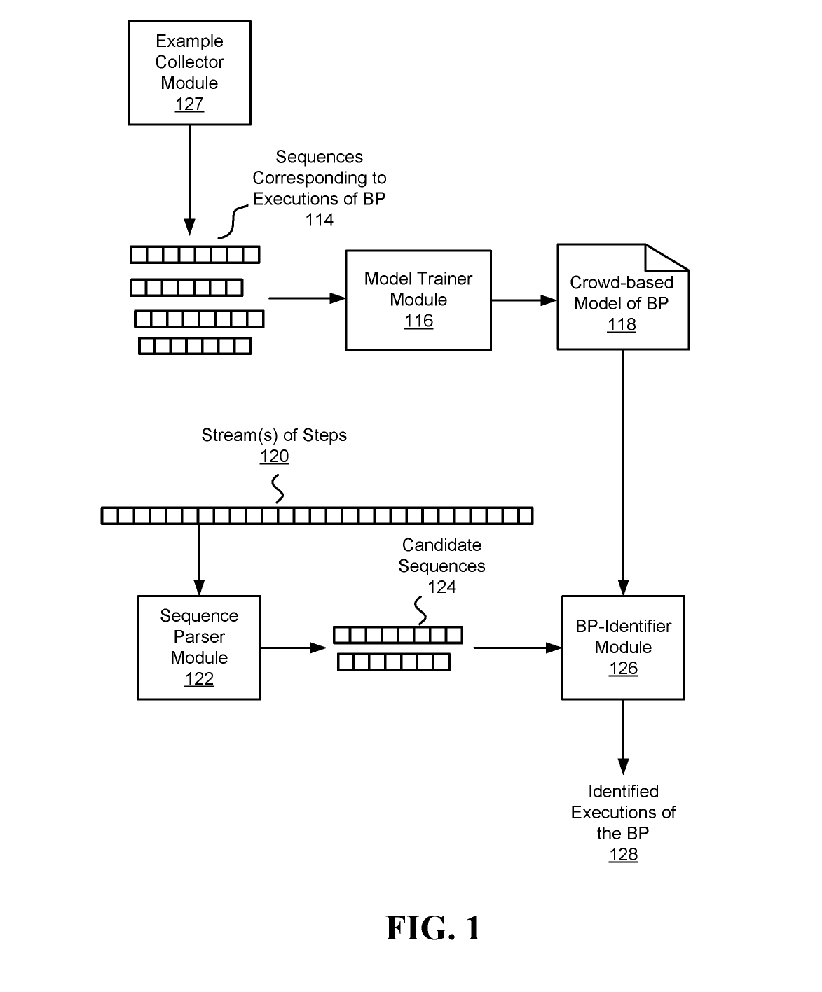

FIG. 1 illustrates one embodiment of a system configured to identify executions of a BP utilizing a crowd-based model of the BP. The system includes at least the following modules: sequence parser module 122, BP model trainer module 116, and BP-identifier module 126. The embodiment illustrated in FIG. 1, as other systems described in this disclosure, may be realized utilizing a computer, such as the computer 400, which includes at least a memory 402 and a processor 401. The memory 402 stores code of computer executable modules, such as the modules described above, and the processor 401 executes the code of the computer executable modules stored in the memory 402.

The BP model trainer module 116 is configured, in one embodiment, to receive sequences 114 of steps selected from among streams of steps performed during interactions with instances of one or more software systems, with each sequence corresponding to an execution of the BP. A discussion about the various types of software systems that may be interacted with in embodiments described in this disclosure is provided at least in Section 1—Software Systems.

In one embodiment, the sequences 114 include sequences corresponding to executions of the BP, which are associated with a plurality of organizations. For example, the sequences include first and second sequences corresponding to executions of the BP, which are associated with first and second organizations, respectively. Herein, an execution of a BP is considered to be associated with an organization if at least one of the following statements is true: (i) at least some of the steps involved in the execution of the BP are performed by a user belonging to the organization, and (ii) at least some of the steps involved in the execution of the BP are executed on a certain instance of a software system belonging to the organization. Additional information regarding organizations is provided in this disclosure at least in Section 2—Organizations.

In some embodiments, a step belonging to a stream comprising steps performed as part of an interaction with an instance of a software system describes one or more of the following aspects of the interaction: a certain transaction that is executed, a certain program that is executed, a certain screen that is displayed during the interaction, a certain form that is accessed during the interaction, a certain field that is accessed during the interaction, a certain value entered in a field belonging to a form, a certain operation performed from within a form, and a certain message returned by the software system during the interaction or following the interaction. Additional information regarding steps and generation of streams of steps may be found in this disclosure at least in Section 4—Streams and Steps.

The BP model trainer module 116 is further configured, in one embodiment, to generate crowd-based model 118 of the BP based on the sequences 114. Optionally, the crowd-based model 118 comprises a pattern describing a sequence of steps involved in the execution of the BP. Additionally or alternatively, the crowd-based model 118 may include a graphical representation (graph) such as a Petri net or a depiction of a Business Process Modeling Notation (BPMN) model.

In some embodiments, the BP model trainer module 116 may be further configured to receive additional sequences of steps, which do not correspond to executions of the BP, and to generate the crowd-based model 118 based on the additional sequences. These additional sequences may be useful for generation of various types of models.

In one example, the BP model trainer module 116 may be further configured to generate, based on the sequences 114 and the additional sequences, an automaton configured to recognize an execution of the BP based on a sequence of steps. In this example, the crowd-based model 118 may include parameters that govern the behavior of the automaton.

In another example, the BP model trainer module 116 may be further configured to utilize a machine learning training algorithm to generate the crowd-based model 118 of the BP based on the sequences 114 and the additional sequences. In this example, the crowd-based model 118 may include parameters used by a machine learning-based predictor configured to receive feature values determined based on a sequence of steps and to calculate a value indicative of a probability that the sequence of steps represents an execution of the BP. Optionally, the machine learning-based predictor may implement one or more of the following machine learning algorithms: decision trees, random forests, support vector machines, neural networks, logistic regression, and a naïve Bayes classifier.

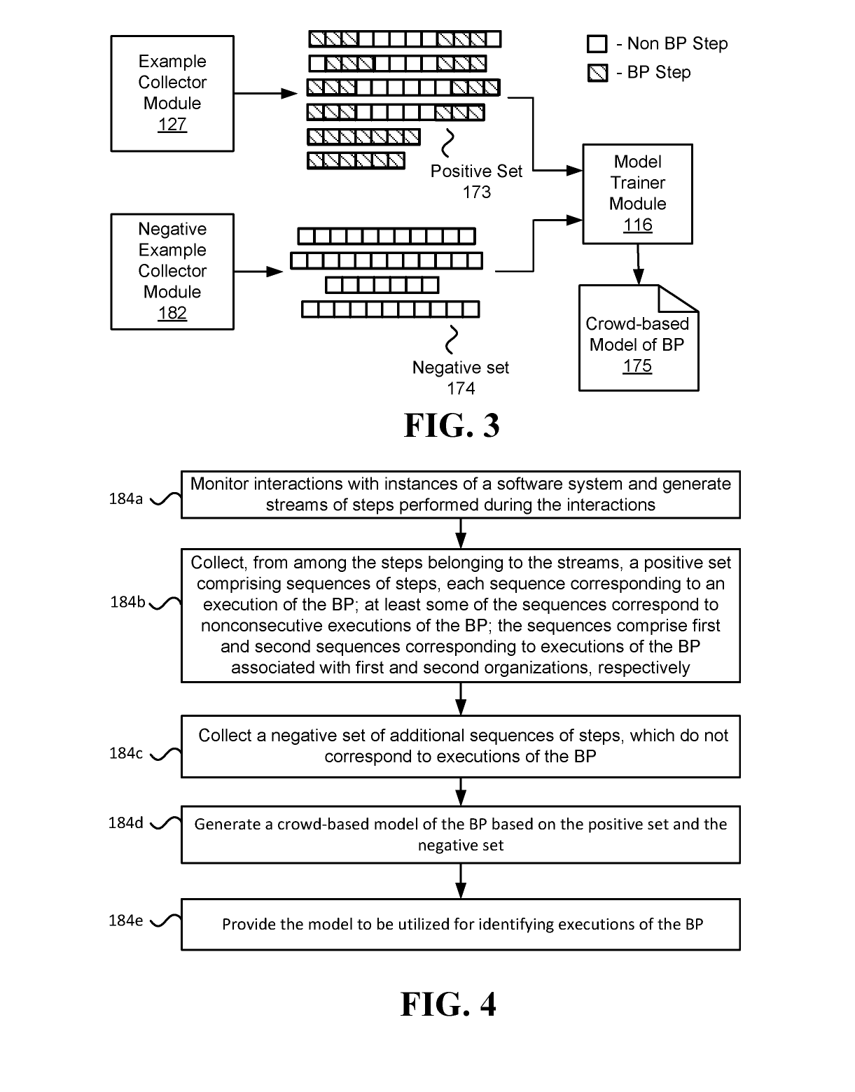

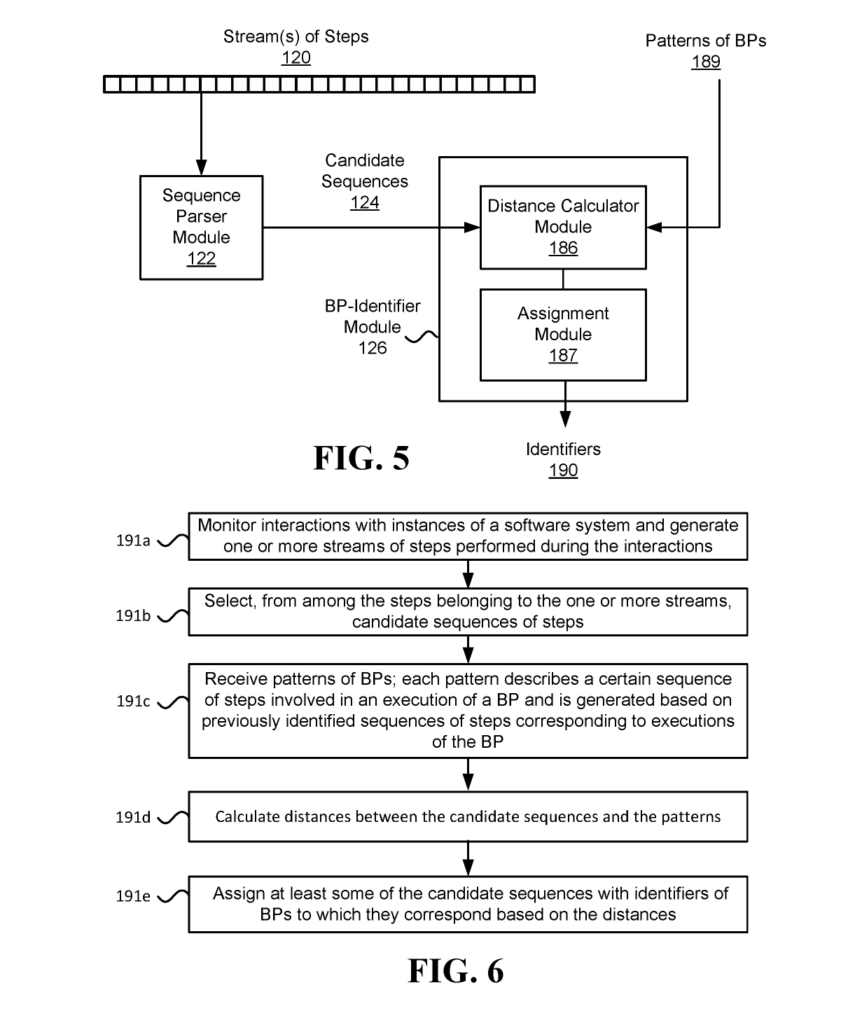

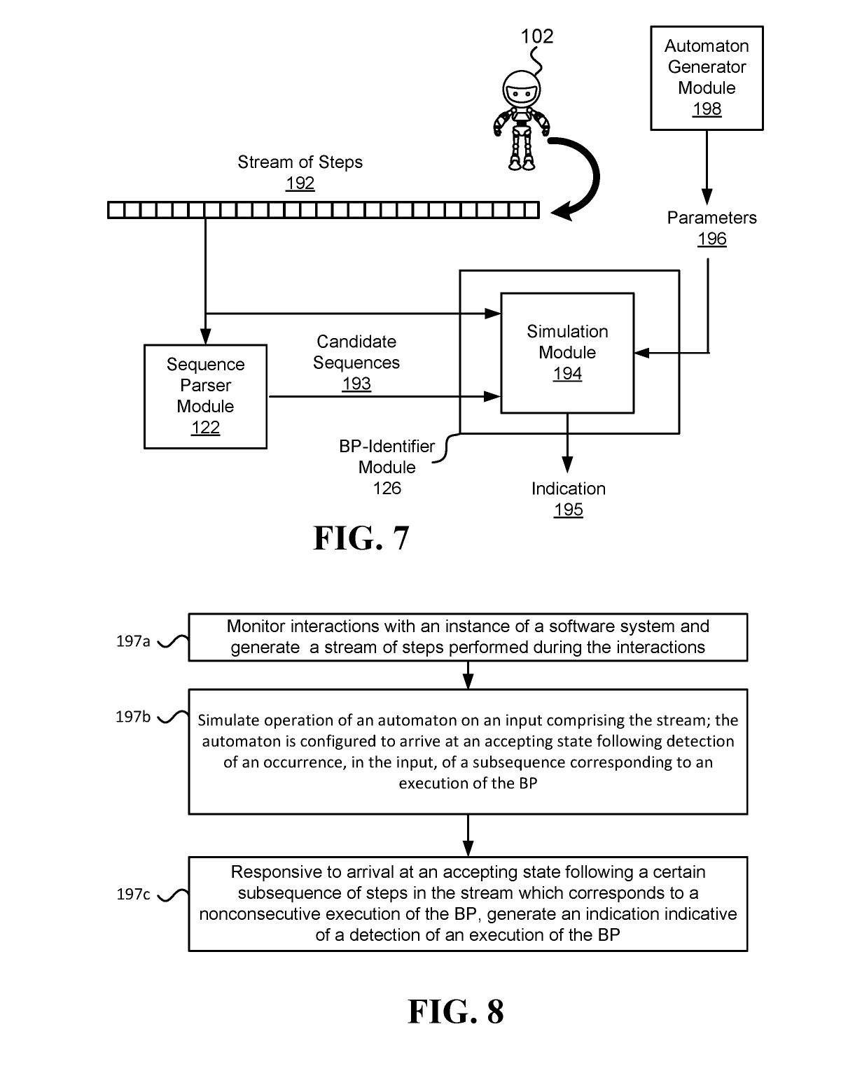

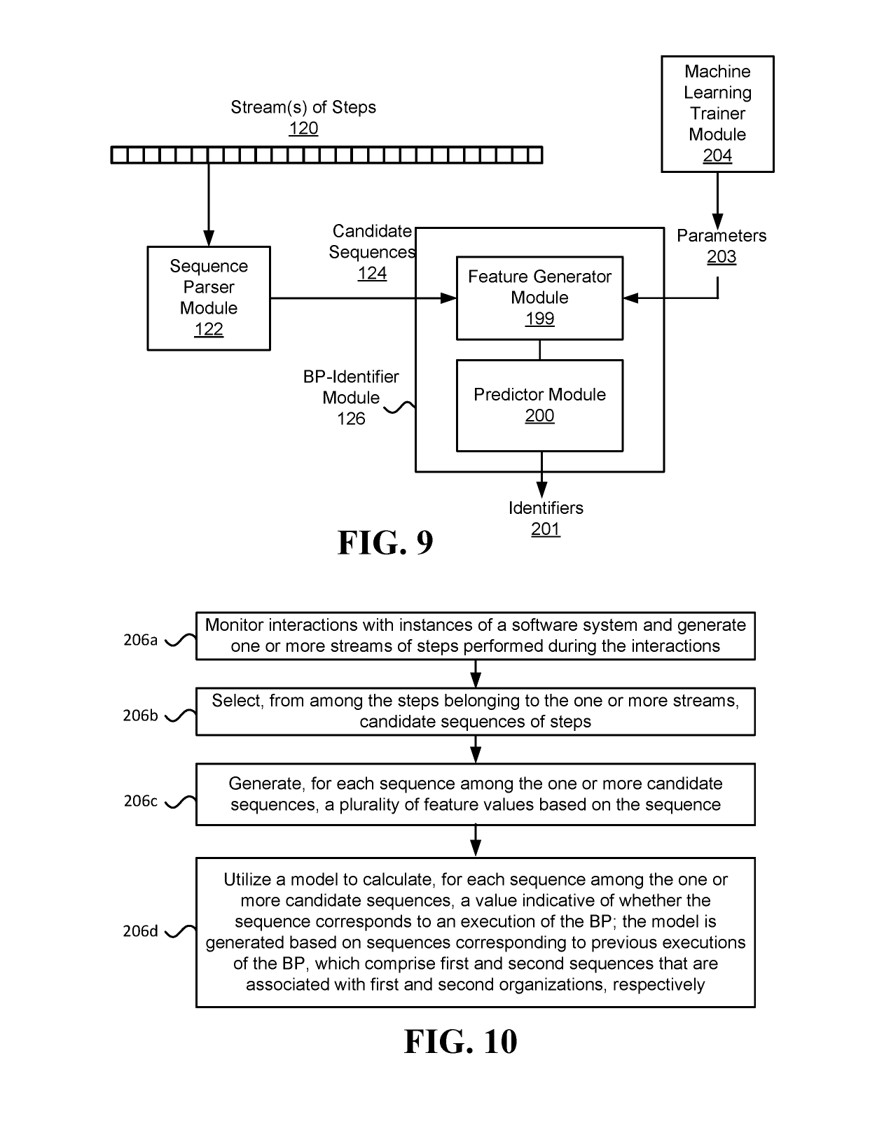

Additional discussion regarding generation of models of BPs based on sequences of steps corresponding to executions of the BPs may be found in this disclosure at least in Section 6—Models of BPs, and in the discussion regarding certain embodiments illustrated in FIG. 3, FIG. 5, FIG. 7, and FIG. 9.

The sequence parser module 122 is configured to receive one or more streams of steps and to select from among the one or more streams, sequences of steps. In one embodiment, the sequence parser module 122 is configured to receive the one or more streams 120 of steps performed during interactions with an instance of a software system, which in this embodiment, belongs to a third organization, and to select, from among the one or more streams 120, candidate sequences 124 of steps. Optionally, the one or more streams of steps may comprise at least two streams of steps, which include a certain first stream of steps performed during interactions with an instance of a first software system and a certain second stream of steps performed during interactions with an instance of a second software system, which is different from the first software system. Optionally, the candidate sequences 124 are forwarded to the BP-identifier module 126 for the purpose of identifying executions of the BP. Additionally or alternatively, the sequence parser module 122 may be utilized to select at least some of the sequences 114, and in particular, the sequence parser module 122 may be utilized to select the first and second sequences from among steps belonging to first and second streams, mentioned further above. Additional discussion regarding selecting sequences by the sequence parser module 122 is given further below and also may be found in this disclosure at least in Section 5—Selecting Sequences from Streams.

It is to be noted that a sequence of steps that is provided for identification of which BP it corresponds to (if any) may be referred to herein as a “candidate sequence”. This term is used purely for convenience in order to allude to a certain purpose of selected sequences; however, it is not meant to imply that identification of corresponding BPs is the only use for candidate sequences.

Additionally, it is to be noted that depending on how they were selected, the sequences 114 may include some sequences that include only consecutively performed steps and/or or some sequences that include some nonconsecutively performed steps. In one example, the first sequence includes at least some nonconsecutively performed steps. In this example, the first sequence comprises a first step directly followed by a second step, the first stream comprises a third step that appears between the first and second step, but the third step does not belong to the first and second streams.

The BP-identifier module 126 is configured to utilize the crowd-based model 118 to identify, from among the candidate sequences 124, one or more sequences of steps that correspond to executions 128 of the BP. Optionally, most of the candidate sequences 124 are not identified as corresponding to executions of the BP. Optionally, at least some of the identified sequences comprise only steps the correspond to the an execution of the BP. Optionally, at least some of the identified sequences may comprise some steps that do not correspond to an execution of the BP, and as such, those sequences may be considered corresponding to nonconsecutive executions of the BP (which are discussed in more detail further below).

In one embodiment, identifying a sequence as corresponding to an execution of the BP involves calculating a value indicative of a distance between the sequence and a pattern from the model 118, which describes a reference sequence of steps corresponding to an execution of the BP. Optionally, a sequence is identified as corresponding to the execution of the BP if the distance between the sequence and the reference sequence described by the pattern reaches a threshold. Optionally, the distance is calculated using a sequence alignment algorithm such as pairwise trace alignment described in Bose, et al. “Trace alignment in process mining: opportunities for process diagnostics”, International Conference on Business Process Management, Springer Berlin Heidelberg, 2010.

In another embodiment, identifying a sequence as corresponding to an execution of a BP involves finding a path in a graphical representation of the BP (e.g., a BPMN model) included in the model 118. Optionally, the BP-identifier module 126 provides a description of a path in the graph (from among a plurality of possible paths) to which the sequence corresponds.

In yet another embodiment, identifying a sequence as corresponding to an execution of the BP involves providing the sequence as an input to an automaton whose parameters are described in the model 118. Optionally, the result of miming the automaton on the sequence is indicative of whether the sequence corresponds to an execution of the BP (e.g., the sequence corresponds to an execution of the BP if the automaton reaches an accepting state).

In still another embodiment, identifying a sequence as corresponding to an execution of a BP involves generating feature values based on the sequence, and utilizing the model 118 to calculate, based on the feature values, a value indicative of whether the sequence corresponds to an execution of the BP. Optionally, in this embodiment, the model 118 includes parameters of a machine learning-based model that is utilize for calculating the value.

Some of the embodiments described herein involve evaluating the candidate sequences separately. However, when sequences of steps are represented as symbols, then the BP-identifier module 126 may utilize various efficient techniques known in the art that involve string matching to rapidly identify, from among the candidate sequences 124, sequences corresponding to executions of BPs. In one embodiment, the candidate sequences 124 are stored in a data structure that allows a rapid determination of presence and/or absence of a certain string (e.g., a hash table or a suffix tree). Thus, even a very large number of candidate sequences may be searched quickly to determine which of them match a sequence corresponding to a pattern of a BP. This approach may be extended to enable identification of candidate sequences that are similar, but not necessarily identical, to a sequence corresponding to a pattern of a BP. For example, the BP-identifier module 126 may utilize various approximate string-matching algorithms to identify the sequences corresponding to executions of BPs. Examples of such algorithms are discussed in detail in Navarro, G. “A guided tour to approximate string matching”, in ACM computing surveys (CSUR) 33.1 (2001): 31-88. In one example, the BP-identifier module 126 may store candidate sequences in a suffix tree and efficiently detect sequences corresponding to executions of BPs using the approaches discussed in Ukkonen, E. “Approximate string-matching over suffix trees”, in Annual Symposium on Combinatorial Pattern Matching, Springer Berlin Heidelberg, 1993.

Data describing interactions with an instance of a software system (e.g., the one or more streams 120) may be obtained, in some embodiments, utilizing one or more monitoring agents. Each monitoring agent generates a stream comprising steps performed as part of an interaction with an instance of a software system. Optionally, a monitoring agent that generates the stream is implemented, at least in part, via a program that is executed by an additional processor that belongs to at least one of the following machines: a client that provides a user with a user interface via which a user interacts with an instance, and a server upon which the instance runs. Monitoring agents may be of various types in different embodiments, as described in the examples below. A more comprehensive discussion regarding monitoring agents and the data they examine/produce may be found in this disclosure at least in Section 3—Monitoring Activity.

In one embodiment, the one or more monitoring agents comprise an internal monitoring agent. Optionally, a user executes a packaged application on an instance of a software system, and the internal monitoring agent monitors interactions between the user and the instance. Optionally, the internal monitoring agent is configured to perform at least one for the following operations: (i) initiate an execution, on the instance of the software system, of a function of the packaged application, (ii) retrieve, via a query sent to the instance of the software system, a record from a database, and (iii) access a log file created by the instance of the software system.

In another embodiment, the one or more monitoring agents comprise an internal monitoring agent that is configured to collect data related to a transaction performed by a user. Optionally, at least some of the data related to the transaction is not presented to the user via a user interface (UI) utilized by the user to perform the transaction.

In still another embodiment, the one or more monitoring agents include an interface monitoring agent that comprises a software element installed on a client machine on which runs a user interface (UI) that is used by a user to execute the BP. Optionally, the software element monitors information exchanged between the client and an instance of a software system (e.g., the instance runs on a server). Optionally, the monitoring performed by the software element but does not alter the information in a way that affects the execution of the BP. Optionally, the interface monitoring agent is configured to extract information from data presented on a user interface (UI) used by a user to execute the BP. Optionally disabling the software element does not impede the execution of the BP.

Selecting sequences by the sequence parser module 122 may be done in various ways in different embodiments. Following are some examples of various approaches that may be utilized in different embodiments by the sequence parser module 122.

In one embodiment, the sequence parser module 122 is further configured to identify a value of an Execution-Dependent Attribute (EDA). Optionally, at least some of the steps comprised in each of the candidate sequences 124 are associated with the same value of the EDA. Some examples of the type of values to which the EDA may correspond include one or more of the following types of values: a mailing address, a Universal Resource Locator (URL) address, an Internet Protocol (IP) address, a phone number, an email address, a social security number, a driving license number, an address on a certain blockchain, an identifier of a digital wallet, an identifier of a client, an identifier of an employee, an identifier of a patient, an identifier of an account, and an order number.

In another embodiment, the sequence parser module 122 may utilize a second model to select, from among the one or more streams 120, at least some of the candidate sequences 124. Optionally, the second model is trained based on a plurality of sequences corresponding to executions of a plurality of BPs. Thus, the second model may capture aspects of the type of steps that are in the plurality of BPs (and not necessarily only in a specific BP). This may enable the model to be generalizable and applicable for selecting sequences that include steps performed by various BPs, which may not necessarily be BPs upon which the second model was based. Optionally, the second model is generated based on models of the plurality of the BPs (e.g., graph-based descriptions and/or patterns describing the plurality of the BPs. Optionally, the plurality of sequences include sequences corresponding to executions associated with multiple organizations.

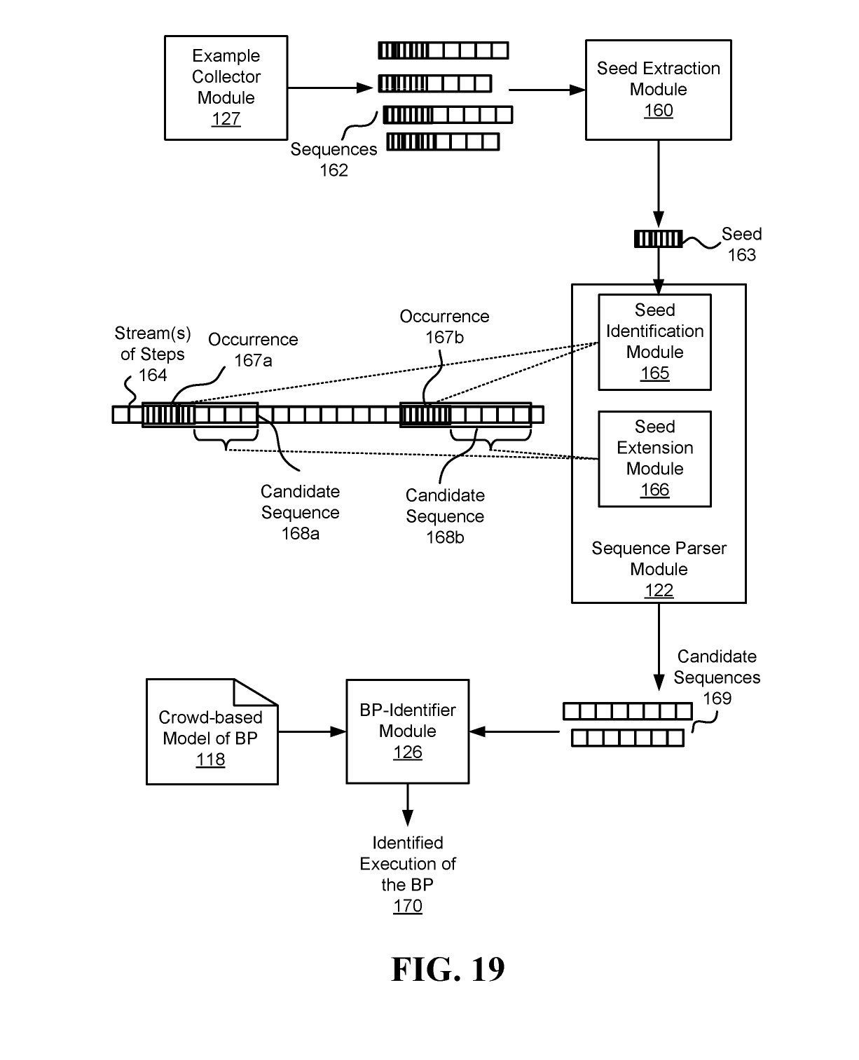

In yet another embodiment, the sequence parser module 122 may identify occurrences of sequence seeds in the one or more streams 120 and select at least some of the candidate sequences 124 by extending the sequence seeds. Optionally, a sequence seed comprises one or more consecutively performed steps from a certain stream. Utilization of this approach by the sequence parser module 122 is described in further detail in the discussion regarding embodiments illustrated in FIG. 19.

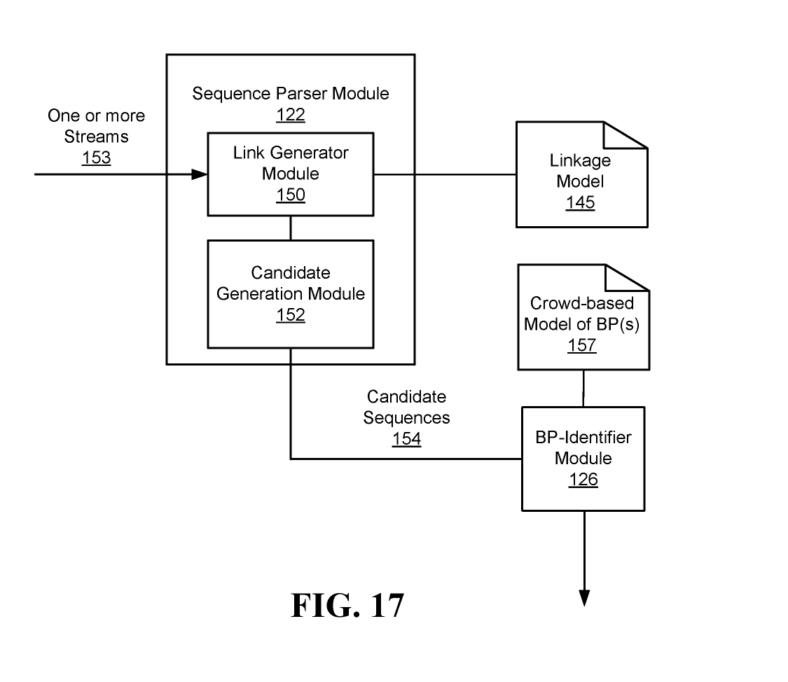

And in still another embodiment, the system may include a link generator module configured to generate links between pairs of steps that are among steps belonging to the one or more streams 120, and to select at least some of the candidate sequences 124 utilizing the links. Optionally, for each pair of consecutive steps in a selected candidate sequence at least one of the following is true: the pair is a pair of consecutive steps in a stream from among the streams, and the pair is linked by at least one of the links. Utilization of this approach by the sequence parser module 122 is described in further detail in the discussion regarding embodiments illustrated in FIG. 17.

The sequences 114 may be provided, in some embodiments, by example collector module 127, which receives information that can help determine which portions of a stream include steps involved in an execution of the BP. Collection of sequences by the example selector module 127 may also be referred to herein as “selection” of the sequences by the example selector module 127.

In one embodiment, the example collector module 127 is configured to: receive an indication that is indicative of the steps in a stream, performed as part of an interaction with an instance of a software system, which are involved in an execution of the BP, and to utilize the indication to select from the stream one or more steps belonging to a sequence of steps corresponding to an execution of the BP. Optionally, the indication is indicative of at least one of the following values: a step at the beginning of the execution of the BP, a step at the end of the execution of the BP, an identifier of a transaction involved in the execution of the BP, and an identifier of a form accessed as part of the execution of the BP. Optionally, the indication is provided by a user involved in the execution of the BP. For example, the user may enter a name and/or code describing the BP when the user executes the BP. Optionally, the indication is provided by the instance of the software system. For example, the software system may be a Process Aware Information Systems (PAIS), so at different times, the instance can determine which BP is being executed.

In another embodiment, the example collector module 127 is configured to receive an indication that is indicative of a period of time during which the BP was executed and select a sequence of steps corresponding to an execution of the BP from among at least some streams comprising steps that were performed during the period. In one example, the indication may be provided by a user (e.g., by specifying when the user started and/or finished executing the BP). In another example, the indication may be generated by analyzing products of the BP, such as determining when certain files and/or messages, which are part of an output of executing the BP, were generated. In in still another example, analysis of various logs (e.g., event logs) can help determine a time frame for when executions of the BP occurred.

In yet another embodiment, the example collector module 127 is configured to receive an indication that is indicative of a value associated with a certain execution of the BP and to select, from among the streams, a sequence of steps corresponding to an execution of the BP. Optionally, at least some of the steps belonging to the sequence describe the value. Optionally, the value associated with the certain execution of the BP is an EDA that corresponds to one or more of the following: a certain mailing address, a certain Universal Resource Locator (URL) address, a certain Internet Protocol (IP) address, a certain phone number, a certain email address, a certain social security number, a certain driving license number, a certain address on a certain blockchain, an identifier of a client, an identifier of an employee, a patient number, and an order number.

In still another embodiment, the example collector module 127 is configured to receive identifications of sequences corresponding to executions of the BP generated by the BP-identifier module 126. Optionally, the BP-identifier module 126 utilizes a model that is different from the crowd-based model 118, such as a manually generated model of the BP (e.g., a model generated by an expert).

The sequences 114 may different characteristics and/or combinations, which may depend on the method of used to select the sequences 114 and/or the streams of steps from which the sequences 114 were selected. The following are some examples of types of sequences the sequences 114 may comprise in different embodiments.

In one embodiment, the sequences 114 include sequences of steps performed by different users. For example, the sequences 114 include a third sequence of steps comprising steps performed by a first user and a fourth sequence of steps comprising steps performed by a second user, who is different from the first user. Optionally, the first user belongs to the first organization and the second user belongs to the second organization.

In another embodiment, the sequences 114 include at least some different sequences. For example, the sequences 114 include fifth and sixth sequences of steps that are different. In this example, the fifth sequence comprises the steps comprised in the sixth sequence and at least one additional step that is not comprised in the sixth sequence. Optionally, the at least one additional step is not involved in an execution of the BP. Alternatively, the at least one additional step is involved in an execution of the BP. In another example, the fifth sequence comprises a first number or repetitions of a certain step and the sixth sequence comprises a second number of repetitions of the certain step, which is different from the first number of repetitions. In yet another example, the fifth sequence comprises a first step that is not comprised in the sixth sequence and the sixth sequence comprises a second step that is not comprised in the fifth sequence.

In yet another embodiment, the sequences 114 include one or more sequences of steps that each comprises a first step performed on an instance of a first software system and a second step performed on an instance of a second software system, which is different from the first software system. Optionally, the first step is performed by a first user and the second step is performed by a second user, who is different from the first user. Optionally, the instance of the first software system belongs to a certain first organization and the instance of the second software system belongs to a certain second organization.

In still another embodiment, the sequences 114 include one or more sequences of steps that each comprises: (i) a first step belonging to a first stream, from among the one or more streams 120, which is generated by a first monitoring agent, and (ii) a second step belonging to a second stream, from among the one or more streams 120, which is generated by a second monitoring agent. Additionally, the first monitoring agent is an internal monitoring agent, which is different from the second monitoring agent, which is an interface monitoring agent.

In some embodiments, at least some the sequences 114 may include sequences corresponding to consecutive executions of the BP, where each sequence includes only steps that are involved in an execution of the BP. Optionally, all of the sequences 114 are sequences corresponding to consecutive executions of the BP. In other embodiments, at least some the sequences 114 may include sequences corresponding to nonconsecutive executions of the BP, where each sequence may include at least some steps that are not involved in the execution of the BP. For example, a sequence corresponding to a nonconsecutive execution of the BP includes at least first and second steps from a stream that also comprises a third step; the third step, which is not involved in an execution of the BP, is performed after the first step is performed and before the second step is performed. Additional details regarding utilizing sequences corresponding to nonconsecutive executions of BP for generating a model of the BP is given in the discussion regarding FIG. 3.

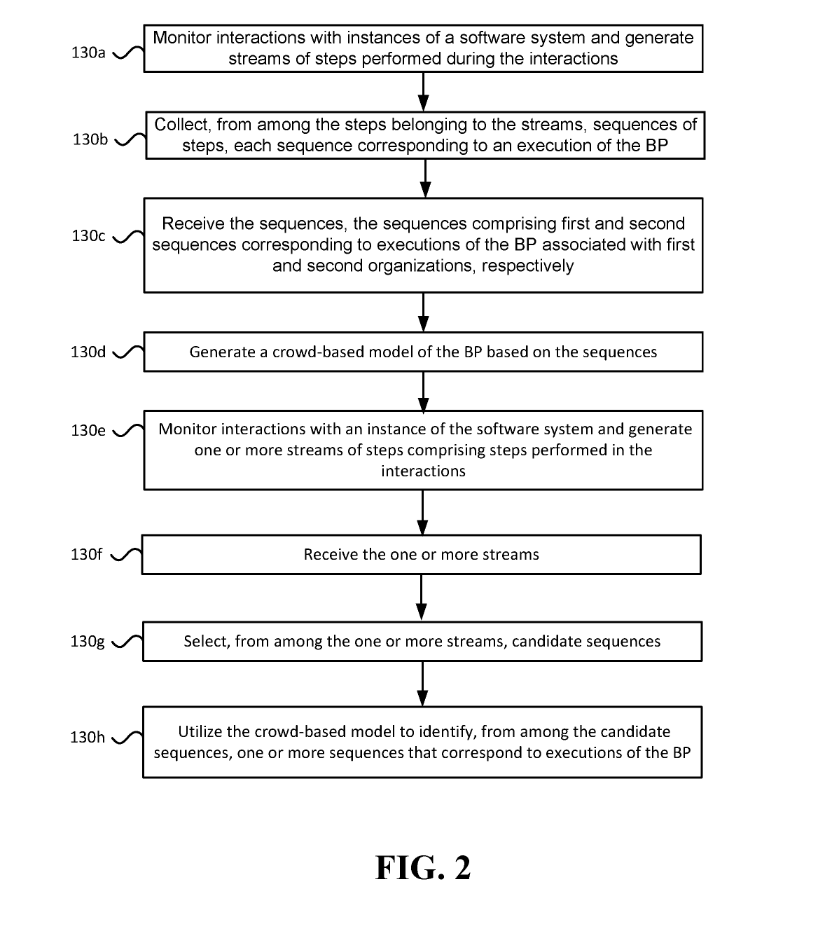

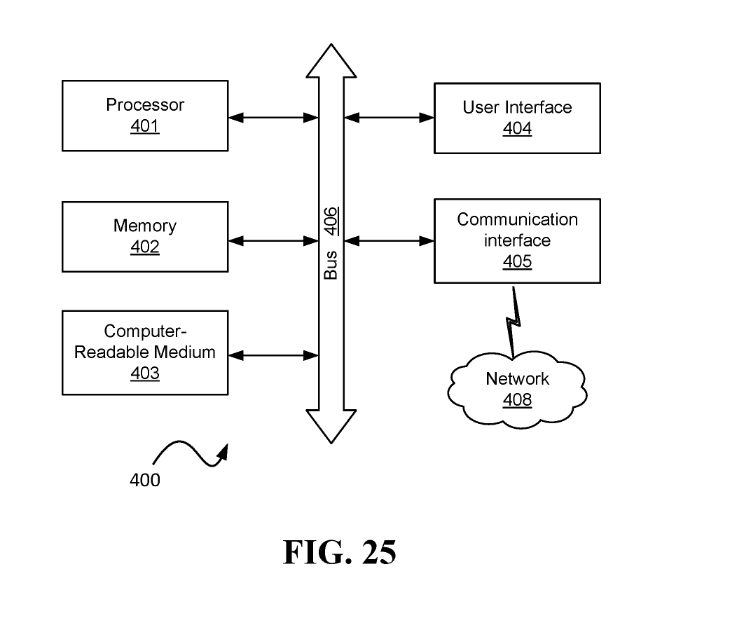

FIG. 2 illustrates steps that may be performed in one embodiment of a method for identifying executions of a BP utilizing a crowd-based model of the BP. The steps described below may be, in some embodiments, part of the steps performed by an embodiment of a system described above, which is illustrated in FIG. 1. In some embodiments, instructions for implementing the method described below may be stored on a computer-readable medium, which may optionally be a non-transitory computer-readable medium. In response to execution by a system including a processor and memory, the instructions cause the system to perform operations that are part of the method. Optionally, the methods described below may be executed by a system comprising a processor and memory, such as the computer illustrated in FIG. 25. Optionally, at least some of the steps may be performed utilizing different systems comprising a processor and memory. Optionally, at least some of the steps may be performed using the same system comprising a processor and memory.

In one embodiment, a method for identifying executions of a BP utilizing a crowd-based model of the BP includes at least the following steps:

In Step 130c, sequences of steps selected from among streams of steps performed during interactions with instances of a software system. Optionally, each sequence corresponds to an execution of the BP. Optionally, the sequences comprise first and second sequences corresponding to executions of the BP which are associated with first and second organizations, respectively. Optionally, the sequences received in this step are the sequences 114.

In Step 130d, generating the crowd-based model of the BP based on the sequences. Optionally, the model is generated utilizing the model trainer module 116. Optionally, the crowd-based model of the BP generated in this step is the crowd-based model 118.

In Step 130f, receiving one or more streams of steps performed during interactions with an instance of the software system, which belongs to a third organization.

In Step 130g, selecting, from among the one or more streams, candidate sequences of steps. Optionally, selecting the candidate sequences is done utilizing the sequence parser module 122. Optionally, the candidate sequences selected in this step are the candidate sequences 124.

And in Step 130h, utilizing the crowd-based model generated in Step 130d to identify, from among the candidate sequences, one or more sequences of steps that correspond to executions of the BP. Optionally, identifying the one or more sequences is done utilizing the BP-identifier module 126.

In some embodiments, the method optionally includes Step 130a, which involves monitoring interactions with the instances of one or more software systems and generating the streams of steps based on data collected during the monitoring. Optionally, the monitoring is performed by one or more monitoring agents, each of which being one of the monitoring agents 102a to 102d. Additionally or alternatively, the method optionally includes Step 130b, which involves collecting the sequences received in Step 130c from among the streams of steps. Optionally, collecting the sequences is done utilizing the example collector module 127.

In some embodiments, the method optionally includes Step 130e, which involves monitoring the interactions with the instance of the software system and generating the one or more streams received in Step 130f based on data collected during the monitoring. Optionally, the monitoring is performed by one or more monitoring agents, each of which being one of the monitoring agents 102a to 102d.

Monitoring interactions, such as the monitoring performed in Step 130a, Step 130e and/or other steps described in this disclosure that mention monitoring interactions, may involve performing various operations. In one example, monitoring the interactions involves monitoring information exchanged between a client and an instance of a software system. In this example, the monitoring does not alter the information in a way that affects the execution of the BP. In another example, monitoring the interactions involves performing at least one for the following operations: (i) initiating an execution, on an instance of the software system, of a function of the packaged application, (ii) retrieving, via a query sent to an instance of the software system, a record from a database, and (iii) accessing a log file created by an instance of the software system. In yet another example, monitoring the interactions involves extracting information from data presented on a user interface (UI) used by a user to execute the BP. In still another example, monitoring the interactions involves analyzing input provided by a user via a user interface (UI). Optionally, the input is provided using at least one of the following devices: a keyboard, a mouse, a gesture-based interface device, a gaze-based interface device, and a brainwave-based interface device. And in yet another example, monitoring the interactions involves analyzing network traffic between a terminal used by a user and a server used to run an instance of the software system.

Generating the crowd-based model in Step 130d may involve performing different operations. In one example, generating the crowd-based model comprises generating a pattern describing a sequence of steps involved in the execution of the BP. In another example, generating the model in Step 130d involves generating a graphical description of the BP, such as a Petri net or a BPMN model. In some embodiments, generating the model in Step 130d involves receiving additional sequences of steps, which do not correspond to executions of the BP, and generating the crowd-based model of the BP based on the additional sequences. In one example, generating the model in Step 130d, involves utilizing the sequences and the additional sequences, to generate an automaton configured to recognize an execution of the BP based on a sequence of steps. In this example, the crowd-based model comprises parameters of the automaton. In another example, generating the model in Step 130d involves utilizing a machine learning training algorithm to generate the crowd-based model of the BP based on the sequences and the additional sequences. Optionally, the crowd-based model of the BP comprises parameters used by a machine learning-based predictor configured to receive feature values determined based on a sequence of steps and to calculate a value indicative of a probability that the sequence of steps represents an execution of the BP.

In real world activity observed in many organizations, BPs are often executed nonconsecutively. For example, a user may start executing a first BP, switch to a second BP, and then resume with the first BP. In some embodiments, software systems may not be process aware information systems (PAIS) and/or the monitoring of interactions with instances of the software systems may not provide sufficient information to determine which steps correspond to which executions (e.g., a case ID corresponding to each step may not be known). Identifying executions of BPs in such an environment may pose certain challenges stemming from the fact that it may not be clear which steps in the streams should be considered belonging to the same execution of a BP. In different embodiments, this uncertainty may be addressed in different ways.

In some embodiments, the sequence parser module 122 may attempt to filter out certain steps of the streams in order to generate at least some candidate sequences that contain mostly (if not entirely) steps that belong to the same execution of a BP. One way in which such candidate sequences may be selected from streams is described the discussion regarding embodiments related to FIG. 14, which involves the use of links between nonconsecutively performed steps. In other embodiments, at least some of the candidate sequences selected by the sequence parser module 122 may likely include steps that do not all belong to a certain execution of a BP; due to the inclusion of additional steps such sequences may be considered corresponding to nonconsecutive executions of the BP. In these embodiments, a model of the BP and/or a module that identifies executions of the BP (e.g., the BP-identifier module 126) may need to address this issue, as discussed in more detail in embodiments illustrated in FIG. 3, FIG. 5, FIG. 7 and FIG. 9.

FIG. 3 illustrates one embodiment of a system configured to generate a model useful for identifying nonconsecutive executions of a certain BP. The system includes at least the following modules: the example collector module 127, and the model trainer module 116. In some embodiments, the system may optionally include negative example collector module 182 and/or the BP-identifier module 126. The embodiment illustrated in FIG. 3 may be realized utilizing a computer, such as the computer 400, which includes at least a memory 402 and a processor 401. The memory 402 stores code of computer executable modules, such as the modules mentioned above, and the processor 401 executes the code of the computer executable modules stored in the memory 402.

The model trainer module 116 is configured to generate models of BPs, such as the crowd-based model 175 of the certain BP. In some embodiments, the model 175 is generated based on sequences corresponding to executions of the certain BP, such as sequences belonging to positive set 173. For example, in these embodiments, the model 175 may describe a pattern of the certain BP. In some embodiments, the model 175 may also be generated based on sequences that do not correspond to executions of the certain BP, such as sequences belonging to negative set 174. For example, in these embodiments, the model 175 may include parameters of an automaton and/or parameters of a machine learning-based model.

The example collector module 127 is configured, in one embodiment, to collect, from among streams of steps performed during interactions with instances of one or more software systems, the positive set 173, which include sequences comprising steps involved in executions of the certain BP. Optionally, the sequences belonging to the positive set 173 include less than half of the steps that are comprised in the streams. Optionally, the sequences in the positive set 173 may not all be of the same length. In one example, the positive set 173 comprises at least first and second sequences of steps, and the first sequence comprises more steps than the second sequence. In one embodiment, at least some of the sequences in the positive set 173 correspond to nonconsecutive executions of the certain BP. Additionally or alternatively, the sequences in the positive set 173 include sequences corresponding to executions of the certain BP, which are associated with a plurality of organizations. For example, the sequences in the positive set 173 comprise at least first and second sequences corresponding to executions of the certain BP associated with first and second organizations, respectively.

In some embodiments, a sequence of steps corresponding to a nonconsecutive execution of the certain BP comprises at least first and second steps from a stream that also comprises a third step; the third step, which is not involved in an execution of the certain BP, is performed after the first step is performed and before the second step is performed. Optionally, the sequence corresponding to the nonconsecutive execution of the certain BP may be considered to include at least some nonconsecutively performed steps. The term “nonconsecutively performed steps” is utilized herein to represent steps that are all involved in the execution of a BP, but are not consecutively performed. For example, the first and second steps described above may be considered nonconsecutively performed steps (involved in the execution of the certain BP). In another example, nonconsecutively performed steps may include certain first and second steps that are part of an execution of a BP, but are performed on instances of first and second software systems, respectively.

In some embodiments, steps belonging to a sequence that corresponds to an execution of the certain BP may have associated values that can help identify them as belonging to the same execution of the certain BP. These associated values may help identify steps as belonging to the same execution even if the steps are nonconsecutively performed. For example, referring to the first and second steps mentioned above, the first and second steps may both be associated with a certain value of an Execution-Dependent Attribute (EDA) and the third step described above is not associated with the certain value of the EDA (e.g., it is associated with a different value of the EDA). Optionally, the EDA corresponds to one or more of the following types of values: a mailing address, a Universal Resource Locator (URL) address, an Internet Protocol (IP) address, a phone number, an email address, a social security number, a driving license number, an address on a certain blockchain, an identifier of a digital wallet, an identifier of a client, an identifier of an employee, an identifier of a patient, an identifier of an account, and an order number.

In one embodiment, at least some of the sequences in the positive set 173 correspond to consecutive executions of the certain BP. Herein, in a sequence of steps corresponding to a consecutive execution of the certain BP, there are no first and second steps from a stream, which are performed sequentially (and appear so the stream), such that the stream also comprises a third step that is not involved in the execution of the certain BP, and the third step performed after the first step and before the second step.

In FIG. 3, the positive set 173 is illustrated as including sequences corresponding to consecutive executions of the certain BP, which are illustrated as sequences in which all the steps are BP steps (squares marked with a pattern of slanted lines). Additionally, in the figure, the positive set 173 is illustrated as including sequences corresponding to nonconsecutive executions of the certain BP, which are Illustrated as sequences in which some of the steps are non-BP steps, i.e., steps that are not part of executions of the certain BP. These steps are illustrated as empty squares in FIG. 3. It is to be noted that in other illustrations in this disclosure empty squares may or may not represent non-BP steps (depending on the context of the illustrated embodiments).

The negative example collector module 182 is configured, in one embodiment, to collect a negative set 174, which comprises additional sequences of steps that do not correspond to executions of the certain BP. Optionally, the negative example collector module 182 selects at least some of the additional sequences from among the steps belonging to the streams. For example, the negative set 174 may comprise randomly selected subsequences from among the steps belonging to the streams. In another example, the negative set may comprise at least some sequences that are permutations of sequences belonging to the positive set 173. In yet another example, at least some of the additional sequences in the negative set 174 comprises may correspond to executions of BPs that are different from the certain BP.

The BP model trainer module 116 is configured, in one embodiment, to generate the model 175 of the certain BP based on the positive set 173 and the negative set 174, and to provide the model 175 for use by a system that identifies executions of the certain BP. When the model 175 is generated based on sequences corresponding to executions of the certain BP that are associated with a plurality of organizations, the model 175 may be considered a crowd-based model of the certain BP. Similarly to the crowd-based model 118, the model 175 may include different parameters, in different embodiments, as described in the examples below. Additional discussion regarding generation of models of BPs based on sequences of steps corresponding to executions of the BPs may also be found in this disclosure at least in Section 6—Models of BPs.

In one embodiment, the model 175 comprises a pattern describing a sequence of steps involved in the execution of the certain BP. Optionally, the pattern describes a consecutive sequence of steps involved in the execution of the BP. Optionally, the pattern describes a nonconsecutive sequences of steps involved in the execution of the BP. For example, the pattern may include information regarding the location (in a sequence of steps) of one or more gaps in the execution of the certain BP and/or indications regarding the of the one or more gaps length (e.g., duration in time and/or number of steps). Optionally, the pattern is determine from alignment of sequences from among the positive set 173 that include both sequences that correspond to consecutive executions of the certain BP and sequences the correspond to nonconsecutive executions of the certain BP. Optionally, the pattern represents steps that appear in most of the sequences belonging to the positive set 173. For example, each step belonging to the sequence described by the pattern is included in at least 50% of the sequences in the positive set 173. Optionally, each step belonging to the sequence described by the pattern is included in all of the sequences in the positive set 173.

In another embodiment, the model comprises a descriptions of an automaton configured to recognize an execution of the certain BP based on a sequence of steps that comprises steps involved in an execution of the certain BP. Optionally, the sequence of steps may comprise steps that do not belong to an execution of the certain BP, but nonetheless the automaton may recognize the sequence since it is trained with data that comprises sequences corresponding to nonconsecutive executions of the certain BP.

In yet another embodiment, the model 175 comprises parameters used by a machine learning-based predictor configured to receive feature values determined based on a sequence of steps and to calculate a value indicative of a probability that the sequence of steps represents an execution of the certain BP. Optionally, the machine learning-based predictor implements one or more of the following machine learning algorithms: decision trees, random forests, support vector machines, neural networks, logistic regression, and a naïve Bayes classifier.

The model 175 may be provided, in some embodiments, for use by a system that identifies executions of the certain BP. For example, the model 175 may be provided to the BP-identifier module 126 and utilized to identify which sequences from among candidate sequences correspond to executions of the certain BP. Optionally, the candidate sequences are selected from among one or more streams of steps by the sequence parser module 122. Optionally, when the model 175 is utilized to identify executions of the certain BP, on average, a first sequence that belongs to the positive set 173 and corresponds to a nonconsecutive execution of the certain BP is more likely to be identified as corresponding to an execution of the certain BP than a second sequence of steps, of equal length to the first sequence, which comprises steps that appear in one or more of the streams and does not belong to the positive set 173.

In some embodiments, the streams of steps from which the sequences belonging to the positive set 173 were selected are obtained from monitoring the interactions with the instances of the one or more software systems. Optionally, embodiments of the system illustrated in FIG. 3 may include a plurality of monitoring agents configured to generate the streams of steps. Optionally, each monitoring agent generates a stream comprising steps performed as part of an interaction with an instance of a software system from among the one or more software systems. Additional discussion regarding monitoring agents and the data they examine/produce may be found in this disclosure at least in Section 3—Monitoring Activity.

FIG. 4 illustrates steps that may be performed in one embodiment of a method for generating a model useful for identifying nonconsecutive executions of a certain BP. The steps described below may be, in some embodiments, part of the steps performed by an embodiment of a system illustrated in FIG. 3. In some embodiments, instructions for implementing the method described below may be stored on a computer-readable medium, which may optionally be a non-transitory computer-readable medium. In response to execution by a system including a processor and memory, the instructions cause the system to perform operations that are part of the method. Optionally, the methods described below may be executed by a system comprising a processor and memory, such as the computer illustrated in FIG. 25. Optionally, at least some of the steps may be performed utilizing different systems comprising a processor and memory. Optionally, at least some of the steps may be performed using the same system comprising a processor and memory.

In one embodiment, a method for generating a model useful for identifying nonconsecutive executions of a certain BP includes at least the following steps:

In Step 184b, receiving streams of steps performed during interactions with instances of one or more software systems and collecting, from among the streams, a positive set comprising sequences of steps involved in executions of the certain BP. Each sequence of steps comprises steps that appear in one or more of the streams. Additionally, at least some of the sequences correspond to nonconsecutive executions of the certain BP. The sequences comprise sequences corresponding to executions of the certain BP that are associated with a plurality of organizations. For example, the sequences include at least first and second sequences corresponding to executions of the certain BP associated with first and second organizations, respectively. Optionally, the sequences collected in this step belong to the positive set 173. Optionally, the sequences are collected by the example collector module 127.

In Step 184c, collecting a negative set that comprises additional sequences of steps. Optionally, the negative set is the negative set 174. Optionally, the additional sequences are collected by the negative examples collector module 182. Optionally, at least some of the additional sequences are sequences of steps corresponding to executions of BPs that are different from the certain BP.

In Step 184d, generating the model of the certain BP based on the positive set selected in Step 184b and the negative set selected in Step 184c. Optionally, the generated model is the model 175. Optionally, the model generated in this step is generated by the model trainer module 116.

And in Step 184e, providing the model generated in Step 184d to be utilized for identifying executions of the certain BP. Optionally, the model is utilized by the BP-identifier module 122.

In one embodiment, the method described above may optionally include Step 184a which involves monitoring the interactions with the instances of the one or more software systems. Optionally, the monitoring is performed by one or more monitoring agents, such as one or more of the monitoring agents 102a to 102d.

In one embodiment, selecting the sequences belonging to the positive set in Step 184b involves receiving indications identifying the sequences of steps in the streams that correspond to executions of the certain BP and utilizing the indications to select at least some of the sequences in the positive set. In one example, an indication is received from a user indicative of a period of time during which the user executed the certain BP, and utilizing the indication to select a sequence of steps, form among the one or more streams, which corresponds to an execution of the certain BP.

In different embodiments, Step 184d may involve performing different operations, depending on the type of model being generated. In one example, Step 184d may involve aligning the sequences belonging to the positive set in order to obtain a consensus pattern of steps that appear in most of the sequences. Optionally, the alignment may involve a gapped-alignment algorithm, such as various alignment algorithms used to for biological sequences (e.g. an algorithm for aligning DNA sequences to find motifs). In another example, Step 184d may involve generating an automaton based on the positive and negative sets. Optionally, the automaton recognizes most of the sequences belonging to the positive set and does not recognize most of the sequences belonging to the negative set. In yet another example, Step 184d may involve generating at least one of the followings sets of parameters: parameters of a neural network, parameters for a support vector machine, parameters of a naïve Bayesian model, logistic regression parameters, and parameters of a decision tree.

FIG. 5 illustrates one embodiment of a system configured to perform pattern-based identification of sequences corresponding to executions of Business Processes (BPs). The system includes at least the following modules: the sequence parser module 122, distance calculator module 186, and assignment module 187. In some embodiments, the distance calculator module 186 and/or the assignment module 187 may be considered modules that belong to, and/or are utilized by, the BP-identifier module 126. The embodiment illustrated in FIG. 5 may be realized utilizing a computer, such as the computer 400, which includes at least a memory 402 and a processor 401. The memory 402 stores code of computer executable modules, such as the modules described above, and the processor 401 executes the code of the computer executable modules stored in the memory 402.

The sequence parser module 122 is configured, in one embodiment, to receive the one or more streams 120 of steps performed during interactions with an instance of a software system, which belongs to a certain organization. The sequence parser module 122 is configured to select, from among the one or more streams 120, the candidate sequences 124 of steps.

There are various ways in which the sequence parser module 122 may select the candidate sequences 124 (these are discussed in more detail in the discussion regarding FIG. 1). For example, the sequence parser module 122 may identify a value of an Execution-Dependent Attribute (EDA), and select the candidate sequences 124 such that at least some of the steps comprised in each candidate sequence are associated with the same value of the EDA. In another example, the sequence parser module 122 may utilize links between nonconsecutively performed steps, as described in the discussion of embodiments modeled according to FIG. 17. And in still another example, the sequence parser module 122 may select the candidate sequences 124 by identifying and extending seeds, as described in more detail in the discussion of embodiments modeled according to FIG. 19.

The distance calculator module 186 is utilized, in one embodiment, to calculate distances between the candidate sequences 124 and patterns 189 of the BPs. Each pattern of a BP, from among the patterns 189, describes a certain sequence of steps involved in an execution of the BP. For example, the certain sequence may specify a sequence of transactions and/or operations that may be performed in order to execute the BP. Optionally, a pattern of a BP may be described using a regular expression, and the certain sequence described by the pattern is a sequence that corresponds to the regular expression (i.e., it is one of the “words” in the regular grammar that corresponds to the regular expression). Optionally, the patterns 189 include at least first and second different patterns that describe different sequences corresponding to executions of first and second BPs, respectively.

In some embodiments, one or more of the patterns 189 may come from crowd-based models of BPs, such as the crowd-based model 118 or some other crowd-based model of a BP designated in this disclosure using some other reference numeral. Optionally, at least some of the patterns 189 are generated based on sequences selected by the example collector module 127. Optionally, at least some of the patterns 189 are generated by the model trainer module 116. In one example, a certain sequence describing a pattern of a BP from among the patterns 189 is generated based on previously identified sequences of steps corresponding to executions of the BP, which comprise at least first and second sequences that correspond to executions of the BP associated with first and second organizations, respectively. The first and second organizations in this example are different from the certain organization whose activity is described in the one or more streams 120.

The distance calculator module 186 is configured, in some embodiments, to calculate a distance between a candidate sequence (from among the candidate sequences 124) and the pattern (from among the patterns 189) based on an alignment of the candidate sequence and the certain sequence described by the pattern. Various alignment functions may be utilized to calculate the distance between the candidate sequence and the certain sequence described by a pattern. In one example, a pairwise trace alignment may be used, such as described in Bose, et al. “Trace alignment in process mining: opportunities for process diagnostics”, International Conference on Business Process Management, Springer Berlin Heidelberg, 2010. In another example, a variant of one of the many sequence alignment algorithms developed for aligning biological sequences may be used for this task (e.g., a sequence alignment algorithm that utilized dynamic programming to find an optimal alignment according to a chosen distance function).

The assignment module 187 is configured, in one embodiment, to assign at least some of the candidate sequences 124 with identifiers 190 of BPs to which they correspond based on distances calculated between the at least some of the candidate sequences 124 and the patterns 189 of the BPs. Optionally, an identifier of a BP may be a name, code, serial number, and/or other form of label that may be used to single out a certain BP from among a plurality of BPs. Optionally, when a candidate sequence is assigned an identifier of a certain BP, it means that a distance calculated between the candidate sequence and a pattern of the certain BP is below a threshold. Optionally, for each pattern from among the patterns 189, distances between most of the candidate sequences 124 and the pattern are not below the threshold. Additionally or alternatively, when a candidate sequence is assigned an identifier of a certain BP, it may mean that there is no other pattern, from among the patterns 189, that has a lower distance from the candidate sequence.

In one example, the candidate sequences 124 comprise first and second candidate sequences that are assigned identifiers of the first and second BPs, respectively. Optionally, the first and second candidate sequences are not the same. For example, the first sequence comprises at least one step that is not comprised in the second sequence and/or the second sequence comprises at least one step that is not comprised in the first sequence. Optionally, the different assignment of BPs in this example may stem from different distances of the first and second candidate sequences from different patterns from among the patterns 189. For example, a first distance calculated between the first candidate sequence and a first pattern of the first BP is smaller than a second distance calculated between the first candidate sequence and a second pattern of the second BP. Additionally, a third distance calculated between the second candidate sequence and the second pattern is smaller than a fourth distance calculated between the second candidate sequence and the first pattern. Optionally, in this example, the first and third distances are below a threshold, while the second and fourth distances are not below the threshold.

An assignment of a candidate sequence with an identifier of a BP to which the candidate sequence corresponds does not necessarily imply that a certain sequence described by a pattern of the BP is identical to the candidate sequence. In some embodiments, a candidate sequence may be dissimilar to some extent from the pattern. In one example, the first candidate sequence mentioned above comprises at least one step that is not included in a certain sequence of steps involved in an execution of the first BP, which is described in the first pattern. In another example, a certain sequence of steps involved in an execution of the first BP, which is described in the first pattern, comprises at least one step that is not included in the first candidate sequence.

In some embodiments, the assignment module 187 may utilize prior information regarding the extent to which each of the BPs is typically executed in order to assign the identifiers 190. Optionally, the prior information may comprise prior probabilities of executions of the BPs, and the assignment module 187 may utilize a Bayesian approach that takes into account the prior probability that a BP was executed when determining whether to identify a candidate sequence as corresponding to the BP. In one example, the assignment module 187 may utilize different thresholds for different BPs, such that the distance threshold for a rarely executed BP may be lower than a distance threshold for a frequently executed BP. Thus, in this example, an assignment of candidate sequence with an identifier of the rarely executed BP may be based on better alignment (i.e., an alignment of a smaller distance) than an assignment of another candidate sequences with an identifier of the frequently executed BP. In one embodiment, the prior information regarding the extent to which each of the BPs is executed is collected from executions of BPs of another organization, which is not the certain organization. Optionally, the other organization is similar to the certain organization (e.g., both organizations are in the same field of operations).

Some of the candidate sequences 124 that are assigned the identifiers 190 may include, in some embodiments, steps that are not performed as part of the BP to which they correspond; as such, in those embodiments, those candidate sequences may be considered to correspond to nonconsecutive executions of the BP to which they correspond. As discussed above, various alignment algorithms may be utilized to calculate distances given gaps that may arise in the alignment of a candidate sequence and a pattern when the candidate sequence corresponds to a nonconsecutive execution of a BP.

In one example, the first candidate sequence mentioned above comprises first, second, and third steps that belong to a certain stream from among the one or more streams. The first step was performed before the second step and the second step was performed before the third step. Additionally, the first and third step were performed as part of an execution of the first BP while the second step was not performed as part of an execution of the first BP. Thus, in this example the first candidate sequence may be considered to correspond to a nonconsecutive execution of the first BP. Optionally, the first and third steps are both associated with a certain value of an Execution-Dependent Attribute (EDA) and the second step is not associated with the certain value of the EDA. Optionally, the second step is associated with a value for the EDA, which is different from the certain value. For example, the first and third steps may describe operations involving a client associated with a first client ID, while the second step may describe an operation involved a client associated with a second client ID that is different from the first client ID.

In some embodiments, the system described above may include one or more monitoring agents configured to generate the one or more streams 120. Optionally, each monitoring agent generates a stream comprising steps performed as part of an interaction with an instance of a software system. Additional discussion regarding monitoring agents and the data they examine/produce may be found in this disclosure at least in Section 3—Monitoring Activity.

FIG. 6 illustrates steps that may be performed in one embodiment of a method for performing pattern-based identification of sequences corresponding to executions of a Business Processes (BPs). The steps described below may, in some embodiments, be part of the steps performed by an embodiment of a system described above, such as a system illustrated in FIG. 5. In some embodiments, instructions for implementing the method described below may be stored on a computer-readable medium, which may optionally be a non-transitory computer-readable medium. In response to execution by a system including a processor and memory, the instructions cause the system to perform operations that are part of the method. Optionally, the methods described below may be executed by a system comprising a processor and memory, such as the computer illustrated in FIG. 25. Optionally, at least some of the steps may be performed utilizing different systems comprising a processor and memory. Optionally, at least some of the steps may be performed using the same system comprising a processor and memory.

In one embodiment, a method for performing pattern-based identification of sequences corresponding to executions of BPs includes at least the following steps:

In Step 191b, receiving one or more streams of steps performed during interactions with instances of one or more software systems, and selecting, from among steps belonging to the one or more streams, candidate sequences of steps. Optionally, the one or more streams describe interactions with instances of a single software system. Optionally, the candidate sequences are selected utilizing the sequence parser module 122.

In Step 191c, receiving patterns of the BPs. Each pattern of a BP describes a certain sequence of steps involved in an execution of the BP. The certain sequence is generated based on previously identified sequences of steps corresponding to executions of the BP, which comprise at least certain first and second sequences that correspond to executions of the BP associated with first and second organizations, respectively.

In Step 191d, calculating distances between the candidate sequences and the patterns of the BPs. Optionally, each distance between a candidate sequence and a pattern is based on an alignment of the candidate sequence and the certain sequence described by the pattern. Optionally, the distances are calculated utilizing the distance calculator module 186.

An in Step 191e, assigning at least some of the candidate sequences with identifiers of BPs to which they correspond based on distances calculated in Step 191d between the at least some of the candidate sequences and patterns of the BPs. Optionally, the at least some candidate sequences comprise first and second candidate sequences that are assigned identifiers of first and second BPs, respectively. Optionally, when a candidate sequence is assigned an identifier of a certain BP, a distance calculated between the candidate sequence and a pattern of the certain BP is below a threshold. Optionally, assigning the identifiers in this step is done utilizing the assignment module 187.

In one embodiment, the method described above may optionally include Step 191a that involves monitoring the interactions with the instances of the one or more software systems and generating the one or more streams received in Step 191b. Optionally, the monitoring involves at least one of the following types of monitoring: internal monitoring (e.g., by an internal monitoring agent), and interface monitoring (e.g., by an interface monitoring agent).

In some embodiments, calculating the distances in Step 191d may involve performing a gapped-alignment. In one example, the first candidate sequence described above may comprise first, second, and third steps that belong to a certain stream from among the one or more streams. The first step was performed before the second step and the second step was performed before the third step. The first and third step were performed as part of an execution of the first BP while the second step was not performed as part of an execution of the first BP. In this example, calculating a distance between the first candidate sequence and the first pattern involves performing a gapped-alignment between the candidate sequence and a certain sequence of steps described by the first pattern.

Selecting the candidate sequences in Step 191b may be done in different ways in different embodiments, as discussed in more detail at least in the discussion regarding FIG. 1 and Section 5—Selecting Sequences from Streams. In one example, Step 191b may involve identifying values of an Execution-Dependent Attribute (EDA) in at least some of the steps comprised in the one or more streams and selecting the candidate sequences such that for each candidate sequence, the steps belonging to the candidate sequence are associated with the same value of the EDA. In another example, Step 191b may involve: (i) generating links between pairs of steps that are among steps belonging to the one or more streams (where at least some of the links are between pairs of steps that are not consecutively performed steps in the same stream); and (ii) selecting the candidate sequences utilizing the links. Optionally, for each pair of consecutive steps in a candidate sequence at least one of the following is true: the pair is a pair consecutive steps in a stream from among the streams, and the pair is linked by at least one of the links.

FIG. 7 illustrates one embodiment of a system configured to utilize an automaton to identify a sequence corresponding to an execution of a BP. The system includes at least the following modules: monitoring agent 102, and simulation module 194. In some embodiments, the system may optionally include the sequence parser module 122. In some embodiments, the simulation module 194 may be a module that is included in, and/or utilized by, the BP-identifier module 126. The embodiment illustrated in FIG. 7 may be realized utilizing a computer, such as the computer 400, which includes at least a memory 402 and a processor 401. The memory 402 stores code of computer executable modules, such as the modules described above, and the processor 401 executes the code of the computer executable modules stored in the memory 402.

The monitoring agent 102 is configured, in some embodiments, to generate stream 192 of steps performed during interactions with an instance of a software system belonging to a certain organization. Additional details about the monitoring agent 102 and monitoring the interactions may be found in this disclosure at least in Section 3—Monitoring Activity.

The simulation module 194 is configured to simulate running an automaton on an input comprising a sequence of steps (i.e., to “run” the automaton on the input). Depending on the embodiment, the stream 192 may be provided directly to the simulation module 194 as input and/or the stream 192 may be further parsed to provide the simulation module 194 with candidate sequences 193. Thus, in some embodiments, the system may optionally include the sequence parser module 122, which in these embodiments is configured to select, from among the steps belonging to the stream 192, the candidate sequences of steps 193. In these embodiments, the simulation module 194 is configured to simulate the running of the automaton on each of the candidate sequences 193.

Herein, an “automaton” is an abstract machine, which implements a mathematical model of computation. An automaton operates on inputs that comprise sequences of symbols (e.g., symbols describing steps), and it can either accept or rejects each sequence. The sequences that are accepted by an automaton are considered to belong to a “language” of the automaton. In some embodiments, an automaton is a finite-state machine that produces a deterministic computation (or run) of the automaton for each input sequence. In these embodiments, each run of the automaton on the same input produces the same result. Typically, with automatons described herein, the operation of an automaton is governed by a set of parameters that determine which sequences of steps are to be accepted and/or which are to be rejected. In some embodiments, the automaton is configured to accept sequences of steps corresponding to executions of a certain BP (or multiple BPs). In one example, the automaton may be configured to identify sequences in which all the steps in the sequence are involved in an execution of the BP. In another embodiment, the automaton may be configured to identify sequences of steps that include the steps involved in an execution of the BP, and possibly other steps too (e.g., steps involved in execution of another BP). In one example, the parameters of the automaton may include parameters describing the following elements: a finite set of states (Q), a finite set of symbols (the alphabet of the automaton Σ), a transition function (δ:Q×ΣQ), a start state (q0), and a set of accepting states (F). Optionally, the parameters of the automaton describe a Deterministic Finite Automaton (DFA). Optionally, the parameters of the automaton describe a Nondeterministic Finite Automaton (NFA).

In some embodiments, the simulation module 194 sequentially evaluates the steps in an input provided to it. For each step, and current state, the simulation module 194 transitions to a next state based on the transition function δ described above. Optionally, upon reaching an accepting state (i.e., a state that belongs to the set F mentioned above), the simulation module 194 generates indication 195 which is indicative that the input to the simulation module 194 contained a sequence of steps that corresponds to an execution of the BP. This situation may be referred to herein as the automaton “recognizing” the sequence. Optionally, the accepting state is reached after the last step in the sequence of steps that corresponds to the execution of the BP is evaluated. Optionally, the indication 195 further includes information regarding which of the steps in the input belong to the sequence corresponding to the execution of the BP. In one example, determining which steps belong to the sequence may be done by evaluating the states the automaton was in after evaluating various steps in the input. In this example, certain states in the set Q may be considered to be states that represent being within a possible execution of the BP, while other states may be considered to represent being outside of an execution of the BP. Optionally, for most steps in the input, following evaluation of each step of the most of the steps, the automaton does not arrive at an accepting state.

In some embodiments, at least some of the times the automaton reaches an accepting state occur following a certain subsequence of steps that corresponds to a nonconsecutive execution of the BP. In one example, the subsequence comprises first, second, and third steps; the first step is performed before the second step, the second step is performed before the third step, the first and third step are involved in the execution of the BP, while the second step is not involved in the execution of the BP. Thus, in this example the subsequence may be considered to correspond to a nonconsecutive execution of the BP. Optionally, the first and third steps are both associated with a certain value of an Execution-Dependent Attribute (EDA) and the second step is not associated with the certain value of the EDA. Optionally, the second step is associated with a value for the EDA, which is different from the certain value. For example, the first and third steps may describe operations involving a client associated with a first client ID, while the second step may describe an operation involved a client associated with a second client ID that is different from the first client ID.

The parameters 196 of the automaton that is run by the simulation module 194 may be generated, in some embodiments, based on examples of sequences of steps that correspond to executions of the BP (referred to herein as a positive set) and sequences of steps that do not correspond to executions of the BP (referred to herein as a negative set). Optionally, the parameters 196 include descriptions of the set Q, Σ, the function δ, q0, and F, which are described above. Optionally, the parameters 196 may be included in a model of the BP, such as the crowd-based model 118, the crowd-based model 175, or a model of a BP designated by some other reference numeral in this disclosure.

In one embodiment, the system further includes the example collector module 127, which is configured, in this embodiment, to collect a positive set (e.g., the positive set 173) comprising sequences of steps, each belonging to one or more streams of steps performed during interactions with instances of one or more software systems. Optionally, most of the sequences in the positive set correspond to executions of the BP. Additionally, a sequence corresponds to an execution of the BP if it comprises all of the steps involved in an execution of the BP. Optionally, the system may further include the negative example collector module 182, which is configured to select a negative set (e.g., the negative set 174) of sequences that do not correspond to executions of the BP. Optionally, the negative set comprises sequences of steps corresponding to executions of BPs that are different from the BP to which the sequences in the positive set correspond.

In one embodiment, at least some of the sequences included in the positive set correspond to nonconsecutive executions of the BP. For example, the at least some of the sequences may each include both steps that are involved in an execution of the BP and steps that are not involved in the execution of the BP, such as steps involved in a different execution of the BP and/or steps involved in an execution of a different BP.

In one embodiment, the system includes automaton generator module 198, which is configured to generate an automaton based on the positive and set of sequences and the negative set of sequences. Optionally, the automaton generator module 198 is part of, and/or is utilized by, the model trainer module 116. The reference Cook, Jonathan E., and Alexander L. Wolf “Discovering models of software processes from event-based data”, ACM Transactions on Software Engineering and Methodology (TOSEM) 7.3 (1998): 215-249, mentions some approaches for generating an automaton based on such positive and negative sets that may be utilized by the automaton generator module 198. Optionally, the automaton generator module 198 generates the parameters 196 to represent the automaton's functionality. Optionally, when the simulation module 194 utilizes with the parameters 196 generated by the automaton generator module 198, the automaton it implements recognizes most of the sequences belonging to the positive set and does not recognize most of the sequences belonging to the negative set.

In some embodiments, at least some of the sequences in the positive set, and optionally some of the sequences in the negative set, are previously identified sequences of steps corresponding to executions of the BP associated with a plurality of organizations. In one example, the positive set comprises at least first and second sequences that correspond to executions of the BP, which are associated with first and second organizations, respectively. The first and second organizations in this example are different from the certain organization whose activity is described in the stream 192.

It is to be noted that while the description above discusses an automaton that recognizes sequences corresponding to executions of the BP, those skilled in the art will recognize that similar automatons may be used to recognize executions of various BPs (when training data that includes examples of the different BPs is utilized). For example, different accepting states may be made to correspond to the various BPs; thus, the identity of the accepting state can be indicative of the identity of the BP to which a sequence of steps evaluated by the simulation module 194 corresponds. Additionally, in some embodiments, the system illustrated in FIG. 7 may utilize multiple sets of parameters, each used to recognize sequences corresponding to a different BP.

FIG. 8 illustrates steps that may be performed in one embodiment of a method for utilizing an automaton to identify a sequence corresponding to an execution of a BP. The steps described below may, in some embodiments, be part of the steps performed by an embodiment of a system illustrated in FIG. 7. In some embodiments, instructions for implementing the method described below may be stored on a computer-readable medium, which may optionally be a non-transitory computer-readable medium. In response to execution by a system including a processor and memory, the instructions cause the system to perform operations that are part of the method. Optionally, the methods described below may be executed by a system comprising a processor and memory, such as the computer illustrated in FIG. 25. Optionally, at least some of the steps may be performed utilizing different systems comprising a processor and memory. Optionally, at least some of the steps may be performed using the same system comprising a processor and memory.

In one embodiment, a method for utilizing an automaton to identify a sequence corresponding to an execution of a BP includes at least the following steps:

In Step 197a, monitoring interactions with an instance of a software system belonging to a certain organization and generating a stream of steps performed during the interactions. Optionally, the monitoring is performed by a monitoring agent such as the monitoring agent 102.

In Step 197b, simulating a running of an automaton on an input comprising the stream generated in Step 197a. Optionally, the simulation is performed with the simulation module 194. The automaton is configured to arrive at an accepting state following detection of an occurrence, in the input, of a subsequence corresponding to an execution of the BP. Optionally, the parameters that govern the behavior of the automaton are generated based on previously identified sequences of steps corresponding to executions of the BP, which comprise at least first and second sequences that correspond to executions of the BP associated with first and second organizations, respectively.

And in Step 197c, responsive to arrival at an accepting state following a certain subsequence of steps in the stream which corresponds to a nonconsecutive execution of the BP, generating an indication indicative of a detection of an execution of the BP. Optionally, the certain subsequence comprises first, second, and third steps; the first step is performed before the second step, the second step is performed before the third step, the first and third step are involved in the execution of the BP, while the second step is not involved in the execution of the BP.

In some embodiments, the parameters used to simulate the running of the automaton in Step 197b area generated based on training data comprising examples of sequences that correspond to executions of the BP and examples of sequences that do not correspond to executions of the BP. In these embodiments, the method described above may optionally include the following additional steps: receiving a positive set comprising sequences of steps belonging to one or more streams of steps performed during interactions with instances of one or more software systems, receiving a negative set of sequences of steps, and generating the automaton based on the positive and negative sets. Most of the sequences in the positive set correspond to executions of the BP and most of the sequences in the negative set do not correspond to executions of the BP. Additionally, the automaton recognizes most of the sequences belonging to the positive set and does not recognize most of the sequences belonging to the negative set. Optionally, at least some of the sequences included in the positive set correspond to nonconsecutive executions of the BP. For example, the at least some of the sequences each includes both steps that are involved in an execution of the BP and steps that are not involved in the execution of the BP, such as steps involved in a different execution of the BP and/or steps involved in an execution of a different BP. In one embodiment, the positive set may be the positive set 173, the negative set is the negative set 174, and the parameters 195 are the parameters of the automaton generated based on these two sets.

In one embodiment, collecting sequences for the positive set involves performing the following steps: receiving an indication indicative of steps in the one or more streams that are involved in a certain execution of the BP, selecting the steps involved in the certain execution from the one or more streams in order to form a sequence that is added to the positive set. Optionally, collecting the sequences in this embodiment is done utilizing the example collector module 127.

In some embodiments, instead of simulating the running of the automaton on an input comprising the stream generated in Step 197a, or in addition to that simulation, the method described above may involve a step of simulating the running of the automaton on candidate sequences selected from among the steps belonging to the stream generated in Step 197a. In these embodiments, the method described above may optionally include steps involving selecting, from among the steps belonging to the stream, candidate sequences of steps and simulating the running of the automaton on each of the candidate sequences. Optionally, selecting the sequences is done by the sequence parser module 122.

Selecting the candidate sequences may be done in different ways. In one embodiment, selecting the sequences involves identifying values of an Execution-Dependent Attribute (EDA) in at least some of the steps comprised in the streams and selecting the candidate sequences such that for each candidate sequence, the steps belonging to the candidate sequence are associated with the same value of the EDA. In another embodiment, selecting the candidate sequences may involve generating links between pairs of steps that are among steps belonging to the stream, and selecting the candidate sequences utilizing the links. At least some of the links are between pairs of steps that are not consecutively performed steps in the same stream, and for each pair of consecutive steps in a candidate sequence at least one of the following is true: the pair is a pair consecutive steps in a stream from among the streams, and the pair is linked by at least one of the links.

FIG. 9 illustrates one embodiment of a system configured to utilize a machine learning-based model to identify a sequence corresponding to an execution of a Business Processes (BP). The system includes at least the following modules: the sequence parser module 122, feature generator module 199, and predictor module 200. In some embodiments, the feature generator module 199 and/or predictor module 200 may be considered modules that belong to, and/or are utilized by, the BP-identifier module 126. The embodiment illustrated in FIG. 9 may be realized utilizing a computer, such as the computer 400, which includes at least a memory 402 and a processor 401. The memory 402 stores code of computer executable modules, such as the modules described above, and the processor 401 executes the code of the computer executable modules stored in the memory 402.

The sequence parser module 122 is configured, in one embodiment, to receive the one or more streams 120 of steps performed during interactions with an instance of a software system, which belongs to a certain organization. The sequence parser module 122 is configured to select, from among the one or more streams 120, the candidate sequences 124 of steps.

The feature generator module 199 is configured, in one embodiment, to receive a sequence of steps from among the candidate sequences 124 and to generate a plurality of feature values based on the sequence. Optionally, the plurality of feature values describe various aspects of the candidate sequences 124 and/or aspects of a context in which the steps the candidate sequences 124 were performed.

In one example, the plurality of feature values generated based on a sequence of steps comprise a feature value that is indicative of one or more of the following aspects: a certain transaction executed in one or more of the steps, a certain order of transactions executed in the steps, a certain screen presented in one or more of the steps, a certain order of screens presented in the steps, a certain field accessed in at least one of the steps, a certain order of accessing fields in one or more of the steps, a certain value entered in a field in at least one of the steps, a certain message received from a system as part of at least one of the steps.

In another example, the plurality of feature values generated based on a sequence of steps comprise a feature value that is indicative of one or more of the following: the number of steps in the sequence, the duration it took to perform the steps in the sequence, an identity of a user who performed a step from among the steps, a role of the user in an organization, an identity of a system on which one of the steps was performed, an identity of an organization to which belongs a user who performed one of the steps, an identity of an organization to which belongs a system on which at least one of the steps was performed, and a field of operations of the organization.

In yet another example, the plurality of feature values generated based on a sequence of steps comprise a feature value that is indicative of activity of the certain organization prior to when the sequence of steps was performed. For example, the plurality of feature value may include feature values describing the extent to which various BPs were executed prior to when the sequence was performed.

The predictor module 200 is configured, in one embodiment, to receive an input comprising a plurality of feature values generated, based on a sequence of steps, by the feature generator module 199. The predictor module 200 is further configured to utilize parameters 203 to calculate, based on the input comprising the plurality of feature values, a value indicative of whether the sequence corresponds to an execution of the BP. Optionally, the predictor module 200 assigns identifiers 201 to at least some of the candidate sequences 124 for which the calculated values indicate that they correspond to executions of the BP. Optionally, the parameters 203 may belong to a crowd-based model of the BP, such as the model 118 and/or a model designated with some other reference numeral in this disclosure.

Various machine learning-based approaches may be utilized, in different embodiments, to implement the predictor module 200. Optionally, the parameters 203 that are utilized by the predictor module 200 may include one or more of the following values: parameters of a neural network, parameters for a support vector machine, parameters of a naïve Bayesian model, logistic regression parameters, and parameters of a decision tree.

In one embodiment, the predictor module 200 is a classifier module, which is configured to use the parameters 203 to calculate the value, based on the input, that is indicative of a class to which the a sequence of steps belongs. For example, the predictor module 200 may utilize a neural network, support vector machine, a decision tree, or logistic regression to calculate a value that is indicative a class to which the sequence belongs (e.g., a class of sequences that correspond to the BP or a class of sequences that do not correspond to the BP).

In another embodiment, the predictor module 200 is configured to calculate, based on the input, a value indicative of a probability that the sequence corresponds to an execution of the BP. For example, the predictor module 203 may implement a naïve Bayesian classifier or utilize a logistic regression model.

In some embodiments, determining whether sequence correspond to executions of the BP is done based on the magnitude of the value calculated based on the input. Optionally, the value reaches a threshold is indicative of the fact that the sequence (upon which the input is based) corresponds to an execution of the BP. In one example, reaching the threshold may correspond to at least a certain extent of affinity of the sequence to a class of sequences that correspond to executions of the BP. In another example, reaching the threshold may correspond to a certain similarity between the sequence and a typical sequence of steps that is performed when executing the BP (e.g., a pattern of the BP). Herein, when a value reaches a threshold it means that the value equals the threshold or exceeds it.

Some of the candidate sequences 124 that are assigned the identifiers 201 may include steps that are not performed as part of the BP to which they correspond; as such, these candidate sequences may be considered to correspond to nonconsecutive executions of the BP. In one example, a candidate sequence, from among the candidate sequences 124, comprises first, second, and third steps that belong to a certain stream from among the one or more streams. The first step was performed before the second step and the second step was performed before the third step. Additionally, the first and third step were performed as part of an execution of the first BP while the second step was not performed as part of an execution of the first BP. Thus, in this example the candidate sequence may be considered to correspond to a nonconsecutive execution of the first BP. Optionally, the first and third steps are both associated with a certain value of an Execution-Dependent Attribute (EDA) and the second step is not associated with the certain value of the EDA. Optionally, the second step is associated with a value for the EDA, which is different from the certain value. For example, the first and third steps may describe operations involving a client associated with a first client ID, while the second step may describe an operation involved a client associated with a second client ID that is different from the first client ID.

In some embodiments, the plurality of features generated based on the sequence by the feature generator module 199 include at least some features that may be useful for identifying sequences corresponding to nonconsecutive executions of the BP. In one example, the plurality of features comprise a feature that is indicative of whether a certain two or more steps (e.g., steps representing two or more transactions) are associated with the same value for a certain EDA (e.g., the same customer number). In another example, the plurality of features comprise a feature that is indicative of the duration that elapsed between when a certain pairs of steps were performed; in some cases, certain steps may involve a certain period of waiting (e.g., in order to receive a confirmation from a remote site), thus the certain delay may be expected. In the meantime, it is possible that some other steps, which may not necessarily correspond to the same execution of the BP, were performed.

In some embodiments, the system described above may include one or more monitoring agents configured to generate the one or more streams 120. Optionally, each monitoring agent generates a stream comprising steps performed as part of an interaction with an instance of a software system. Additional discussion regarding monitoring agents and the data they examine/produce may be found in this disclosure at least in Section 3—Monitoring Activity.

The parameters 203 may be generated, in some embodiments, based on examples of sequences of steps that correspond to executions of the BP (referred to herein as a positive set) and sequences of steps that do not correspond to executions of the BP (referred to herein as a negative set). In one embodiment, the system further includes the example collector module 127, which is configured, in this embodiment, to collect a positive set (e.g., the positive set 173) comprising sequences of steps belonging to one or more streams of steps performed during interactions with instances of one or more software systems. Optionally, most of the sequences in the positive set correspond to executions of the BP. Additionally, a sequence corresponds to an execution of the BP if it comprises all of the steps involved in an execution of the BP. Optionally, the system may further include the negative example collector module 182, which is configured to select a negative set (e.g., the negative set 174) of sequences that do not correspond to executions of the BP. Optionally, the negative set comprises sequences of steps corresponding to executions of BPs that are different from the BP to which the sequences in the positive set correspond. Optionally, at least some of the sequences included in the positive set correspond to nonconsecutive executions of the BP. For example, the at least some of the sequences may each include both steps that are involved in an execution of the BP and steps that are not involved in the execution of the BP, such as steps involved in a different execution of the BP and/or steps involved in an execution of a different BP.

In some embodiments, at least some of the sequences in the positive set described above, and optionally some of the sequences in the negative set, are previously identified sequences of steps corresponding to executions of the BP associated with a plurality of organizations. In one example, the positive set comprises at least first and second sequences that correspond to executions of the BP, which are associated with first and second organizations, respectively. The first and second organizations in this example are different from the certain organization whose activity is described in the one or more streams 120.

In some embodiments, the system may optionally include machine learning trainer module 204, which is configured to generate the parameters 203 utilizing the positive and negative sets. Optionally, the machine learning trainer module 204 is part of, and/or is utilized by, the model trainer module 116. Optionally, the machine learning trainer module 204 utilizes samples, generated by the feature generator module 199, with each sample comprising a plurality of feature values generated based on a sequence from among the positive set or the negative set. Optionally, the machine learning trainer module 204 provides the samples as input to a learning algorithm in order to generate the parameters 203. For example, the samples may be used to learn parameters of a neural network, parameters of support vector machine, etc.

It is to be noted that while the description above discusses embodiments of a system that may be used to identify sequences corresponding to executions of the BP, those skilled in the art will recognize that the system may be used to recognize executions of various BPs. For example, some machine learning-based models may involve multiple classes, with each class corresponding to a different BP. Additionally, in some embodiments, the system illustrated in FIG. 9 may utilize multiple sets of parameters, each corresponding to a different BP.

FIG. 10 illustrates steps that may be performed in one embodiment of a method for utilizing a machine learning-based model to identify a sequence corresponding to an execution of a BP. The steps described below may, in some embodiments, be part of the steps performed by an embodiment of a system illustrated in FIG. 9. In some embodiments, instructions for implementing a method, such as the method described below, may be stored on a computer-readable medium, which may optionally be a non-transitory computer-readable medium. In response to execution by a system including a processor and memory, the instructions cause the system to perform operations that are part of the method. Optionally, the methods described below may be executed by a system comprising a processor and memory, such as the computer illustrated in FIG. 25. Optionally, at least some of the steps may be performed utilizing different systems comprising a processor and memory. Optionally, at least some of the steps may be performed using the same system comprising a processor and memory.

In one embodiment, a method for utilizing a machine learning-based model to identify a sequence corresponding to an execution of a BP includes at least the following steps:

In Step 206b, receiving, by a system comprising a processor and memory, one or more streams of steps performed during interactions with instances of a software system, which belongs to a certain organization, and selecting, from among the one or more streams, candidate sequences of steps. Optionally, the candidate sequences are selected utilizing the sequence parser module 122.

In Step 206c, generating, for each sequence among the candidate sequences, a plurality of feature values based on the sequence. Optionally, the plurality of feature values are generated by the feature generator module 199.

And in Step 206d, utilizing a model of the BP to calculate, based on an input comprising the plurality of feature values generated for each sequence among the candidate sequences, a value indicative of whether the sequence corresponds to an execution of the BP. Optionally, the model comprises the parameters 203 described above. Optionally, the model is generated based on sequences corresponding to previous executions of the BP, which comprise first and second sequences that are associated with first and second organizations, respectively. Optionally, the first and second organizations are different from the certain organization.

In one embodiment, the method described above may optionally include Step 206a that involves monitoring the interactions with an instance of the software system and generating the one or more streams received in Step 206b. Optionally, the monitoring involves at least one of the following types of monitoring: internal monitoring (e.g., by an internal monitoring agent), and interface monitoring (e.g., by an interface monitoring agent).

In some embodiments, the method described above may involve a step of generating the model of the BP, which is utilized in Step 206d. Optionally, generating the model involves utilization of samples, each of which comprises a plurality of feature values generated based on a sequence of steps. Some of the samples are generated based on sequences corresponding to executions of the BP (i.e., sequences belonging to the positive set). Additionally, some of the samples are generated based on sequences that do not correspond to executions of the BP (i.e., sequences belonging to the negative set). Optionally, the positive set comprises the first and second sequences mentioned in Step 206d. Optionally, most of the sequences in the positive set correspond to executions of the BP, and most of the sequences in the negative set do not correspond to executions of the BP. Optionally, generating the model comprises generating at least one of the followings sets of parameters: parameters of a neural network, parameters for a support vector machine, parameters of a naïve Bayesian model, logistic regression parameters, and parameters of a decision tree.

In one embodiment, generating the model involves collecting sequences belonging to the positive set from among streams of steps performed during interactions with additional instances of the software system. Optionally, collecting the sequences is done utilizing the example collector module 127. Optionally, collecting at least some of the sequences involves user provided indications. For example, collecting a certain sequence in the positive set may involve receiving an indication indicative of certain steps in the streams that are involved in a certain execution of the BP and selecting the certain steps from the streams in order to form the certain sequence. In another embodiment, generating the model further involves collecting at least some of the sequences belonging to the negative set from among the steps belonging to the streams. Optionally, collecting these sequences is done utilizing the negative example collector 182. Optionally, sequences of steps corresponding to executions of BPs that are different from the BP may be utilized for the negative set.

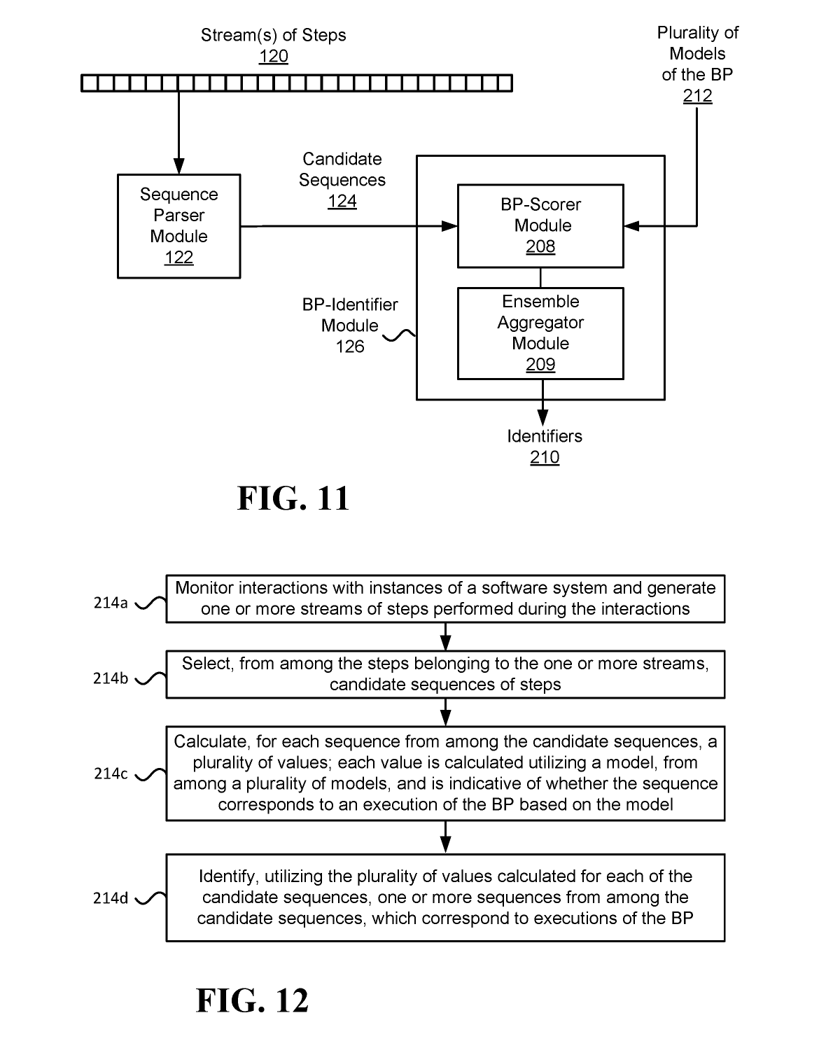

FIG. 11 illustrates one embodiment of a system configured to perform an ensemble-based identification of sequences corresponding to executions of a Business Process (BP). The system includes at least the following modules: the sequence parser module 122, BP-scorer module 208, and ensemble aggregator module 209. In some embodiments, the BP-scorer module 208 and/or the ensemble aggregator module 209 may be considered modules that belong to, and/or are utilized by, the BP-identifier module 126. The embodiment illustrated in FIG. 11 may be realized utilizing a computer, such as the computer 400, which includes at least a memory 402 and a processor 401. The memory 402 stores code of computer executable modules, such as the modules described above, and the processor 401 executes the code of the computer executable modules stored in the memory 402.

The sequence parser module 122 is configured, in one embodiment, to receive the one or more streams 120 of steps performed during interactions with an instance of a software system, which belongs to a certain organization. The sequence parser module 122 is configured to select, from among the one or more streams 120, the candidate sequences 124 of steps.

The BP-scorer module 208 is configured to utilize a model of the BP to calculate, for each sequence from among the candidate sequences 124, a value indicative of whether the sequence corresponds to an execution of the BP based on the model. Optionally, the BP-scorer module 208 is provided with plurality of models 212 of the BP and is utilized to calculate, for each of the candidate sequences, a plurality of values (where each value is calculated utilizing a model from among the plurality of models 212). Optionally, the plurality of models 212 comprise models generated based on data collected from multiple organizations, with each model being generated based on data collected from a certain organization from among the plurality of organizations. For example, in some embodiments, the plurality of models 212 comprises at least first and second models of the BP, generated based on sequences corresponding to executions of the BP that are associated with first and second organizations, respectively. In these embodiments, the certain organization is different from the first and second organizations.

It is to be noted that, in some embodiments, the BP-scorer module 208 may be implemented using the BP-identifier 126. That is, the BP-scorer module 208 may have functionality attributed herein to the BP-identifier module 126; in this case, separate module names and reference numerals are employed herein for the sake of avoiding including a description of nested, self-referring modules in the disclosure.

In different embodiments, the plurality of models 212 of the BP may comprise different types of models, which are employed for different approaches described in this disclosure for identifying sequences that correspond to executions of BPs. In some embodiments, the plurality of models 212 are made up of models of the same type, while in other embodiments, the plurality of models 212 comprise models of multiple types.

In one embodiment, the plurality of models 212 comprise a model that includes a pattern describing a sequence of steps involved in the execution of the BP. For example, the model may include one or more of the patterns 189. Optionally, in this embodiment, the BP-scorer module 208 may include and/or utilize the distance calculator module 186 and/or the assignment module 187 in order to calculate the value indicative of whether the sequence corresponds to an execution of the BP. Utilization of these modules is described in more detail in the discussion regarding embodiments modeled according to the system illustrated in FIG. 5.

In another embodiment, the plurality of models 212 comprise a model that describes an automaton configured to recognize an execution of the BP based on a sequence of steps. For example, the model may include the parameters 196. Optionally, in this embodiment, the BP-scorer module 208 may include and/or utilize the simulation module 194, which is discussed in more detail in the discussion regarding embodiments modeled according to the system illustrated in FIG. 7.

In yet another embodiment, the plurality of models 212 comprise a model that comprises parameters used by a machine learning-based predictor, such as the predictor module 200. For example, the model may include the parameters 203. Optionally, in this embodiment, the BP-scorer module 208 may include and/or utilize the feature generator module 199 and/or the predictor 200. Utilization of these modules is described in more detail in the discussion regarding embodiments modeled according to the system illustrated in FIG. 9.

The ensemble aggregator module 209 is configured, in one embodiment, to utilize values calculated by the BP-scorer module 208 in order to identify, from among the candidate sequences, one or more sequences that correspond to executions of the BP. Optionally, the ensemble aggregator module 209 evaluates, for each sequence among the candidate sequences 124, a plurality of values calculated for the sequence by the BP-scorer module 208 utilizing a model from among a plurality of models 212. Optionally, the ensemble aggregator module 209 assigns identifiers 210 to at least some of the candidate sequences 124 for which the corresponding plurality of values indicate that they correspond to executions of the BP. Optionally, the identification of sequences corresponding to executions of the BP is done such that only some, but not all of the candidate sequences 124 are identified. For example, in some embodiments, most of the candidate sequences 124 are not identified as corresponding to executions of the BP.

In one embodiment, the ensemble aggregator module 209 is configured to identify a sequence as corresponding to an execution of the BP when at least a certain proportion of the plurality of values calculated for the sequence reaches a threshold, and not to identify a sequence as corresponding to an execution of the BP when the proportion of the plurality of values calculated for the sequence that reaches the threshold is below the certain proportion. Optionally, different thresholds may be utilized for different models from among the plurality of models 212. Optionally, when a value calculated for a sequence based on the model reaches the threshold, it means that with respect to the model (and an organization to which the model corresponds), the sequence corresponds to an execution of the BP. In one example, the certain proportion is at least 50%. Thus, in this example, a sequence from the candidate sequences 124 is identified by the ensemble aggregator module 209 as corresponding to an execution of the BP if, based on individual determinations according to each of a majority of the plurality of models 212, the sequence corresponds to an execution of the BP.

In another embodiment, the ensemble aggregator module 209 is configured to identify a sequence as corresponding to an execution of the BP when at least a certain number of the plurality of values calculated for the sequence reaches a threshold. Optionally, the certain number is one. Alternatively, the certain number may be greater than one, such as at least two. Optionally, when a value calculated for a sequence based on the model reaches the threshold, it means that with respect to the model (and an organization to which the model corresponds), the sequence corresponds to an execution of the BP. Thus, in one example, the ensemble aggregator module 209 may be configured to identify a sequence as corresponding to an execution of the BP if, based on at least one of the plurality of models 212, the sequence corresponds to an execution of the BP.

In some embodiments, the ensemble aggregator module 209 may assign weights to values from among the plurality of values calculated for a sequence based on which of the plurality of models 212 were utilized to calculate each of the values. These weights can then be utilized in order to give more importance to certain values from among the plurality of values when it comes to determining whether a sequence corresponds to an execution of the BP. For example, the weights may be used to calculate a value that is a weighted average of the plurality of values (and the determination regarding the sequence is made according to the weighted average). Weights may be assigned by the ensemble aggregator module 209 in various ways.

In one embodiment, weights may be determined according to factors such as the accuracy of each of the models (e.g., determined using a test set of sequences) and/or the amount of data used to generate each of the models. In this embodiment, the more accurate a model and/or the more data used to generate the model, the higher the weight assigned to a value calculated utilizing the model. Optionally, weights may be determined utilizing various ensemble learning techniques such as boosting, Bayesian parameter averaging, and/or Bayesian model combination. Optionally, the weights are set such that they yield more accurate BP identifications for the certain organization. For example, the weights may be calculated utilizing a training set of sequences that correspond to executions of the BP (and/or other BPs) by the certain organization.

In another embodiment, the ensemble aggregator module 209 is further configured to weight each value, from among the plurality of values calculated for a sequence from among the candidate sequences 124, based on a similarity between an organization corresponding to a model used to calculate the value and the certain organization. Optionally, the more similar the organization to the certain organization, the higher the weight of the value. Herein, an organization may be considered to correspond to a model if the model is generated based on sequences of steps corresponding to executions of the BP that are associated with the organization.

Similarity between organizations may be determined in different ways. In one embodiment, similarity between organizations is determined based on a comparison of profiles of the organizations. Optionally, a profile of an organization is indicative of at least some of the following attributes related to the organization: the field of operations of the organization, the size of the organization, a country of operations of the organization, an identifier of a certain supplier of the organization, an identifier of a certain customer of the organization, an identifier a software system utilized by the organization, an identifier of a version of a package installed on a software system utilized by the organization. In another embodiment, similarity between organizations is determined based on a comparison of activity profiles of the organizations. Optionally, each activity profile generated for an organization is indicative of the extent at least some of BPs were executed on one or more instances of the software system, which belong to the organization.

In some embodiments, the system described above may include one or more monitoring agents configured to generate the one or more streams 120. Optionally, each monitoring agent generates a stream comprising steps performed as part of an interaction with an instance of a software system. Additional discussion regarding monitoring agents and the data they examine/produce may be found in this disclosure at least in Section 3—Monitoring Activity.

FIG. 12 illustrates steps that may be performed in one embodiment of a method for performing an ensemble-based identification of sequences corresponding to executions of a BP. The steps described below may, in some embodiments, be part of the steps performed by an embodiment of a system illustrated in FIG. 11. In some embodiments, instructions for implementing a method, such as the method described below, may be stored on a computer-readable medium, which may optionally be a non-transitory computer-readable medium. In response to execution by a system including a processor and memory, the instructions cause the system to perform operations that are part of the method. Optionally, the method described below may be executed by a system comprising a processor and memory, such as the computer illustrated in FIG. 25. Optionally, at least some of the steps may be performed utilizing different systems comprising a processor and memory. Optionally, at least some of the steps may be performed using the same system comprising a processor and memory.

In one embodiment, a method for performing an ensemble-based identification of sequences corresponding to executions of a BP includes at least the following steps:

In Step 214b, receiving one or more streams of steps performed during interactions with instances of one or more software systems and selecting, from among steps belonging to the one or more streams, candidate sequences of steps.

In Step 214c, calculating, for each sequence from among the candidate sequences, a plurality of values; each value is calculated utilizing a model, from among a plurality of models, and is indicative of whether the sequence corresponds to an execution of the BP based on the model. Optionally, the plurality of models comprise first and second models of the BP, generated based on sequences corresponding to executions of the BP that are associated with first and second organizations, respectively. Optionally, the plurality of values are calculated by the BP-Scorer module 208.

And in Step 214d, utilizing the plurality of values calculated for each of the candidate sequences to identify, from among the candidate sequences, one or more sequences that correspond to executions of the BP. Optionally, the ensemble aggregator module 209 is utilized to identify the one or more sequences based on the plurality of values.

In one embodiment, the method described above may optionally include Step 214a that involves monitoring the interactions with the instances of a software system and generating the one or more streams received in Step 214b. Optionally, the monitoring involves at least one of the following types of monitoring: internal monitoring (e.g., by an internal monitoring agent), and interface monitoring (e.g., by an interface monitoring agent).

Identifying the one more sequences in Step 214d may be done in different ways. In one embodiment, Step 214d involves identifying a sequence as corresponding to an execution of the BP when at least a certain proportion of the plurality of values calculated for the sequence reaches a threshold, and not identifying a sequence as corresponding to an execution of the BP when the proportion of the plurality of values calculated for the sequence that reaches the threshold is below the certain proportion. Optionally, different thresholds may be utilized with different models from among the plurality of models. In another embodiment, Step 214d involves weighting each value, from among the plurality of values calculated for a sequence from among the candidate sequences, based on a similarity between an organization corresponding to a model used to calculate the value and the certain organization. Optionally, the more similar the organization to the certain organization, the higher the weight of the value.

Selecting the candidate sequences in Step 214b may be done in different ways in different embodiments, as discussed in more detail in the discussion regarding FIG. 1. In one example, Step 214b may involve identifying values of an Execution-Dependent Attribute (EDA) in at least some of the steps comprised in the one or more streams and selecting the candidate sequences such that for each candidate sequence, the steps belonging to the candidate sequence are associated with the same value of the EDA. In another example, Step 214b may involve: (i) generating links between pairs of steps that are among steps belonging to the one or more streams (where at least some of the links are between pairs of steps that are not consecutively performed steps in the same stream); and (ii) selecting the candidate sequences utilizing the links. Optionally, for each pair of consecutive steps in a candidate sequence at least one of the following is true: the pair is a pair consecutive steps in a stream from among the streams, and the pair is linked by at least one of the links.

In some embodiments, selecting candidate sequences from one or more streams may be done by employing a mechanism in which pairs of steps from among the one or more streams are connected by links. A link from a first step to a second step signifies that the first step is to be performed before the second step. Conceptually, such links may be considered to be part of a graphical representation in which one or more streams are represented as a graph G=(V,E). In this example, V is a set of vertices corresponding to at least some of the steps belonging to the one or more streams (with each step corresponding to a vertex), and E is a set of directed edges between pairs of vertices in V. There are two types of directed edges that may be added to E: (i) edges between pairs of consecutively performed steps (i.e., a trivial edge between a first step in a stream and a second step that directly follows the first step in the stream), and (ii) edges between nonconsecutively performed pairs of steps (e.g., an edge that connects between two nonconsecutively performed steps in the same stream or an edge that connects between a first step in a first stream and a second step in a second stream). The second type of edges may be considered “nontrivial” edges. Optionally, for each directed edge in E from a first step to a second step, the time at which the first step was performed is not after the time at which the second step was performed. Optionally, the first step is performed before the second step.

As described above, directed edges between pairs of steps may be referred to as “links” between steps, and determining which steps to link may be done by a module referred to herein as a link generator module (e.g., link generator module 150). In some embodiments, links are assumed to be possible between many (if not all) pairs of consecutively performed steps, and the task of adding links involves determining which pairs of nonconsecutively performed steps are to be linked.

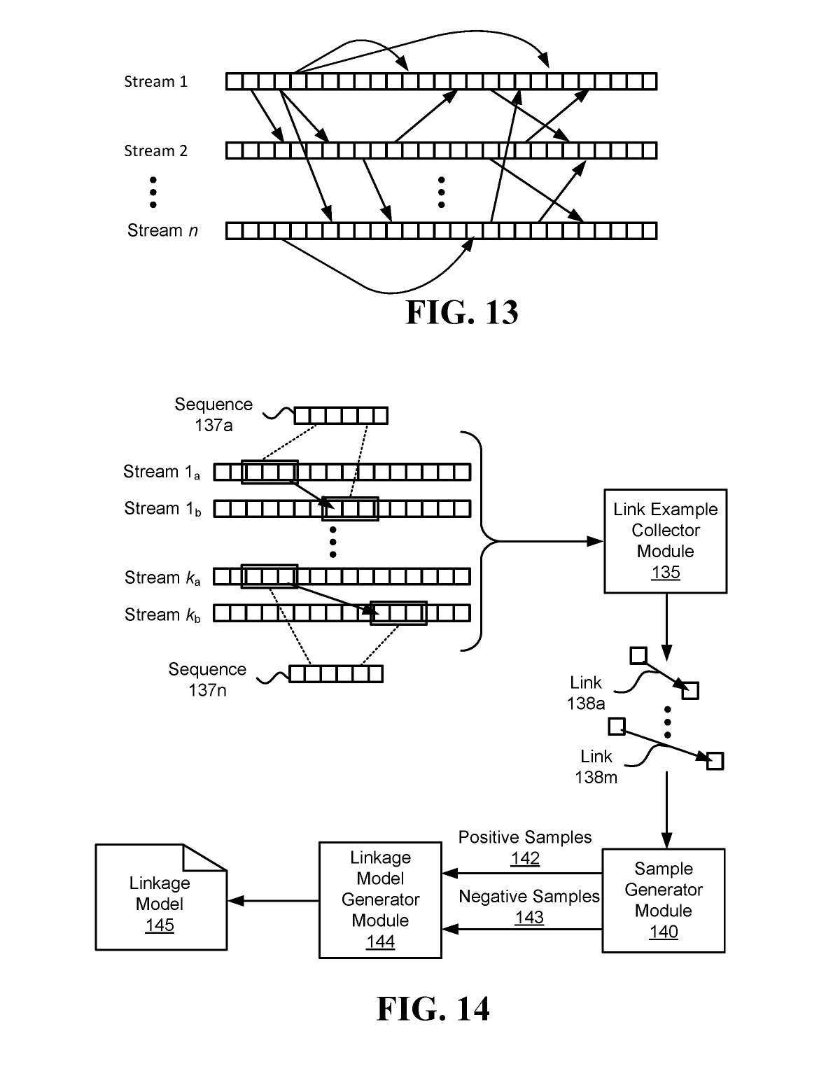

FIG. 13 illustrates an example of linkage of nonconsecutively performed steps. In the illustration, each stream from among n streams is represented by a sequence of connected squares. Links between nonconsecutively performed steps are illustrated as arrows between pairs of steps, each pair comprising steps that may be in the same stream or in different streams.

When sequences of steps are selected (e.g., by the sequence parser module 122) utilizing the mechanism in which the one or more streams may represented by the graph G described above (or some equivalent scheme), selecting sequences may be considered a similar process to choosing sub-paths in the graph G. Thus, each selected sequence comprises steps that are linked; each consecutive pair of steps in a selected sequence are either a consecutively performed pair of steps from a certain stream from among the one or more streams, or a nonconsecutively performed pair of steps that are connected via link (i.e., steps representing a nontrivial edge in a graph representing the one or more streams).

Due to the large number of additional steps to which each step may be linked, in some embodiments, links between nonconsecutively performed steps are created judiciously. That is, when links are added from a certain step from a certain stream, they typically connect the certain step to only a portion of the steps in the certain stream and/or only a portion of steps from other streams from among the one or more streams. Thus, while theoretically, the number of links between steps in the one or more streams may be quadratic (in the total number of steps in the one or more streams), in practice, in many embodiments, the number of links between steps in the one or more streams may be smaller.

A judicious creation of links between nonconsecutively performed steps that appear in the one or more streams may involve a process in which generating links is done based on certain linking rules. Optionally, a linking rule may be utilized to identify pairs of steps that may be linked and/or pairs of steps should not be linked. Following are some examples of various types of rules that may be utilized in embodiments described herein to link steps.

In one embodiment, determining which pairs of steps to link is done utilizing a linking rule related to a certain maximum difference between when linked steps are performed. In one example, a link may be created from a first step to a second step if the second step is performed at most one hour after the first step is performed. In another example, the maximum difference between when the first and second steps are performed may be larger, such as at most a day or at most a week between when the first and second steps are performed.

In another embodiment, determining which pairs of steps to link may be done utilizing a linking rule related to the identity of users who performed the steps and/or software systems on which the steps were performed. In one example, links between pairs of steps may be created when the pairs of steps are performed by the same user. In another example, links between pairs of steps may be created when the pairs of steps were performed while interacting with the same instance of a software system and/or when the pairs of steps were performed while interacting with instances of a certain software system.

In yet another embodiment, determining which pairs of steps to link is done utilizing a linking rule related to the content of the steps considered for linkage. Optionally, the content of a step comprises values of various attributes. In one example, links between pairs of steps may be created when the pairs of steps involve a certain order of operations. For example, a link from a first step to a second step may be created when the first step involves a certain first operation (e.g., clicking a certain button) and the second step involves a certain second operation (e.g., entering a value into a certain field). In another example, links between pairs of steps may be created when the pairs of steps involve a certain order of transactions. For example, a link from a first step to a second step may be created when the first step involves executing a certain first transaction (e.g., a transaction identified by a specific first code) and the second step involves executing a certain second transaction (e.g., a transaction identified by a specific second code).

In some embodiments, determining which pairs of steps to link may be based on identifying a relationship between values of an Execution-Dependent Attribute (EDA), which appear in descriptions of the steps belonging to the pairs (e.g., as part of the attributes corresponding to each of the linked steps). Examples of types of values that may be considered an EDA include: a mailing address, a Universal Resource Locator (URL) address, an Internet Protocol (IP) address, a phone number, an email address, a social security number, a driving license number, an address on a certain blockchain, an identifier of a digital wallet, an identifier of a client, an identifier of an employee, an identifier of a patient, an identifier of an account, an order number. Additionally or alternatively, in some embodiments, a value of an EDA may be based on input and/or output that is part of the step (e.g., a value entered to a certain field on a certain screen or a value of certain system message). Additionally or alternatively, in some embodiments, a value of an EDA may be based on attributes related to the circumstances involved in execution of a step such as: a date associated with the certain execution of the step, a time associated with the execution of the step, an identifier of a user who performed the step, an identifier of a terminal used by the user to perform the step, and identifier of a system involved in performing the step, an operating system identifier of a process involved in performing the step, and an operating system identifier of a thread involved in performing the step.

An EDA may involve values that are provided by a user (e.g., a value of a certain field in a certain screen) and/or a software system with which the user interacts (e.g., content of a system message). As used herein, an EDA does not usually have the same value in all executions of a BP. For example, in a BP that involves generating a sales order, the customer name will typically not be the same in all executions of the BP (assuming that the same customer is not involved in all sales). In some embodiments, an EDA may have a different value in most executions of a BP by design, for example, the EDA may be based on meta-data such as a process ID or a thread ID, which are typically different when programs are executed at different times.

There are various ways in which values of EDAs may be utilized in rules for linking pairs of steps. In one example, a rule for generating a link from a first step to a second step may involve descriptions of the first and second steps indicating that the first step and the second step have the same value for a certain EDA (e.g., the same order ID). In another example, a rule for generating a link from a first step to a second step may involve descriptions of the first and second steps indicating that a first value of a certain EDA in the first step may have some other relationship to a second value of the certain EDA in the second step, such as the first value being greater or smaller than the second value. For example, a link between first and second steps may be generated when a shipment date in the first step is earlier than a shipment date in the second step.

It is to be noted that the examples given above for various types of rules for linking pairs of steps may be considered, in some embodiments, as prototypes of rules. In these embodiments, at least some of the rules utilized for linking pairs of steps involve combinations of the prototypes of rules mentioned above. For example, a rule may involve linking a first step to a second step when: (i) the first step was performed at most one hour before he second step, (ii) the first step involved a certain first transaction and the second step involved a certain second transactions, and (iii) the first and second steps involved the same value for a certain EDA (e.g., the same order number). Furthermore, these examples describe some of the considerations that may be utilized by a link generator module to determine whether a pair of steps, from the same stream or from different streams, should be linked. In some embodiments, these considerations may be represented as feature values that correspond to the linking rules. The feature values may be utilized by the link generator module to generate the links, as described in more detail further below.

Generating rules for linking pairs of steps that appear in one or more streams may be done in various ways. In some embodiments, at least some rules for linking pairs of steps that appear in the one or more streams are manually specified. For example an expert may define, based on his or her experience, rules that correspond to links between nonconsecutively performed steps that belong to a sequence of steps corresponding to an execution of a BP. In other embodiments, at least some rules for linking pairs of steps that appear in the one or more streams are generated from evaluation of descriptions of BPs such as documentation of a BP or a model of the BP. In yet other embodiments, a model may be generated based on examples of pairs of steps that should be linked (e.g., pairs of nonconsecutively performed steps from sequences corresponding to executions of BPs); such a model may be referred to herein as a “linkage model”. In some embodiments, the model describes one or more rules that may be used to determine whether a pair of steps should be linked. In other embodiments, the model may include parameters of a machine learning-based model that may be used to calculate, based on feature values describing a pair of steps, a value indicative of whether the pair of steps should be linked.

Following are descriptions of embodiments of a system configured to generate a model for linking between steps performed when executing a Business Process (BP). In one embodiment, the model may be a linkage model corresponding to a certain BP, which means that it is primarily generated and/or utilized for linking pairs of steps in sequences corresponding to executions of the certain BP. Such a model may be referred to herein as being a “specific model” or a “specific linkage model”. In another embodiment, the model may be a linkage model corresponding to multiple BPs, which means that it is generated and/or utilized for linking pairs of steps in sequences corresponding to executions of various BPs. Such a model may be referred to herein as being a “general model” or a “general linkage model”. The nature of the model, such as whether it is to be considered more specific or general, may be determined based on the composition of examples used to generate it, as discussed in more detail below.

FIG. 14 illustrates one embodiment of a system configured to generate a model for linking between steps performed when executing a BP (i.e., a “linkage model”). The system includes at least the following module: link example collector module 135, sample generator module 140, and linkage model generator module 144 that generates linkage model 145.

The link example collector module 135 is configured, in one embodiment, to receive sequences of steps (e.g., sequences 137a to 137n) selected from among steps belonging to streams of steps performed during interactions with instances of one or more software systems. In one embodiment, each of the sequences corresponds to an execution of a certain BP. Optionally, in this embodiment, the linkage model 145 may be specific linkage model for the certain BP. In another embodiment, each of the sequences corresponds to an execution of a BP from among a plurality of BPs. Additionally, for each BP from among the plurality of BPs, at least some of the sequences correspond to executions of that BP. Optionally, in this embodiment, the linkage model 145 may be a general linkage model for BPs.

It is to be noted that while FIG. 14 illustrates the sequences 137a to 137n as each coming from a pair of streams from among k pairs of streams, this is not necessarily the case for all sequences. Some sequences may include steps that come from a single stream (e.g., a sequence comprising two separated, nonconsecutively performed steps in a stream), while some sequences may include steps from more than two. Additionally, as illustrated, each sequence includes one link between nonconsecutively performed steps, however, some sequences may include more than one link. Furthermore, as illustrated, a single sequence is generated from each pair of streams. However, in some embodiments, a stream of steps may include steps that may be part of multiple sequences (e.g., the stream may include steps belonging to multiple executions of one or more BPs).

The link example collector module 135 is also configured, in one embodiment, to select examples of links between pairs of steps. Optionally, at least some of the examples of links are links between pairs of steps from the sequences 137a to 137n. Each pair steps from a sequence comprises first and second steps such that, in the sequence, the second step directly follows the first step. Optionally, the second step may also follow the first step in a stream in which the two steps appear (in which case the first and second steps may be considered consecutively performed steps). Alternatively, the second step does not follow the first step in the stream in which the first step appears. In this case, the first and second steps are considered nonconsecutively performed steps. Optionally, for first and second steps from a sequence that are nonconsecutively performed steps, at least one of the following is true: (i) there is a third step that appears in the same stream as the first and seconds steps, the third step is performed after the first step and before the second step, but the third step does not appear in the sequence, and (ii) the first step belongs to a first stream and the second step belongs to a second stream. Examples of links between pairs of nonconsecutively performed pairs of steps selected in one embodiment by the link example collector module 135 are illustrated as the links 138a to 138m in FIG. 14.

The sample generator module 140 is configured, in one embodiment, to generate samples corresponding to links between pairs of steps. Each generated sample that corresponds to a link between a pair of steps comprises one or more feature values describing properties of the link from a first step of the pair to a second step of the pair, which is performed after the first step. Optionally, the first and second steps belong to the same stream. In this case, the first and second steps may be either one step directly followed by the other (i.e., consecutively performed steps) or there may be one or more steps in the stream that were performed between the two steps (i.e., the first and second steps may be considered to be nonconsecutively performed steps). Alternatively, the first and second steps may belong to different streams. In this case, the first and second steps may also be considered to be nonconsecutively performed steps.

There may be different relationships between the first and second steps of a pair of linked steps. In one example, the first and second steps are performed by the same user (though not necessarily one directly after the other). In another example, the first step is performed by a first user while the second step is performed by a second user, which is different from the first user. In yet another example, the first step is performed as part of an interaction with a first instance of a certain software system and the second step is performed as part of an interaction with a second instance of the certain software system, which is different from the first instance. In still another example, the first step is performed as part of an interaction with an instance of a first software system and the second step is performed as part of an interaction with an instance of a second system, which is different from the first software system. And in still another example, the first step is performed as part of an interaction with an instance of a software system belonging to a first organization and the second step is performed as part of an interaction with an instance of a software system that belongs to a second organization, which is different from the first organization.

The samples generated by the sample generator module 140 include positive samples 142. The positive samples 142 are samples corresponding to links from among the examples of links selected by the link example collector module 135. Thus, the positive samples 142 include sets of feature values that correspond to cases in which pairs of steps should in fact be linked. Optionally, at least some of the positive samples 142 correspond to links between consecutively performed steps. Optionally, at least some of the positive samples 142 correspond to links between nonconsecutively performed steps (e.g., the links 138a to 138m).

In addition to the positive samples 142, in some embodiments, the samples generated by the sample generator module 140 include negative samples 143. The negative samples 143 are samples corresponding to links between pairs of steps that do not follow one another in a sequence corresponding to an execution of a BP. In one example, at least some of the pairs of steps upon which the negative samples 143 are based are pairs of randomly selected steps from one or more streams of steps. In another example, at least some of the pairs of steps upon which the negative samples 143 are based are pairs in which the first step of each pair is involved in an execution of a first BP and the second step of the pair is involved in an execution of a second BP, which is different from the first BP. In still another example, at least some of the pairs of steps upon which the negative samples 143 are based are pairs in which the first step of each pair belongs to a first stream, which includes steps involving interactions with a first instance of a first software system, and the second step the pair belongs to a second stream, which includes steps involving interactions with a second instance of a second system.

Various types of feature values that may be utilized in embodiments described herein to represent a link between a first step and a second step. At least some of the feature values that are used may described properties of one or both of the steps being linked. Some examples of such properties may include: (i) an identity of a transaction performed in the first and/or second steps, (ii) a value entered in the first and/or second steps, (iii) a value of an EDA that is an attribute of the first and/or second steps, and more. Some features may be used to compare two steps being linked. For example, a feature may be indicative of whether the first and second steps have the same value for an EDA. In another example, a feature value may be indicative of whether the second step is performed within a certain time from when the first step was performed. In yet another example, a feature may be indicative of whether the first step and the second step are performed by the same user, on the same instance of a software system, and/or by users belonging to the same organization. In yet another example, a feature value may be indicative of a certain combination, such as the first step involving a certain first operation and the second step involving a certain second operation.

In some embodiments, at least some of the feature values that are used to describe a link between a first step and a second step may describe contextual information regarding the first and/or second steps. In one example, a feature value may describe a property of a step that is performed before the first (second) step or a property of a step that is performed after the first (second) step. In another example, the feature value may be indicative of a comparison between the first (second) step and a step performed before it or after it. For example, the feature value may be indicative of whether the first step has the same value for a certain EDA as the step before it or the step after it. In yet another example, a feature value may be a value indicative of an attribute of a user who performed the first (second) step, of an attribute of the instance of the software system on which the first (second) step were performed, and/or of an attribute of an attribute of the organization on behalf of whom the first (second) step was performed. In still another example, a feature value may identify a certain transaction and/or BP performed before or after the first (second) step was performed.

The positive samples 142, and optionally the negative samples 143, may include, in some embodiments, samples based on steps from sequences corresponding to executions of one or more BPs associated with multiple organizations. In one example, the positive samples 142 include first and second samples generated based pairs of steps belonging to first and second sequences of steps. In this example, the first sequence corresponds to an execution of a first BP associated with a first organization, and the second sequence corresponds to an execution of a second BP associated with a second organization, which is different from the first organization. When the positive samples 142 include samples based on executions of BPs associated with multiple organizations, this may assist in some cases in generating a linkage model that may be more beneficial for additional organizations since the linkage model describes a general behavior that may be common in executions of BPs by multiple organizations (and thus is likely to suit the additional organizations).

The linkage model generator module 144 is configured, in one embodiment, to generate the linkage model 145 based on training samples comprising the positive samples 142 and optionally the negative samples 143. In some embodiments, the linkage model 145 describes one or more rules for generating a link from a first step to a second step, which is executed after the first step. Optionally, each rule involves a condition involving at least some of the one or more feature values describing properties of a link from the first step to the second step. In other embodiments, the linkage model 145 may include parameters of a machine learning-based model that may be used to predict which pairs of steps should be linked (and/or which pairs should not be linked). The following is a more detailed discussion regarding these different approaches.

Rules for linking pairs of steps that appear in one or more streams may be generated, in some embodiments, based on examples of sequences of steps that correspond to executions of BPs (or a certain BP). In one example, the linkage model generator module 144 identifies pairs of consecutive steps in the sequences that appear multiple times in sequences. Optionally, at least some of the pairs are nonconsecutively performed in the streams. Once pairs of consecutive steps are identified, a rule based on common characteristics of the pairs can be derived from samples representing links between the pairs (e.g., the positive samples 142). For example, an observation that in many of the pairs, which were performed within ten minutes of each other, the first step of the pair involves a certain first transaction and the second step of the pair involves a certain second transaction, may lead to the generation of a corresponding candidate rule which may be paraphrased as “generate a link between a first step in a first stream and a second step in a second stream if the two steps were performed within ten minutes of each other, the first step involves the certain first transaction, and the second step involves the certain second transaction”.

Given that many candidate rules may be generated, it may be desirable, in some embodiments, to select a subset of the generated candidate rules in order to avoid having a possibly intractable number of candidate sequences that may be generated from streams, if a large number of candidate rules is utilized. Optionally, selecting which candidate rules are to be utilized is done by evaluating a frequency at which pairs of steps, from among sequences corresponding to executions of the BPs, conform to each candidate rule. This frequency, which may be referred to the BP-frequency of a candidate rule, may be utilized to select candidate rules that are most frequent. Optionally, the BP-frequency may be evaluated utilizing the positive samples 142. Additionally or alternatively, the BP-frequency of a candidate rule may be compared to a second frequency, which may be referred to as the non-BP-frequency of the candidate rule; the non-BP-frequency corresponds to a frequency at which pairs of steps from the streams, which do not belong to the sequences corresponding to executions of the BPs, conform to the candidate rule. Optionally, evaluation of the non-BP-frequency is done utilizing the negative samples 143. In some embodiments, a candidate rule for which the BP-frequency is significantly greater than the non-BP-frequency, is utilized for selecting sequences of steps from streams (i.e., is entered into the linkage model 145). Additionally or alternatively, a candidate rule for which the BP-frequency is not significantly greater than the non-BP-frequency, is not utilized for selecting sequences of steps from streams.

Choosing which rules to utilize for generating links between steps may involve evaluations of multiple possible subsets of candidate rules in order to determine their efficiency and/or coverage. For example, a subset of candidate rules may be evaluated utilizing a test set of sequences that are selected from streams of steps and correspond to executions of BPs. The evaluation of the subset of candidate rules may determine whether utilizing the subset is sufficient for generating the sequences belonging to the test set. In this example, the coverage may be a value indicative of how many of the test sequences are generated utilizing the subset of candidate rules and the efficiency may be indicative of the proportion of sequences generated utilizing the subset that are test sequences (and not sequences that do not correspond to executions of BPs). If, for example, the coverage of a subset of rules is too low, additional rules may be added to the subset in order to increase the coverage. This addition may amount to generation of additional links that may ultimately enable generation of additional sequences from the test set. Optionally, the additional rules are generated based on those sequences from the test set which were not initially generated utilizing links created based on rules in the subset. In another example, when the efficiency is low, certain rules may be removed while other, more specific, rules may be added in order to attempt to make the subset more efficient.

In some embodiments, the linkage model generator module 144 is further configured to utilize inductive logic concept learning to generate one or more rules for linking pairs of steps, which may be comprised in the linkage model 145. Optionally, the one or more rules are learned based on positive samples 142 and the negative samples 143. In one example, inductive constraint logic (ICL) may be utilized to generate the rules, as described in De Raedt, L. and Van Laer, W., (1995), “Inductive constraint logic”, In International Workshop on Algorithmic Learning Theory (pp. 80-94). Other examples of algorithmic approaches that may be used for this task are surveyed in Fürnkranz, J., “Separate-and-conquer rule learning”, in Artificial Intelligence Review 13.1 (1999): 3-54.

Rules utilized for generating links between pairs of steps may be, in some embodiments, specific rules for a certain BP or a certain set of BPs. For example, a certain first set of rules for generating links that are used for selecting first candidate sequences that are utilized in order to identify sequences corresponding to execution of a first BP. However, a certain second set of rules for generating links is utilized for selecting second candidate sequences that are provided in order to identify sequences corresponding to execution of a second BP. In this example, the first set of rules may be different from the second set of rules, and consequently, the first candidate sequences may be different from the second candidate sequences, even when the first and second candidate sequences are both selected from the same one or more streams of steps.

In some embodiments, rules utilized for generating links between pairs of steps may be general rules, which are appropriate for creating links that may be utilized for selecting sequences that may correspond to executions of various BPs. For example, when generating rules based on sequences corresponding to executions of BPs, if a variety of sequences is utilized to generate the rules, which correspond to many different BPs, then the generated rules may be considered a general set of rules appropriate for the various BPs (and possibly appropriate for BPs whose executions were not used to generate the rules). Herein, using a variety of sequences, which correspond to executions of various BPs, means that while each sequence corresponds to an execution of a certain BP, the set of BPs for which there is at least one corresponding sequence among the sequences, includes multiple different BPs.

In some embodiments, rules utilized for generating links between pairs of steps may be generated for a certain organization. Such rules may be useful for recognizing cases that are characteristic of the activity of the certain organization, such as BPs that involve certain combinations of transactions or BPs that involve different users and/or instances of different software systems. In other embodiments, rules utilized for linking pairs of steps may be generated based on observations made with multiple organizations (e.g., rules made manually based on experiences of multiple organizations or rules made based on examples of executions of BPs associated with multiple organizations). Thus, these rules may be considered general and/or “crowd-based” rules. Such rules may be useful for recognizing general principles, which are true for multiple organizations, regarding how different combinations of steps may be performed in order to execute BPs. Thus, crowd-based rules may often be more useful for a new organization compared to rules tailored to the activity of a specific organization (which is not the new organization).

Another approach for generating links between pairs of steps involves utilization of a machine learning-based model. In some embodiments, the linkage model generator module 144 is further configured to utilize a machine learning-based training algorithm to generate parameters included in the linkage model 145, based on the positive samples 142 and the negative samples 143. In these embodiments, the linkage model 145 may be utilized to calculate an output indicative of whether a certain first step and a certain second step, which is performed after the certain first step, belong to a sequence of steps corresponding to an execution of a BP. For example, the output may be indicative of whether the certain first step should appear directly before the certain second step in a sequence corresponding to an execution of the BP (i.e., it is possible for the sequence not to include a certain third step between the certain first step and the certain second step).

In one embodiment, the output described above is generated based on an input comprising one or more feature values describing properties of a link from the certain first step to the certain second step. The one or more feature values may be of the various types of feature values described further above that describe properties of the certain first step and/or the certain second step, and/or contextual information related to the certain first and/or the certain second step. Additionally or alternatively, the one or more features may include feature values corresponding to linkage rules described above. For example, a feature value may have the value 1 if the certain first step and the certain second step should be linked according to a certain linkage rule and a value 0 otherwise. Various machine learning-based approaches may be used to learn the parameters included in the linkage model 145 based on the positive samples 142 and the negative samples 143. For example, learning the parameters included in the linkage model 145 may involve training one or more of the following: a neural network, a support vector machine, a regression model, and/or a graphical model. Optionally, the linkage model 145 comprises one or more of the following: parameters of a neural network, parameters of a support vector machine, parameters of a regression model, and parameters of a graphical model. In one example, the linkage model 145 includes parameters of a regression model, and calculating the output is done by multiplying one or more regression coefficients with the one or more feature values. In another example, the linkage model 145 includes parameters of a neural network and the output is obtained by computing the output of a neural network configured according to the parameters when given an input comprising the one or more feature values.

Depending on the consistency of the training samples used to generate them, in some embodiments, machine learning-based models that are used to determine between which pairs of steps to generate links, such as the linkage model 145, may be considered specific models or general models. When the training data is primarily derived from sequences corresponding to a certain BP or to a certain set of BPs, the model may be considered a specific model (for the certain BP or the certain set of BPs). Optionally, the specific model is suitable for generating links that are to be used to create candidate sequences that are to be examined to determine whether they correspond to executions of the certain BP or an execution of a BP belonging to the certain set. However, when the training data is based on a variety of sequences corresponding to executions of multiple BPs, the model may be considered a general model. Optionally, the general model is suitable for generating links that are to be used to create candidate sequences that are to be examined to determine whether they correspond to executions of various BPs (without necessarily having a certain BP which is the target for identification).

As discussed above, the linkage model 145 may be a specific linkage model for a certain BP or a certain set of BPs or a general linkage model for a plurality of BPs. Generating these different linkage models may involve performing different steps. The following are descriptions of different methods for generating the different linkage models. In some embodiments, instructions for implementing a method, such as one of the methods described below, may be stored on a computer-readable medium, which may optionally be a non-transitory computer-readable medium. In response to execution by a system including a processor and memory, the instructions cause the system to perform operations that are part of the method. Optionally, the methods described below may be executed by a system comprising a processor and memory, such as the computer illustrated in FIG. 25. Optionally, at least some of the steps may be performed utilizing different systems comprising a processor and memory. Optionally, at least some of the steps may be performed using the same system comprising a processor and memory.

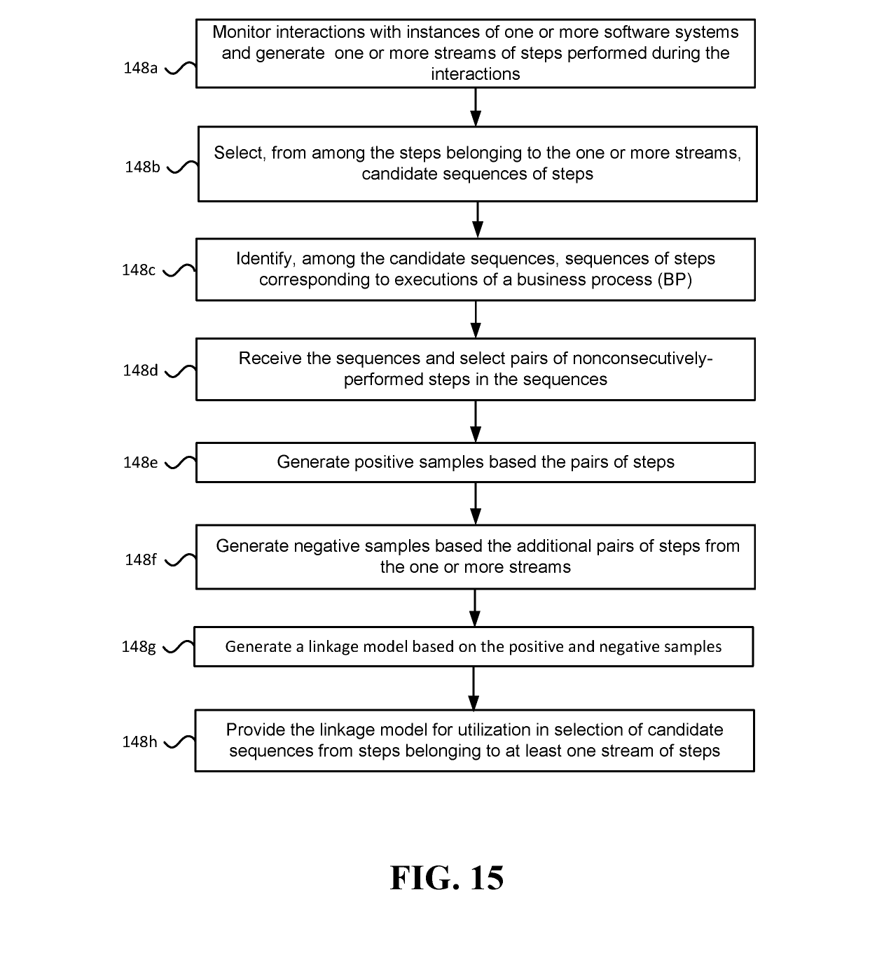

FIG. 15 illustrates steps that may be performed in one embodiment of a method for generating a (specific) model for linking between steps performed when executing a certain BP. In some embodiments, the steps described below maybe part of the steps performed by a system illustrated in FIG. 14.

In one embodiment, a method for generating a model for linking between steps performed when executing a certain BP (i.e., a linkage model) include at least the following steps:

In step 148d, receiving sequences of steps corresponding to executions of the certain BP and selecting pairs of nonconsecutively performed steps in the sequences. Each pair of steps selected from a sequence includes first and second steps such that in the sequence, the second step directly follows the first step, but in one or more streams of steps from which sequence was selected, the first and second steps are not consecutively performed. Optionally, the sequences are selected from among steps belonging to one or more streams of steps, each describing interactions with an instance of a software system (from among one or more software systems).

In Step 148e, generating positive samples based the pairs of steps selected in Step 148d. Optionally, each of the positive samples comprises one or more feature values describing properties of a link from a first step of a pair from among the pairs, to the second step of that pair.

In Step 148f, generating negative samples based the additional pairs of steps from the one or more streams. Optionally, each of the negative samples comprises one or more feature values describing properties of a link from a first step of a pair from among the additional pairs, to the second step of that pair.

And in Step 148g, generating the linkage model based on the positive and negative samples.

In some embodiments, the method may optionally include Step 148h that involves providing the linkage model for utilization in selection of candidate sequences from among steps belonging to at least one stream of steps. Optionally, the candidate sequences comprise at least a sequence that comprises a pair of nonconsecutively performed steps. Optionally, at least some sequences corresponding to executions of the certain BP are identified from among the candidate sequences. For example, the BP-identifier module 126 may utilize a model of the certain BP, such as the crowd-based model 118, which in this example is generated based on sequences corresponding to executions of the certain BP, which are associated with a plurality of organizations.

Generating the linkage model in Step 148g may be done in different ways in different embodiments. In one embodiment, generating the linkage model involves utilizing a machine learning-based training algorithm to generate parameters of the linkage model based on the positive samples and negative samples. Optionally, the linkage model is utilized to calculate an output indicative of whether a certain first step and a certain second step, which is performed after the certain first step, belong to a sequence of steps corresponding to an execution of the certain BP. The output is calculated based on an input comprising one or more feature values describing properties of a link from the certain first step to the certain second step. Optionally, the one or more feature values are generated by the sample generator module 140. Optionally, calculating the output is done utilizing the linkage model, which comprises one or more of the following: parameters of a neural network, parameters of a support vector machine, parameters of a regression model, and parameters of a graphical model.

In another embodiment, generating the linkage model in Step 148g involves generating, based on the positive samples and the negative samples, one or more rules for generating a link from a first step to a second step, which is performed after the first step. Optionally, each rule involves a condition that is evaluated based on values of one or more feature values describing properties of a link from the first step to the second step. Optionally, the linkage model describes the one or more rules. Optionally, generating the one or more rules is done utilizing inductive logic concept learning.

In some embodiments, the method may optionally include Step 148a, which involves monitoring the interactions with the instances of the one or more software systems and generating the one or more streams based on data collected during the monitoring. Optionally, the interactions are monitored using monitoring agents from among the monitoring agents 102a to 102d. Additionally, in some embodiments, the method may optionally include Step 148b and/or Step 148c. Step 148b involves selecting, from among the steps belonging to the one or more streams, candidate sequences of steps. Optionally, selecting the candidate sequences is done by the sequence parser module 122. Step 148c involves identifying, among the candidate sequences, sequences of steps corresponding to executions of the certain BP, which are received in Step 148d.

There may be various ways to select the additional steps, which are used for negative examples of links between steps in Step 148f to generate the negative samples. In one example, Step 148f may involve randomly selecting pairs of steps from the one or more streams and utilizing the selected pairs to generate at least some of the negative samples. In another example, Step 148f may involve selecting pairs in which the first step of the pair is involved in an execution of a first BP and the second step of the pair is involved in an execution of a second BP, which is different from the first BP, and utilizing the selected pairs to generate at least some of the negative samples. In still another example, Step 148f may involve selecting pairs in which the first step of the pair belongs to a first stream from among the one or more streams, which includes steps involving interactions with a first instance of a first software system, and the second step the pair belongs to a second stream from among the one or more streams, which includes steps involving interactions with a second instance of a second system, and utilizing the selected pairs to generate at least some of the negative samples.

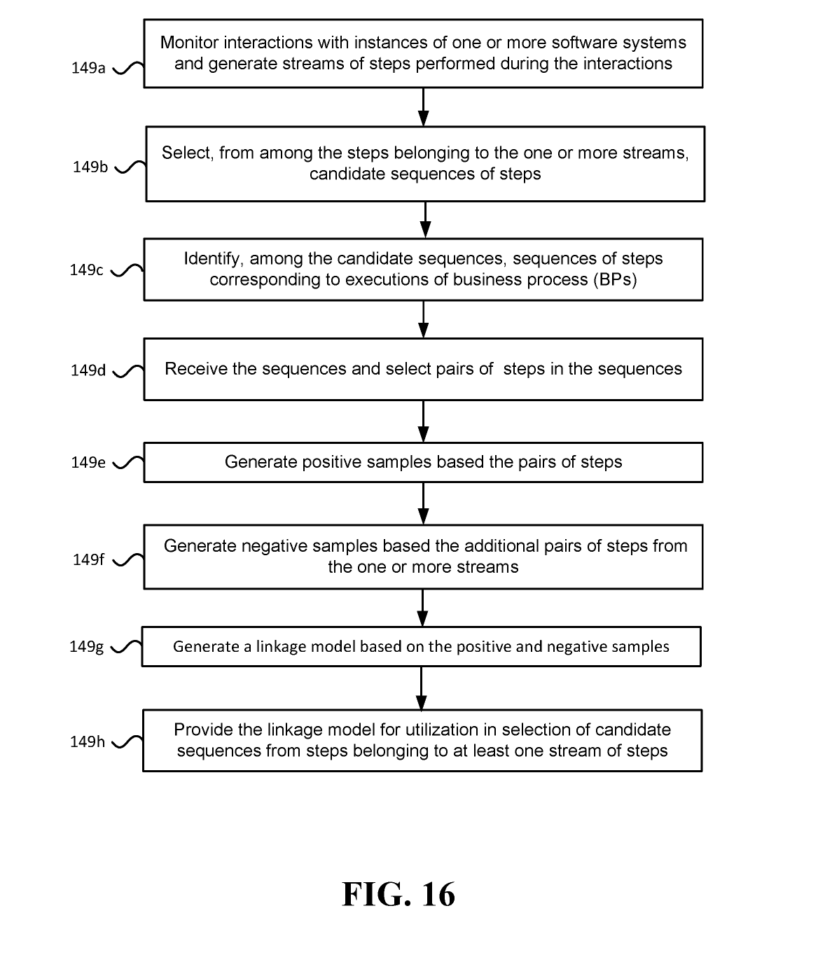

FIG. 16 illustrates steps that may be performed in one embodiment of a method for generating a general model for linking between steps performed when executing BPs. In some embodiments, the steps described below maybe part of the steps performed by a system illustrated in FIG. 14.

In one embodiment, a method for generating a model for linking between steps performed when executing BPs (i.e., a linkage model) include at least the following steps:

In step 149d, receiving sequences of steps corresponding to executions of the BPs and selecting pairs of steps from the sequences. Optionally, the sequences are selected from among steps belonging to streams of steps performed during interactions with instances of one or more software systems. Each sequence, from among the sequences received in this step, corresponds to an execution of a BP from among the BPs. Additionally, each pair of steps selected from a sequence includes first and second steps, such that in the sequence, the second step directly follows the first step. Optionally, at least some of the pairs of steps selected in Step 149d may be nonconsecutively performed, such that in the one or more streams of steps from which a sequence was selected, the first and second steps of a pair selected from the sequence are not consecutively performed. Optionally, this means that at least one of the following is true: (i) there is a third step that appears in the same stream as the first and seconds steps, the third step is performed after the first step and before the second step, but the third step does not appear in the sequence, and (ii) the first step belongs to a first stream and the second step belongs to a second stream.

In Step 149e, generating positive samples based the pairs of steps selected in Step 149d. Optionally, each of the positive samples comprises one or more feature values describing properties of a link from a first step of a pair from among the pairs, to the second step of that pair.

In Step 149f, generating negative samples based the additional pairs of steps from the streams. Optionally, each of the negative samples comprises one or more feature values describing properties of a link from a first step of a pair from among the additional pairs, to the second step of that pair.

And in Step 149g, generating the linkage model based on the positive and negative samples. Since the positive samples include examples of links between steps in sequences corresponding to executions of multiple BPs, in some embodiments, the linkage model may be considered a general linkage model.

In some embodiments, the method may optionally include Step 149h that involves providing the linkage model for utilization in selection of candidate sequences from among steps belonging to at least one stream of steps. Optionally, the candidate sequences comprise at least a sequence that comprises a pair of nonconsecutively performed steps. Optionally, at least some sequences corresponding to executions of at least some of the BPs are identified from among the candidate sequences. For example, the BP-identifier module 126 may utilize a model to identify a BP from among the BPs, such as the crowd-based model 118. In another example, the BP-identifier module 126 may utilize a crowd-based model generated based on sequences corresponding to executions of multiple BPs, such as a classification model (which can classify sequences to one or more classes each corresponding to a BP from among the BPs).

Generating the linkage model in Step 149g may be done in different ways in different embodiments. In one embodiment, generating the linkage model involves utilizing a machine learning-based training algorithm to generate parameters of the linkage model based on the positive samples and negative samples. Optionally, the linkage model is utilized to calculate an output indicative of whether a certain first step and a certain second step, which is performed after the certain first step, belong to a sequence of steps corresponding to an execution of a BP from among the BPs. The output is calculated based on an input comprising one or more feature values describing properties of a link from the certain first step to the certain second step. Optionally, the one or more feature values are generated by the sample generator module 140. Optionally, calculating the output is done utilizing the linkage model, which comprises one or more of the following: parameters of a neural network, parameters of a support vector machine, parameters of a regression model, and parameters of a graphical model.

In another embodiment, generating the linkage model in Step 149g involves generating, based on the positive samples and the negative samples, one or more rules for generating a link from a first step to a second step, which is performed after the first step. Optionally, each rule involves a condition that is evaluated based on values of one or more feature values describing properties of a link from the first step to the second step. Optionally, the linkage model describes the one or more rules. Optionally, generating the one or more rules is done utilizing inductive logic concept learning.

In some embodiments, the method may optionally include Step 149a, which involves monitoring the interactions with the instances of the one or more software systems and generating the streams based on data collected during the monitoring. Optionally, the interactions are monitored using monitoring agents from among the monitoring agents 102a to 102d. Additionally, in some embodiments, the method may optionally include Steps 149b and/or Step 149c. Step 149b involves selecting, from among the steps belonging to the streams, candidate sequences of steps. Optionally, selecting the candidate sequences is done by the sequence parser module 122. Step 149c involves identifying, among the candidate sequences, sequences of steps corresponding to executions of the BPs.

There may be various ways to select the additional steps, which are used negative examples of links between steps in Step 149f to generate the negative samples. In one example, Step 149f may involve randomly selecting pairs of steps from the one or more streams and utilizing the selected pairs to generate at least some of the negative samples. In another example, Step 149f may involve selecting pairs in which the first step of the pair is involved in an execution of a first BP and the second step of the pair is involved in an execution of a second BP, which is different from the first BP, and utilizing the selected pairs to generate at least some of the negative samples. In still another example, Step 149f may involve selecting pairs in which the first step of the pair belongs to a first stream from among the one or more streams, which includes steps involving interactions with a first instance of a first software system, and the second step the pair belongs to a second stream from among the one or more streams, which includes steps involving interactions with a second instance of a second system, and utilizing the selected pairs to generate at least some of the negative samples.

A linkage model, such as the linkage model 145 described above, may be utilized to generate sequences from one or more streams of steps. When the sequences of steps are analyzed to identify the BPs they correspond, the sequences may be referred to herein as “candidate sequences”. Generation of candidate sequences is described in FIG. 17, which illustrates one embodiment of a system configured to generate candidate sequences of steps utilizing links between steps that are nonconsecutively performed. The system includes at least the following modules: link generator module 150, and candidate generation module 152. Additionally, the system may include, in some embodiments, the BP-identifier module 126.

It is to be noted that in some embodiments, the link generator module 150 and the candidate generation module 152 may be considered to be modules comprised in, and/or utilized by, the sequence parser module 122. The embodiment illustrated in FIG. 17 may be realized utilizing a computer, such as the computer 400, which includes at least a memory 402 and a processor 401. The memory 402 stores code of computer executable modules, such as the modules described above, and the processor 401 executes the code of the computer executable modules stored in the memory 402.

The link generator module 150 is configured, in one embodiment, to generate links between pairs of steps that are among steps belonging to one or more streams 153 of steps performed during interactions with one or more instances of one or more software systems. Optionally, at least some of the links are from a first step to a second step, and the first and second steps are not consecutively performed steps in the same stream.

In different embodiments, the one or more streams 153 may comprise data from different sources and/or data of different types. In one example, the one or more streams 153 include a single stream of steps involves in interactions with a single instance of a certain software system (e.g., an ERP system). In another example, the one or more streams 153 include at least first and second streams generated based on monitoring of interactions with first and second respective instances of a certain software system. Optionally, in this example, the first stream involves steps performed by a first user and the second stream involves steps performed by a second user, which is not the first user. In yet another example, the one or more streams 153 include at least first and second streams generated based on monitoring of interactions with instances of first and second software systems, respectively (e.g., the first software system may be an ERP and the second software system may provide a SaaS application). Optionally, in this example, the first stream involves steps performed by a first user and the second stream involves steps performed by a second user, which is not the first user.

In embodiments described herein, various types of links between steps may be generated by the link generator module 150. In one example, at least some of the links are between pairs of steps in the same stream. In another example, at least some of the links are between pairs of first and second steps, where the first step belongs to a first stream that includes steps performed as part of interactions with a first instance of a certain software system, and the second step belongs to a second stream that includes steps performed as part of interactions with a second instance of the certain software system, which is different from the first instance. In yet another example, at least some of the links are between pairs of first and second steps, where the first step belongs to a first stream that includes steps performed as part of interactions with an instance of a first software system, and the second step belongs to a second stream that includes steps performed as part of interactions with an instance of a second software system that is different from the first software system.

The link generator module 150 is configured, in some embodiments, to generate the links utilizing the linkage model 145, which is generated based on the positive samples 142 and the negative samples 142. The positive samples 142 describe pairs of first and second steps that were performed nonconsecutively, but in a sequence corresponding to an execution of a BP, the second step appears directly after the first step. The negative samples 143 describe pairs of first and second steps that do not appear one directly after the other in any sequence corresponding to an execution of a BP.

In one embodiment, the linkage model 145 used by the link generator module 150 may be a general linkage model, which may be used to generate links between steps that may belong to various executions of BPs. In one example, the positive samples used to generate the linkage model 145 comprise at least first a first sample generated based on a first pair of steps in a first sequence corresponding to an execution of a first BP, and a second sample generated based on a second pair of steps in a second sequence corresponding to an execution of a second BP, which is different from the first BP. In another embodiment, the linkage model 145 used by the link generator module 150 is a linkage model that is specific to a certain BP. Optionally, the positive samples used to generate this linkage model are mostly generated from sequences of steps corresponding to executions of the certain BP.

In one embodiment, the linkage model 145 is considered a crowd-based model appropriate for the BP. For example, in this embodiment, the positive samples 142 comprise a first sample describing steps belonging to a sequence corresponding to an execution of the BP associated with a first organization and a second sample describing steps belonging to a sequence corresponding to an execution of the BP associated with a second organization, which is different from the first organization. Additionally, in this embodiment, the one or more streams 153 involve interactions with instances of one or more software systems that belong to a third organization, which is different from the first and second organizations. Thus, in this embodiment, crowd-based knowledge learned from other organizations (e.g., the first and second organizations) may be utilized to assist in analysis of activity of a “new” organization (e.g., the third organization).

As discussed in more detail further above, the linkage model 145 may include different types of data in different embodiments. In one embodiment, the linkage model 145 comprises one or more rules for generating a link from a first step to a second step, which is performed after the first step. Optionally, each rule involves a condition involving one or more feature values describing properties of a link from the first step to the second step. In this embodiment, the link generator module 150 is configured to generate a link from a certain first to a certain second step if one or more feature values, which describe properties of a link from the certain first step to the certain second step, conform to at least one of the one or more rules. In another embodiment, the linkage model 145 comprises parameters of a machine learning-based model generated based on the positive and negative samples. The machine learning-based model is utilized by the link generator module 150, which in this embodiment, is configured to calculate an output indicative of whether a certain first step and a certain second step, which is performed after the certain first step, belong to a sequence of steps corresponding to an execution of a BP. The output is calculated based on an input comprising one or more feature values describing properties of a link from the certain first step to the certain second step.

The candidate generation module 152 is configured, in some embodiments, to utilize links generated by the link generator module 150 to generate candidate sequences 154 from steps belonging to the one or more streams 153. In one embodiment, the candidate sequences 154 comprise at least a certain sequence generated based on a link from a certain first step to a certain second step, and the certain first and second steps are nonconsecutively performed. That is, at least one of the following statements is true: (i) there is a certain third step that appears in the same stream as the certain first and seconds steps, the certain third step is performed after the certain first step and before the certain second step, but the certain third step does not appear in the certain sequence, and (ii) the certain first step belongs to a first stream and the second step belongs to a second stream.

The candidate generation module 152 is further configured, in some embodiments, to provide the candidate sequences 154 for determination of whether at least some of the candidate sequences 154 correspond to executions of a BP. In one embodiment, the candidate sequences 154 are forwarded to the BP-identifier module 126, which utilizes a crowd-based model 157 of one or more BPs in order to identify which of the candidate sequences 154 correspond to executions of the one or more BPs. In one example, the crowd-based model 157 comprises a plurality of crowd-based models for different BPs, e.g., multiple instances of the crowd-based model 118 for different BPs. In another example, the crowd-based model 157 may include parameters used by a classifier that classifies sequences of steps to a certain BP, from among a plurality of BPs, to which the sequence corresponds (i.e., the sequence corresponds to an execution of the certain BP). In some embodiments, determining whether the candidate sequences 154 correspond to executions of a BP is done utilizing a model of a BP that is manually generated (e.g., by an expert) and/or generated based on documentation of the BP.

As discussed above (e.g., in the discussion regarding FIG. 13), the links generated by the link generator module 150 may be considered to represent at least some of the edges of a graph in that includes vertices representing at least some of the steps belonging to the one or more streams. Thus, in some embodiments, the task of the candidate generator module 152 may amount to exploring the search space of the graph and extracting sub-paths from the graph, with each sub-path corresponding to a candidate sequence. There various ways in which the graph may be explored in order to extract the sub-paths. In one example, the graph is scanned using Depth First Search (DFS). In another example, the graph is scanned using Breath First Search (BFS). In these examples, a certain step may belong to multiple different candidate sequences.

Often, a large number of sub-paths can be extracted from a graphs generated from an organization's monitored activity. Thus, in some embodiments, certain limitations may be put in place that can help prune the search in the graph, which may lead to extraction of sub-paths of a certain desired nature. In one example, the number links, which may be contained in each sub-path, may be restricted (e.g., to one link or two links at most). In another example, the number of links of a certain type may be restricted, such as not allowing more than one link between steps in different streams (e.g., in order to restrict the number of different software systems that are involved in the execution of a certain BP). In still another example, the number of steps in each sub-path may be restricted to a certain range. In still another example, the duration between when different steps in the sub-path were performed may be limited (e.g., the difference between the first and last steps may be limited to be at most one day). And in yet another example, steps in a sub-path may be restricted to include the same value for an EDA (e.g., the same customer number).

In some embodiments, various parameters involved in the examples above, which may be used to restrict the sub-paths extracted from the graph may be learned from data. For example, the various parameters may be determined based on identified sequences corresponding to executions of a BP extracted from streams of steps. In other embodiments, the various parameters may be provided to the system (e.g., as default and/or configurable parameters). In yet other embodiments, the various parameters may be described in a model of a BP.

Another way in which the sub-paths extracted from a graph may be restricted is through utilization of certain markers that are referred to herein as seeds. A seed is a sequence of one or more consecutively performed steps that typically appear in sequences corresponding to executions of a BP (or multiple BPs). In one example, a seed may include one or more steps that are typically at the beginning of a sequence corresponding to an execution of a BP. Thus, in this example, sub-paths in the graph may be restricted to sub-paths that start with the steps of in seed. In another example, another seed may include one or more steps that are typically at the end of a sequence corresponding to an execution of a BP. In this example, sub-paths in the graph may be restricted to sub-paths that end with the steps in the seed. And in still another example, a seed may include one or more steps that are typically in the middle of a sequence corresponding to an execution of a BP. In this example, sub-paths in the graph may be restricted to sub-paths that contain the steps in the seed. The specifics of seeds that characterize each BP, e.g., what sequence of steps are a seed and/or where the seed belongs in a sequence corresponding to an execution of the BP, may be learned from examples of sequences. Additionally or alternatively, descriptions of the seeds may be comprised in a model of the BP. Additional information regarding seeds is given in the discussion of embodiments illustrated in FIG. 19.

In some embodiments, the system described above may include one or more monitoring agents configured to generate the one or more streams of steps. Optionally, each monitoring agent generates a stream comprising steps performed as part of an interaction with an instance of a software system from among one or more software systems. Additional discussion regarding monitoring agents and the data they examine/produce may be found in this disclosure at least in Section 3—Monitoring Activity.

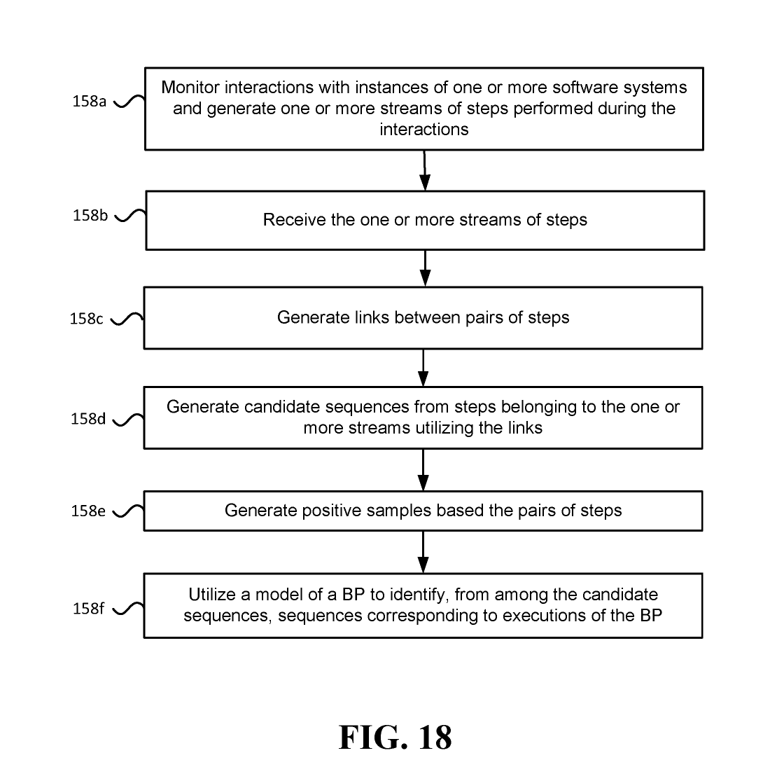

FIG. 18 illustrates steps that may be performed in one embodiment of a method for generating candidate sequences of steps utilizing links between steps that are performed nonconsecutively. The steps described below may, in some embodiments, be part of the steps performed by an embodiment of a system illustrated in FIG. 17. In some embodiments, instructions for implementing the method described below may be stored on a computer-readable medium, which may optionally be a non-transitory computer-readable medium. In response to execution by a system including a processor and memory, the instructions cause the system to perform operations that are part of the method. Optionally, the methods described below may be executed by a system comprising a processor and memory, such as the computer illustrated in FIG. 25. Optionally, at least some of the steps may be performed utilizing different systems comprising a processor and memory. Optionally, at least some of the steps may be performed using the same system comprising a processor and memory.

In one embodiment, a method for generating candidate sequences of steps utilizing links between steps that are performed nonconsecutively includes at least the following steps:

In Step 158b, receiving one or more streams of steps performed during interactions with instances of one or more software systems.

In Step 158c, generating links between pairs of steps belonging to one or more streams. At least some of the links are from a first step to a second step, and the first and second steps are not consecutively performed steps in the same stream. Optionally, the links are generated by the link generator module 150.

In Step 158d, generating candidate sequences from steps belonging to the one or more streams utilizing the links. Optionally, the candidate sequences are generated by the candidate generation module 152. The candidate sequences comprise a certain sequence generated based on a link from a certain first step to a certain second step that are nonconsecutively performed. Optionally, this means that at least one of the following statements is true: (i) there is a certain third step that appears in the same stream as the certain first and seconds steps, the certain third step is performed after the certain first step and before the certain second step, but the certain third step does not appear in the certain sequence, and (ii) the certain first step belongs to a first stream and the second step belongs to a second stream.

And in Step 158e, forwarding the candidate sequences for determination of whether at least some of the candidate sequences correspond to executions of a BP.

In one embodiment, the method may optionally include Step 158f, which involves utilizing a model of the BP to identify which of the candidate sequences corresponds to an execution of the BP. Optionally, the model of the BP is generated based on previously identified sequences of steps corresponding to executions of the BP. For example, the mode of the BP may be the crowd-based model 118 or the crowd-based model 157. Optionally, the model of the BP is generated manually (e.g., by an expert) and/or based on analysis of documentation of the BP.

In one embodiment, the method may optionally include Step 158a, which involves monitoring the interactions and generating the one or more streams received in Step 158b based on data collected during the monitoring. Optionally, the monitoring is performed by one or more monitoring agents, such as one or more of the monitoring agents 102a to 102d.

In some embodiments, generating the links in Step 158c involves utilizing a linkage model. Optionally, the linkage model involves manually generated rules for linking between steps. Additionally or alternatively, the linkage model may be generated based on positive samples and negative samples, such as the linkage model 145. Optionally, the positive samples describe pairs of first and second steps that were performed nonconsecutively, but in a sequence corresponding to an execution of a BP, the second step appears directly after the first step. Optionally, the negative samples describe pairs of first and second steps that do not appear one directly after the other in any sequence corresponding to an execution of a BP.

In one embodiment, the linkage model utilized to generate the links in Step 158c comprises one or more rules for generating a link from a first step to a second step, which is performed after the first step. Each rule involves a condition involving one or more feature values describing properties of a link from the first step to the second step. In this embodiment, Step 158c involves generating a link from a certain first to a certain second step if one or more feature values, which describe properties of a link from the certain first step to the certain second step, conform to at least one of the one or more rules. Optionally, the feature values are generated by the sample generator module 140.

In another embodiment, the linkage model utilized to generate the links in Step 158c comprises parameters of a machine learning-based model generated based on the positive and negative samples. In this embodiment, Step 158c involves utilizing the machine learning-based model e to calculate an output indicative of whether a certain first step and a certain second step, which is performed after the certain first step, belong to a sequence of steps corresponding to an execution of a BP. The output is calculated based on an input comprising one or more feature values describing properties of a link from the certain first step to the certain second step. Optionally, the feature values are generated by the sample generator module 140.

In some embodiments, the links may represent at least some of the edges in a graph in that includes vertices representing at least some of the steps belonging to the one or more streams (e.g., as illustrated in FIG. 13). In these embodiments, generating the candidate sequences in Step 158d may involve traversing the graph and generating at least some of the candidate sequences based on sub-paths observed in the graph.

FIG. 19 illustrates one embodiment of a system configured to extract a seed comprising steps common in executions of a BP and to utilize the seed to identify other executions of the BP. The system includes at least the following modules: seed extraction module 160, seed identification module 165, seed extension module 166, and BP-identifier module 126. The embodiment illustrated in FIG. 19 may be realized utilizing a computer, such as the computer 400, which includes at least a memory 402 and a processor 401. The memory 402 stores code of computer executable modules, such as the modules described above, and the processor 401 executes the code of the computer executable modules stored in the memory 402.

The seed extraction module 160 is configured, in one embodiment, to receive sequences 162 of steps selected from among streams of steps performed during interactions with instances of a software system. Optionally, the sequences 162 are provided utilizing the example collector module 127. In some embodiments, the sequences 162 may include sequences corresponding to executions of a BP, which are associated with a plurality of different organizations. For example, the sequences may include first and second sequences corresponding to executions of the BP, which are associated with first and second organizations, respectively.

It is to be noted that a step performed during an interaction with an instance of a software system may describe various aspects of the interaction, such as a transaction that is performed, a program that is run, a screen that is accessed, and/or an operation performed on a screen. Streams of steps may be obtained utilizing monitoring of interactions, as discussed in further detail in this disclosure at least in Section 3—Monitoring Activity. Additional details regarding steps and streams of steps are given in this disclosure at least in Section 4—Streams and Steps.

While the sequences 162 may typically be similar to each other, they are not necessarily identical. For instance, in the example above, the first sequence may comprise at least one step that is not comprised in the second sequence. However, the sequences 162 may often include certain steps that are conserved and performed in most, if not in all, of the executions of the BP. These steps are considered herein a “seed” (illustrated in the figure as the shaded squares in the sequences 162 and as seed 163). The seed extraction module 160 is configured to extract the seed 163 from the sequences 162. Optionally, the seed 163 comprises two or more consecutively performed steps that appear in each of the sequences 162. In one example, the seed 163 may be represented by a pattern that describes steps that are performed as part of an execution of the BP.

Selecting the seed 163 from among the sequences of steps 162 may be done in various ways. In one embodiment, the number of occurrences of each subsequence of a certain length in the sequences 162 is counted. Optionally, hashing of subsequences may be used to perform this counting efficiently. Optionally, the seed 163 is selected from among the subsequences with the highest number of repetitions in the sequences 162. Optionally, a statistical significance of each subsequence is computed, and the seed 163 is selected from among the subsequences with the highest statistical significance. In one example, the statistical significance of a subsequence is done by calculating a p-value that is indicative of the probability of randomly observing a seed of a given length and a given number of repetitions in the sequences 162. In other embodiments, various motif finding algorithms may be utilized to determine the seed 163, such as the algorithms discussed in Das, et al. “A survey of DNA motif finding algorithms”, in BMC bioinformatics 8.7 (2007):1. It is to be noted that when utilizing a motif finding algorithm, the seed 163 may be a subsequence that has many approximate matches among the sequences 162 (i.e., the subsequences 162 may include subsequences that are close, but not necessarily identical, to the seed 163).

In addition to determining the steps included in the seed 163, in some embodiments, the seed extraction module 160 may determine additional properties of occurrences of the seed 163. For example, in one embodiment, the seed extraction module 160 may also determine the relative location of the seed 163 in the sequences 162 (e.g., whether the seed in the beginning of a sequence, the end, or somewhere in between). In another example, the seed extraction module 160 may determine based on the sequences 162 how many steps typically appear before and/or after the seed 163 in the sequences 162. In yet another example, the seed extraction module 160 may determine what types of steps appear at the beginning and/or end of the sequences 162. The various examples of additional properties of occurrences of seeds may be utilized, in some embodiments, by the seed extension module 166 to generate candidate sequences.

In some embodiments, the seed 163 may be a seed corresponding to a certain BP. In other embodiments, the seed 163 may represent a common element of more than one BP. For example, the seed 163 may be a certain subsequence of steps that are performed in more than one BP. In these embodiments, the seed extraction module 160 may receive additional sequences of steps and utilize the additional sequences for extraction of the seed 163. Optionally, at least some of the additional sequences are selected from among the same streams of steps from which the sequences 162 were selected. Additionally or alternatively, the additional sequences may be selected from among additional streams of steps performed during interactions with instances of the software system. Optionally, the additional sequences are selected by the example collector module 127. The additional sequences each comprise an occurrence of the seed and each of the additional sequences corresponds to an execution of a second BP, which is different from the BP. Thus, when extracting the seed 163 based on its occurrences both in the sequences 162 and among the additional sequences, the seed 163 may reflect an element that is typically performed in more than one BP (and thus may possibly be performed in further other BPs.)

Occurrences of a seed in streams of steps describing interactions with instance of a software system correspond times at which it is possible that a BP corresponding to the seed was executed. Thus, locating occurrences of a seed may be utilized for identifying executions of the BP. In some embodiments, locating occurrences of seeds is done by the seed identification module 165. In one embodiment, the seed identification module 165 is configured to receive one or more streams of steps 164 performed during interactions with one or more instances of the software system. The seed identification module 165 is configured to identify in the one or more streams 164 occurrences of the seed 163. Optionally, the one or more instances belong to a third organization, which is different from the first and second organizations described above. Thus, the seed 163 may be considered in this case to be a crowd-based result learned from executions of a BP by some organizations (e.g., the first and second organizations), which is utilized by other organizations (e.g., the third organization).

Identifying the occurrences of the seed 163 by the seed identification module 165 may be done in different ways. When the occurrences represent exact matches of the seed 163, various pattern matching and/or hashing-based methods may be used to identify the occurrences in the one or more streams 164. In some embodiments, the occurrences may possibly represent inexact matches of the seed 163. Optionally, in these embodiments, the seed identification module 165 may be further configured to calculate distances between a certain sequence representing the seed 163 and subsequences of consecutively performed steps from among the one or more streams 164. For example, the distance may be calculated using various sequence comparison algorithms (e.g., edit distance, Hamming distance, and/or other sequence distance functions). Optionally, if the distance between the seed 163 and a subsequence of steps is below a threshold, then the subsequence is considered an occurrence of the seed 163. Optionally, the threshold may be a predetermined threshold that is set to accommodate at most a certain number of mismatches between the seed 163 and an occurrence of the seed (e.g., at most one or two missing or different steps between the two). Optionally, the threshold is set to a low enough value such that distances between the certain sequence representing the seed 163 and most of the subsequences, from among the one or more streams 164, which are of equal length to the certain sequence, are not below the threshold.

While an occurrence of the seed 163 in a stream of steps may be indicative that a certain BP was executed, this is not necessarily always the case. For example, the seed 163 may be involved in executions of other BPs too. Identification of whether an execution of the certain BP occurred may involve evaluation of additional steps beyond the seed 163. The seed extension module 166 may be utilized for this task. In one embodiment, the seed extension module 166 is configured to select candidate sequences 169 by extending each of the occurrences of the seed 163 by adding to each occurrence of the seed 163 in a stream from among the one or more streams 164 at least one additional step that comes before the occurrence of the seed 163 in the stream or after the of the occurrence of the seed 163 in the stream. Optionally, not all the candidate sequences 169 include the same exact steps. In one example, the candidate sequences 169 comprise first and second candidate sequences, and the first candidate sequence comprises at least one step that is not comprised in the second sequence.

FIG. 19 illustrates how the seed identification module 165 finds in a stream from among the one or more streams 164 two occurrences of the seed 163, denoted occurrence 167a and occurrence 167b. The seed extension module 166 adds steps to these occurrences to obtain candidate sequence 168a and candidate sequence 168b (which may be considered to be part of the candidate sequences 169). It is to be noted that in some embodiments, the seed identification module 165 and the seed extension module 166 may be considered modules that are part of, and/or utilized by, the sequence parser module 122.

A seed may be located in different relative locations of the sequences corresponding to executions of the BP. In FIG. 19, the seed 163 is illustrated as being at the beginning of the sequences 162, but in some cases, a seed may be located at the end of the sequences or somewhere in between the beginning and the end. In one example, the seed 163 is located at the beginning of a candidate sequence and the candidate sequence comprises one or more steps that appear in a stream after the occurrence of the seed 163. In another example, the seed 163 may be located at the end of a candidate sequence and the candidate sequence comprises one or more steps that appear in a stream before the occurrence of the seed 163. And in another example, the seed 163 is neither at the beginning nor at the end of a candidate sequence, and the candidate sequence comprises one or more steps that appear in a stream before the occurrence of the seed 163 and one or more steps that appear in the stream after the occurrence of the seed 163.

In some embodiments, a description of the seed 163 includes additional information regarding occurrences of the seed, such as its typical location in a sequence and/or information about the steps that flank it and/or appear at the beginning and/or end of the sequences. Optionally, this information is utilized by the seed extension module 166 in order to determine how to extend an occurrence of the seed 163.

Additionally, when extending an occurrence of the seed 163, in some embodiments, the seed extension module 166 may consider values of one or more Execution-Dependent Attributed (EDAs). For example, the seed extension module 166 may add to an occurrence of the seed 163 steps in a stream that flank it and have the same values for the one or more EDAs that the steps in the occurrence of the seed 163 have. In one example, the seed extension module 166 is further configured to: (i) identify a value of a certain EDA in at least one of the steps belonging to an occurrence of the seed 163 in a stream from among the one or more streams 164, and (ii) generate a candidate sequence by extending the occurrence of the seed with at least some steps from the stream that are associated with the same value of the certain EDA. Optionally, the EDA corresponds to one or more of the following types of values: a mailing address, a Universal Resource Locator (URL) address, an Internet Protocol (IP) address, a phone number, an email address, a social security number, a driving license number, an address on a certain blockchain, an identifier of a digital wallet, an identifier of a client, an identifier of an employee, an identifier of a patient, an identifier of an account, and an order number.

The BP-identifier module 126 is configured, in one embodiment, to identify, from among the candidate sequences 169, one or more sequences of steps that correspond to executions 170 of the BP. Optionally, the BP-identifier may utilize a model of the BP, such as the crowd-based model 118 in order to identify which of the candidate sequences 169 correspond to the executions of the BP.

While in the description above a single seed is extracted and utilized, in some embodiments multiple seeds may be extracted and utilized to generate candidate sequences. For example, in one embodiment, the seed extraction module 160 is further configured to extract an additional seed from the sequences 162. The additional seed comprises one or more consecutively performed steps that appear in at least some of the sequences 162. In this embodiment, the seed extension module 166 is further configured to select the candidate sequences 169 such that each of the candidate sequences 169 comprises an occurrence of the seed 163 and an occurrence of the additional seed. In one example, the seed 163 is located at the beginning of the sequences 162 and the additional seed is located at the end of the sequences 162. In this example, the seed identification module 165 may identify locations of both seeds in the one or more streams 164, and the sequence extension module 166 may generate the candidate sequences 169 by finding pairs of occurrences of seeds, which comprise an occurrence of the seed 163 that is followed, within a certain number of steps by an occurrence of the additional seed. The seed extension module 166 may generate the candidate sequences 169 based on the pairs by extracting, for each pair, a subsequence that starts at the beginning the occurrence of the seed 163 and ends and the end of the occurrence of the additional seed. In this example, a typical range of acceptable distances between the occurrence of the seed 163 and the occurrence of the additional seed may be determined based on the observed distance between these two occurrences in the sequences 162.

In some embodiments, the system illustrated in FIG. 19 may include one or more monitoring agents configured to generate the one or more streams of steps 164 and/or the streams of steps from among which the sequences 162 were selected. Optionally, each monitoring agent generates a stream comprising steps performed as part of an interaction with an instance of a software system from among one or more software systems. Additional discussion regarding monitoring agents and the data they examine/produce may be found in this disclosure at least in Section 3—Monitoring Activity.

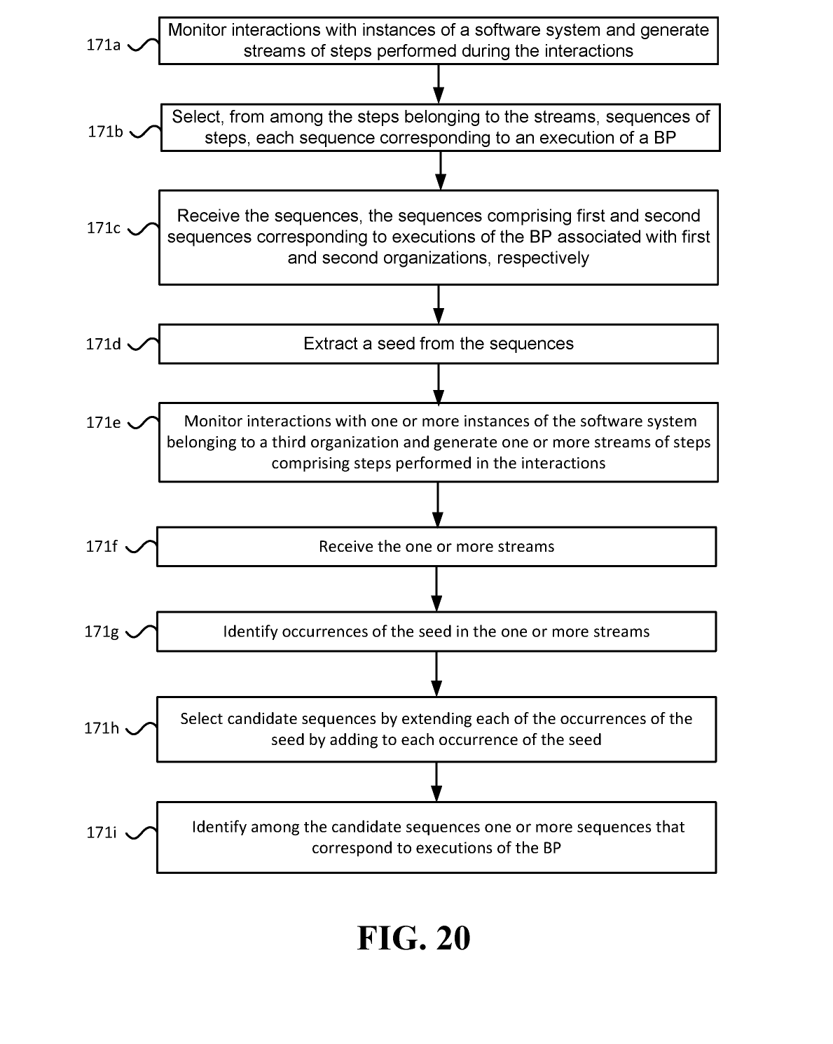

FIG. 20 illustrates steps that may be performed in one embodiment of a method for extracting a seed comprising steps common in executions of a BP and utilizing the seed to identify other executions of the BP. The steps described below may, in some embodiments, be part of the steps performed by an embodiment of a system illustrated in FIG. 19. In some embodiments, instructions for implementing the method described below may be stored on a computer-readable medium, which may optionally be a non-transitory computer-readable medium. In response to execution by a system including a processor and memory, the instructions cause the system to perform operations that are part of the method. Optionally, the methods described below may be executed by a system comprising a processor and memory, such as the computer illustrated in FIG. 25. Optionally, at least some of the steps may be performed utilizing different systems comprising a processor and memory. Optionally, at least some of the steps may be performed using the same system comprising a processor and memory.

In one embodiment, a method for extracting a seed comprising steps common in executions of a Business Process (BP) and utilizing the seed to identify other executions of the BP includes at least the following steps:

In Step 171c, receiving sequences of steps selected from among streams of steps performed during interactions with instances of a software system. Optionally, the sequences comprise first and second sequences corresponding to executions of the BP, which are associated with first and second organizations, respectively. Optionally, the sequences are selected by the example collector module 127.

In Step 171d, extracting a seed from the sequences. Optionally, the extracted seed is the seed 163. Optionally, the seed comprises two or more consecutively performed steps that appear in each of the sequences. Optionally, the seed is extracted utilizing the seed extraction module 160.

In Step 171f, receiving one or more streams of steps performed during interactions with one or more instances of the software system, which belongs to a third organization, which is different from the first and second organizations.

In Step 171g, identifying in the one or more streams occurrences of the seed extracted in Step 171d. Optionally, the occurrences are identified by the seed identification module 165. Optionally, identifying the occurrences involves calculating distances between a certain sequence representing the seed and subsequences of consecutively performed steps from among the one or more streams. Optionally, a subsequence whose distance from the certain sequence is below a threshold is considered an occurrence of the seed. Optionally, distances between the certain sequence and most of the subsequences that are of equal length to the certain sequence are not below the threshold.

In Step 171h, selecting candidate sequences by extending each of the occurrences of the seed by adding to each occurrence of the seed in a stream, from among the one or more streams, at least one additional step that comes before the occurrence of the seed in the stream or after the of the occurrence of the seed in the stream. Optionally, extending the seeds is done by the seed extension module 166.

And in Step 171i, identifying, among the candidate sequences, one or more sequences of steps that correspond to executions of the BP. Optionally, identifying the one or more sequences is done by the BP-identifier module 126. Optionally, identifying the one or more sequences is done utilizing a crowd-based model of the BP, such as the model 118.

In some embodiments, the method optionally includes Step 171a, which involves monitoring interactions with the instances of the software system and generating the streams of steps based on data collected during the monitoring. Optionally, the monitoring is performed by one or more monitoring agents, such as one or more of the monitoring agents 102a to 102d. Additionally or alternatively, the method optionally includes Step 171b, which involves selecting from among the streams of steps the sequences received in Step 171c. Optionally, selecting the sequences is done utilizing the example collector module 127.

In some embodiments, the method optionally includes Step 171e, which involves monitoring the interactions with the instance of the software system and generating the one or more streams received in Step 171f based on data collected during the monitoring. Optionally, the monitoring is performed by one or more monitoring agents, such as one or more of the monitoring agents 102a to 102d.

In some embodiments, the seed extracted in Step 171d may be a seed corresponding to a certain BP. In other embodiments, the seed may represent a common element of more than one BP. For example, the seed may be a certain subsequence of steps that are performed in more than one BP. In these embodiments, the method described above may further include a step of utilizing additional sequences of steps to extract the seed. Optionally, at least some of the additional sequences are selected from among the same streams of steps from which the sequences were selected. Additionally or alternatively, the additional sequences may be selected from among additional streams of steps performed during interactions with instances of the software system. Optionally, the additional sequences are selected by the example collector module 127. The additional sequences each comprise an occurrence of the seed and each of the additional sequences corresponds to an execution of a second BP, which is different from the BP. Thus, when extracting the seed based on its occurrences both in the sequences and among the additional sequences, the seed may reflect an element that is typically performed in more than one BP (and thus may possibly be performed in further other BPs.)

The seed selected in Step 171d may be located in different relative locations of the sequences corresponding to executions of the BP. Thus, depending on the location of the seed, selecting the candidate sequences in Step 171h may involve performing different operations. In one example, the seed is located at the beginning, so Step 171h may involve selecting a candidate sequence by extending an occurrence of the seed in a stream by adding one or more steps that appear in a stream after the occurrence of the seed. In another example, the seed is located at the end, so Step 171h may involve selecting a candidate sequence by extending an occurrence of the seed in a stream by adding one or more steps that appear in a stream before the occurrence of the seed. And in still another example, the seed is located in between, so Step 171h may involve selecting a candidate sequence by extending an occurrence of the seed in a stream by adding one or more steps that appear in the stream before the occurrence of the seed and one or more steps that appear in the stream after the occurrence of the seed.

While in the method illustrated in FIG. 20 describes a single seed that is extracted and utilized, in some embodiments multiple seeds may be extracted and utilized to generate candidate sequences. Thus, in some embodiments, the method may optionally include the following steps: extracting an additional seed from the sequences received in Step 171c, and selecting the candidate sequences such that each of the candidate sequences comprises an occurrence of the seed and an occurrence of the additional seed. Optionally, the additional seed comprises one or more consecutively performed steps that appear in at least some of the sequences.

In some embodiments, extending occurrences of the seed is by adding one or more steps with the same value for a certain EDA, which is observed in steps belonging to the occurrence of the seed. Optionally, in these embodiments, Step 171h may involve performing the following operations: (i) identifying a value of the certain EDA in at least one of the steps belonging to an occurrence of the seed in a stream from among the one or more streams, and (ii) generating a candidate sequence by extending the occurrence of the seed with at least some steps from the stream that are associated with the same value of the certain EDA.

1—Software Systems

A “software system”, as used in this disclosure, may refer to one or more of various types of prepackaged business applications, such as enterprise resource planning (ERP), supply chain management (SCM), supplier relationship management (SRM), product lifecycle management (PLM), and customer relationship management (CRM), to name a few. These packaged applications may be supplied by a variety of vendors such as SAP, ORACLE, and IBM, to name a few. The aforementioned software systems may be also be referred to as “enterprise systems”. Enterprise systems are typically back-end systems that support an organization's back office. The “back office” is generally considered to be the technology, services, and human resources required to manage a company itself. In some embodiments, an enterprise system can process data related to manufacturing, supply chain management, financials, projects, human resources, etc. Optionally, the data may be maintained in a common database through which different business units can store and retrieve information. A software system may also be referred to as an “information system”.

Having an enterprise system can be advantageous for a number of reasons, including standardization, lower maintenance, providing a common interface for accessing data, greater and more efficient reporting capabilities, sales and marketing purposes, and so forth. In one example, an ERP system, which is a type of an enterprise system, integrates many (and sometimes even all) data and processes of an organization into a unified system. A typical ERP system may use multiple components, each involving one or more software modules and/or hardware element, to achieve the integration.

Additionally, as used herein, a “software system”, may refer to a computer system with which a user and/or a computer program (e.g., a software agent) may communicate in order to receive and/or provide information, and/or in order to provide and/or receive a service. In some embodiments, a software system may operate a website that is accessed via a network such as the Internet (e.g., the software system may comprise an email client, a website in which orders may be placed to a supplier, etc.) In some embodiments, a software system may be used to provide applications to users and/or computer programs via a Software as a Service (SaaS) approach in which applications are driveled over the Internet—as a service. Thus, in some embodiments, a software system that is utilized by an organization is not installed on hardware that belongs to the organization.

Essentially the same software system may be installed multiple times (e.g., for multiple organizations). Each installation of a software systems may be considered herein an “instance” of the software system. For example, a software system, such as an operating system (e.g., Microsoft's Windows), may have many millions of instances installed worldwide. Similarly, various installations of packaged applications at different organizations, may be considered different instances of a certain software system (e.g., a SAP ERP software system). It is to be noted that at times, herein, the term “instance” may be omitted without alluding to a different meaning. Thus, for example, a phrase such as “interacting with a software system” has the same meaning in this disclosure as the phrase “interacting with an instance of a software system”.

Running an instance of a software system may involve one or more hardware components (e.g., one or more servers and/or terminals). In some embodiments, these hardware components may be located at various geographical sites and/or utilize various communication networks (e.g., the Internet) in order to operate. In one example, servers are located at multiple sites and are accessed via a large number of terminals. Herein, a terminal may be realized utilizing various forms of hardware, such as personal computers and/or mobile computing platforms.

What is a considered an “instance of a software system” may vary between different embodiments described in this disclosure. Following are various criteria and/or architectural possibilities that may exemplify what may be considered, in various embodiments described herein, same or different instances of a software system.

In some embodiments, when a software system is run on different hardware at different locations (e.g., the software system is run on servers at different sites), then the processes running at the different locations are considered to belong to different instances of the software system. In one example, packages installed on hardware at one site belonging to an organization (e.g., installed on hardware located in a first country) may be considered a different instance of a certain software system than (the same) packages installed on hardware at another site belonging to the organization (e.g., installed on hardware located in a second country).

In some embodiments, the same hardware (e.g., servers) and/or software may be used to run different instances of a certain software system. Optionally, interactions with the certain software system, which involve utilizing different accounts and/or different configuration files, may be considered interactions with different instances of the certain software system. Optionally, each instance may have different default settings and/or different selected behavioral options, which are suitable for a certain user, a certain department, and/or a certain organization.

In one example, a software system, which is a cloud-based service, provides services to users (e.g., a SaaS application). A first interaction of a user from a first organization (having a first account) with the software system may be considered to involve a different instance of the software system than an instance of the software system involved in a second interaction of a user from a second organization (having a second account). In this example, the interactions may be considered to involve different instances of the software system even if the users receive essentially the same service and/or even if both users interact with the same computer servers and/or with the same program processes.

While in some embodiments, different instances of a software system may exhibit the same behavior, in other embodiments, different instances of a software system may exhibit a different behavior. For example, different instances of the same software system belonging to different organizations may allow execution of different Business Processes (BPs), execution of different transactions, display different screens, etc. Adjusting an instance's behavior may be done in various ways in different embodiments. Optionally, an instance's behavior may be adjusted using custom code. Additionally or alternatively, an instance's behavior may be adjusted using configuration options.

In some embodiments, the behavior of a software system that includes a packaged application may be changed utilizing custom code. For example, various modules belonging to the packaged application may include “standard” code, such as code that is created and released by a vendor. In this example, the standard code may enable an instance of a software system to exhibit a typical (“Vanilla”) behavior. Custom code, in this example, may be code that is developed in order to exhibit certain atypical behavior, which may be more suited for a certain organization's goals or needs. In one embodiment, custom code is additional code that is added to a packaged application that is part of an instance of a software system belonging to an organization. For example, the additional code may be code describing additional BPS, transactions, functions, screens, and/or operations that are not part of a typical release of the packed application. In another embodiment, the custom code may replace portions of the standard code that is used to implement a module of a packaged application. In this embodiment, the custom code can change the (standard) behavior of certain BPs, transactions, and/or operations, and/or alter the way certain screens may look (e.g., a screen layout and/or a selection of fields that appear on a screen).

In other embodiments, a software system, such as an ERP or another type of software system, may be designed and/or developed to include many options to choose that allow for various aspects of a software system to be adjusted. Having multiple behavior options that may be adjusted may be useful by providing an organization with the flexibility to personalize an instance of a software system to the organization's specific needs. In one example, such adjustments may be done as part of customization of a SAP ERP system. In another example, such adjustments may be done as part of the setup of an E-Business Suite of Oracle (EB-Suite/EBS).

Herein, any adjustments of the behavior of an instance of a software system that do not involve utilization of custom code may be considered adjustments of the software system's configuration. The term “configuration file” is used herein to denote data that may be used to configure an instance of a software system that may cause it to operate in a certain way. The data may comprise various menu options, entries in files, registry values, etc. Use of the term “configuration file” is not intended to imply that the data needs to reside in a single memory location and/or be stored in a single file, rather, that the data may be collected from various locations and/or storage media (and the collected data may possibly be stored in a file). Additionally, having a different configuration file does not imply that different instances may necessarily behave differently in similar interactions (e.g., when provided similar input by a user). A “configuration file” may also be referred to herein in short as simply a “configuration”.

In one embodiment, a configuration of an instance of a software system may include meta-data tables that are used to store configuration data in SAP ERP software systems. In this embodiment, at least some portions of the meta-data tables may be used to define which transactions to execute as part of a BP, which screens to display in a certain transactions, and/or what fields to display on those screens. In another embodiment, during the setup stage of an Oracle EBS software system, various organization-specific parameters may be set. For example, the setup may be used to set parameters such as a tax rate applicable for a certain country and/or addresses to send invoices.

The disclosure includes various references involving phrases such as “an instance of a software system belonging to an organization” (and variations thereof). This phrase is intended to mean that the instance belongs to the organization and not necessarily that the software system belongs to the organization (though that may be the case in some embodiments). When an instance belongs to an organization, it means that interactions with the instance are done on behalf of the organization, e.g., in order to execute business processes for the organization. In some embodiments, using a phrase such as “an instance of a software system belonging to an organization” implies that the organization (and/or an entity operating on behalf of the organization) has a license and/or permission to utilize the software system. In other embodiments, the phrase implies that the instance is customized to operate with users belonging to the organization. In some embodiments, an instance of a software system belonging to an organization operates utilizing hardware that belongs to the organization (e.g., servers installed in a facility that is paid for by the organization) and/or it operates utilizing other computational resources paid for by the organization and/or which the organization is permitted to use (e.g., the organization pays for cloud-based computational resources utilized by the instance).

Various embodiments described herein involve interactions with instances of one or more software systems. In some embodiments, an interaction with an instance of a software system may involve a user performing certain operations that cause the instance of the software system to act in a certain way (e.g., run a program) and/or cause the instance to provide information (e.g., via a user interface). Additionally or alternatively, instead of (or in addition to) the user performing operations and/or receiving information, an interaction with the instance of the software system may involve a computer program (e.g., a software agent and/or an instance of another software system), which interacts with the instance of the software system in order to perform operations and/or receive information.

In some embodiments, interaction with an instance of a software system may include performing operations involved in execution of a Business Process (BP). Additionally or alternatively, an interaction with an instance of a software system may include performing operations involved in testing the software system. For example, interaction with an instance of a software system may involve running scripted tests by a human and/or a software program, and/or execution of various suites of tests (e.g., regression testing).

A Business Process (BP), which may also be referred to as a “business method”, is a set of related and possibly ordered, structured activities and/or tasks (e.g., involving running certain programs) that produce a specific service and/or product to serve a particular goal for one or more customers. Optionally, the set of activities may be ordered (e.g., represented as a sequence of activities) and/or partially ordered (e.g., allowing for at least some of the activities to be done in parallel or in an arbitrary order). Each of the one or more customers may be an internal customer, e.g., a person or entity belonging to an organization with which an execution of the BP is associated, or an external customer, e.g., an entity that does not belong to the organization.

Execution of a BP in this disclosure typically involves execution of one or more transactions. A “transaction”, as used herein, involves running one or more computer programs. In some embodiments, running a computer program produces one or more “screens” through which information may be entered and/or received. Each screen may include various components via which data may be entered (e.g., fields, tabs, tables, and checkboxes, to name a few). Additionally, various operations may be performed via screens, which may involve one or more of the following: sending information (e.g., sending data to a server), performing calculations, receiving information (e.g., receiving a response from the server), clicking buttons, pressing function keys, selecting options from a drop-down menu, to name a few. In one example, an operation may involve sending to a server information entered via a screen, and receiving a response from the server indicating an outcome of the operation (e.g., whether there was an error or whether the data entered was successfully processed by the software system).

In some embodiments, a transaction may be performed utilizing various forms of user interfaces. For example, a transaction may involve access and/or manipulation of data presented to a user via an augmented reality system, a virtual reality system, and/or a mixed-reality system. Thus, a “screen” as used in this disclosure may refer to any interface through which data may be presented and/or entered as part of executing a transaction. For example, a screen may be an area in a virtual space in which data is presented to a user. In another example, a screen may be a layer of data overlaid on a view of the real world (e.g., an augmented reality data layer). Thus, the use of a “screen” is not intended to limit the scope of the embodiments described herein to traditional systems in which data is viewed via a 2D computer monitor.

2—Organizations

Herein, the term “organization” is used to describe any business, company, enterprise, governmental agency, and/or group comprising multiple members in pursuit of a common goal (e.g., a non-governmental organization). In some embodiments, different organizations are businesses, companies, and/or enterprises that have different ownership structures. For example, a first organization is different from a second organization if the first organization is owned by a different combination of shareholders than the second organization. In other embodiments, different organizations may be different companies that are characterized by one or more of the following attributes being different between the companies: the company name, the company's corporate address, the combination of stockholders, and the symbol representing each of the companies in a stock exchange. For example, different organizations may be represented by different symbols (tickers) in one or more of the following US stock exchanges: NYSE, AMEX, and NASDAQ. In still other embodiments, different organizations may have different members belonging to them. For example, a first organization that has a first set of members that belong to it is considered different from a second organization that has a second set of members that belong to it, if the first set does not belong to the second organization and the second set does not belong to the first organization. Optionally, the first and second organizations are considered different organizations of the first set includes at least one member that does not belong to the second set, and the second set includes at least one member that does not belong to the first set.

Herein, a user belonging to an organization is a person that is an employee of the organization and/or is a member of a group of people that belong to the organization. Optionally, a user belonging to an organization operates with permission of the organization and/or on behalf of the organization.

Each time a BP is run (executed) this may be considered an execution of the BP. Herein, an execution of a BP is associated with an organization if at least one of the following statements regarding the execution are true: (i) the execution of the BP involves at least some steps that are performed by a user belonging to the organization (e.g., the at least some steps are performed by an employee of the organization), and (ii) the execution of the BP involves at least some steps that are performed on an instance of a software system belonging to the organization.

3—Monitoring Activity

Various embodiments described in this disclosure involve collecting and/or utilizing data obtained by monitoring activity involving interactions with instances of one or more software systems. In different embodiments, the data collected from monitoring may have various formats. Additionally, in different embodiments, the data may be obtained from various sources and/or may be collected utilizing various procedures.

In some embodiments, data obtained by monitoring may include at least one or more of the following types of data: data describing interactions with user interfaces, data provided by a user (e.g., as input in fields in screens), data provided by a software system (e.g., messages returned as a response to operations), data exchanged between a user interface and a server used to run an instance of a software system (e.g., network traffic between the two), logs generated by an operating system (e.g., on a client used by a user or a server used by an instance of a software system), and logs generated by the instance of the software system (e.g., “event logs” generated by the software system).

Typical numbers dozens of users, if not hundreds, thousands, or tens of thousands of users or more. In some embodiments, each user executes, on average, at least 5, at least 10, at least 25, or at least 100 daily transactions. Optionally, each transaction involves, on average, entering data in at least three screens and/or entering data in at least three fields (some transactions may involve entering data in to a larger number of fields such as dozens of fields or more). In one example, monitoring a user's daily interactions with one or more software systems involves generating data that includes at least one of the following volumes of data: 1 KB, 10 KB, 100 KB, 1 MB, and 1 GB.

Herein, modules that are used to collect data obtained by monitoring activity involving interactions with instances of software systems are generally referred to as “monitoring agents”. A monitoring agent is typically realized by a software component (e g, running one or more programs), but may also optionally include, in some embodiments, a hardware component that is used to obtain at least some of the data. In one example, the hardware component may involve a device that intercepts and/or analyzes network traffic. It is to be noted that realizing a monitoring agent may be done utilizing a processor, which may optionally be one of the processors utilized for interaction of with the instance of the software system. For example, the processor may belong to at least one of the following machines: a client that provides a user with a user interface via which the user interacts with the instance of the software system, and a server on which the instance of the software system runs.

A monitoring agent may collect, process, and/or store data describing interactions with an instance of a software system. Optionally, the data is represented as a stream of steps. Optionally, a step describes an action performed as part of an interaction with the instance of the software system. For example, a step may describe an execution of a transaction and/or performing of a certain operation. Optionally, a step may describe information received from the instance (e.g., a status message following an operation performed by a user). In some embodiments, a step may describe various aspects of the interaction with a software system. For example, a step may describe a record from a log, a packet sent via a network, and/or a snapshot of a system resource such as a database. Thus, in some embodiments, a “step” may be considered similar to an “event” as the term is used in the literature, but a “step” is not necessarily extracted from an event log; it may come from the various sources data that may be monitored, as described in this disclosure. In some embodiments, due to the large volume of “raw” monitoring data that may be obtained (e.g., extensive logs generated by servers), abstracting the activity as a series (stream) of steps can ease the tasks of storage and/or analysis of the monitoring data.

In some embodiments, monitoring activity involving the interactions with instances of software systems does not interfere and/or alter the interactions. For example, the fact that a monitoring agent operates does not alter input provided by a user and/or responses generated by an instance of the software system with which the user interacts at the time. In another example, disabling the monitoring does not interfere with the activity (e.g., it does not impede executions of BPs). Additionally, in some embodiments, a user may not be provided an indication of when and/or if a monitoring agent is monitoring activity that involves interactions of the user with an instance of a software system.

A monitoring agent may be categorized, in some embodiments, as being an “internal monitoring agent” and/or an “interface monitoring agent”. Generally put, an internal monitoring agent is a monitoring agent that utilizes functionality of the software system with which an interaction occurs, while the interface monitoring agent, as it names suggests, relies more on data that is provided and/or received via a user interface. Thus, in some embodiments, an internal monitoring agent may be considered to involve the “back-end”, while the interface monitoring agent is more concentrated on the “front-end”. It is to be noted that in some embodiments, a monitoring agent may be considered to be both an internal monitoring agent and an interface monitoring agent. For example, a monitoring agent may have some capabilities and/or characteristics typically associated with an internal monitoring agent and some capabilities and/or characteristics typically associated with an interface monitoring agent.

When a monitoring agent collects data describing interactions with an instance of a software system, the interaction may involve a user interacting with the instance. In some embodiments, a server provides, as part of the interaction, information to the user via a user interface (UI) that runs on a client machine that is not the server. Optionally, in some of these embodiments, an internal monitoring agent is realized, at least in part, via a program executing on a processor belonging to the server, and an interface monitoring agent may be realized, at least in part, via a program executing on the client. Optionally, operating the internal monitoring agent does not involve running a process on the client machine in order to collect data describing the interaction. Optionally, operating the interface monitoring agent does not involve running a process on the server in order to collect data describing the interaction.

In some embodiments, an internal monitoring agent monitoring interactions with an instance of a software system may be configured to utilize an Application Program Interface (API) of the software system. Issuing instructions via the API may cause the instance of the software system to execute a certain procedure that provides the internal monitoring agent with data indicative of at least some steps performed as part of the interactions.

When used to monitor an instance of a software system that includes one or more packaged applications, in some embodiments, an internal monitoring agent may be configured to perform at least one for the following operations: (i) initiate an execution, on the instance of the software system, of a function of a packaged application, (ii) retrieve, via a query sent to the instance of the software system, a record from a database, and (iii) access a log file created by the instance of the software system. Optionally, the database may be maintained by a packaged application. Optionally, the log file may be an event log created by a packaged application, and it may include a description of the state of the application and/or describe data provided to, and/or received from, the instance of the software system when running the packaged application. In one example, the event log may be in one of the following formats: XML, XES (eXtensible Event Stream) and MXML (Mining eXtensible Markup Language).

An internal monitoring agent may have access to information that is not presented to a user interacting with a software system (e.g., information received using an API or information from a log file, as described above). Thus, the internal monitoring agent may, in some embodiments, collect data related to a transaction performed by a user, and at least some of the data related to the transaction is not be presented to the user via a user interface (UI) utilized by the user to perform the transaction.

An interface monitoring agent may, in some embodiments, be configured to extract information from data presented on a user interface (UI) used by a user while interacting with an instance of a software system (e.g., while the user executes BPs). Optionally, the interface monitoring agent may be configured to perform image analysis (e.g., optical character recognition to images on a display), semantic analysis to text presented to the user, and/or speech recognition applied verbal output presented to the user. Additionally or alternatively, the interface monitoring agent may be configured to analyze input provided by a user via a user interface (UI). Optionally, the input may be provided using at least one of the following devices: a keyboard, a mouse, a gesture-based interface device, a gaze-based interface device, and a brainwave-based interface device. Additionally or alternatively, the interface monitoring agent may be configured to analyze network traffic exchanged during an interaction with an instance of a software system between a terminal used by a user and a server belonging to the instance.

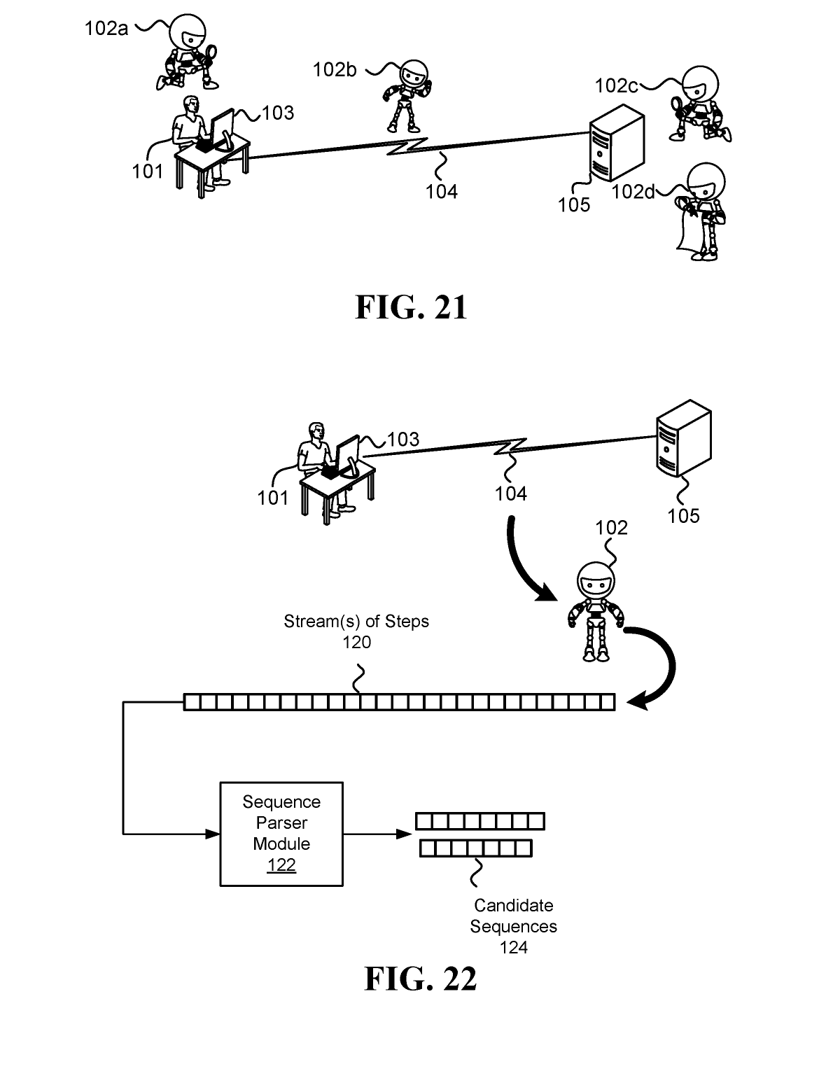

FIG. 21 illustrates some of the different monitoring agents that may be utilized in some of the embodiments described in this disclosure. A user 101 utilizes a terminal 103 to interact with a server 105 running an instance of a software system. Optionally, interacting with the instance may involve communication such as network traffic 104. Interactions with the instance may be monitored by different types of monitoring agents. In one example, monitoring agent 102a is an interface monitoring agent that collects information by analyzing the terminal 103. For example, the monitoring agent 102a may perform image analysis of images presented to the user 101 on a screen of the terminal 103 and/or extract information from key strokes of the user 101 on a keyboard connected to the terminal 103. In another example, monitoring agent 102b is an interface monitoring agent that collects information by analyzing the network traffic 104 between the terminal 103 and the server 105. In yet another example, monitoring agent 102c is an internal monitoring agent that is configured to collect data by observing the operations of the instance of the software system and/or interacting with it (e.g., by making calls to an API of the software system in order to get certain information). And in still another example, monitoring agent 102d may be an internal monitoring agent that collects information from logs, such as event logs generated by the server 105.

In some embodiments, a monitoring agent (e.g., an internal monitoring agent or an interface monitoring agent) may have knowledge of the type of operations involved in performing certain BPs (e.g., it may derive information from models described below). In one example, such knowledge may be utilized by an internal monitoring agent to perform certain types of operations (e.g., certain calls to an API). In another example, an interface monitoring agent may process data it collects in a certain way based on the knowledge about which steps the certain BPs involve.

Interactions with instances of software systems often involve exchange of data that may be considered private and/or proprietary. For example, the data may include details regarding the organization's operations and/or information regarding entities with which the organization has various relationships (e.g., the entities may be employees, customers, etc.) Therefore, in some embodiments, various measures may be employed in the operation of monitoring agents in order to limit what data is collected in order to achieve certain privacy-related goals. In one embodiment, a monitoring agent may operate using inclusion lists (“whitelists”) specifying what data it can collect. For example, an inclusion list may specify which objects may be reported in the monitoring data (where examples of objects may include BPs, transactions, screens, fields, and/or operations). Additionally, the inclusion lists may specify what type of information may be reported for each of the objects mentioned above (e.g., what associated data may be reported). In another embodiment, a monitoring agent may operate using exclusion lists (“blacklists”) specifying what data it should not collect. For example, an exclusion list may specify which BPs, transactions, screens, fields, and/or operations should not be reported in monitoring data. Additionally, the exclusion lists may specify what type of information should not be reported for each of the objects mentioned above. For example, an exclusion list may specific that personal data such as names, addresses, email accounts, phone numbers, and bank accounts are not to be recorded by a monitoring agent.

4—Streams and Steps

Data collected by monitoring agents may, in some embodiments, be represented as one or more streams of steps. Optionally, each monitoring agent generates a stream of steps that describes at least some aspects of interaction(s) with an instance of a software system. Typically, in a stream of steps, a first step that appears before a second step in the stream represents a first aspect of the interaction that occurred before a second aspect represented by the second step. Optionally, each step represents one or more of the following aspects: a certain transaction executed in the step, a certain screen accessed as part of performing the step, a certain field that was updated as part of the step, a certain operation performed as part of the step, and a certain message received from the instance of the certain software system as part of the step. For example, steps can be generated by trapping of message exchanges (e.g., SOAP messages) and recording read and write actions.

Aspects of interactions with an instance of a software system may be represented in different embodiments as steps that contain different types of data. Optionally, steps may correspond to different resolutions at which the interactions may be considered. In one embodiment, a step may identify a transaction executed as part of the interactions. For example, each step in a stream may describe an identifier (e.g., a code or name) of a transaction that is executed. In another embodiment, a step may identify a program executed as part of the interactions. Optionally, such a step may also include a description of how the program was invoked (e.g., a command line and/or a description arguments passed to the program) and/or an output representing a status of the termination of the program.

Often interacting with instances of software systems (e.g., enterprise systems) may involve entering and/or receiving data via screens that have fields, menus, tabs, etc. through which data may be provided to the software system and/or received from it. Data regarding screens and/or fields may also be represented in steps. In one embodiment, a step may include a description of a screen accessed by a user (e.g., as part of executing a transaction). For example, a step may include a screen name, URL, and/or other form of identifier for a screen. In another embodiment, a step may include a description of a field accessed on a screen (e.g., a name and/or number identifying the field and/or the screen on which the field is located). In still another embodiment, a step may include a description of a value entered to a field on a screen.

Interacting with instances of software systems may involve performing various operations. Some examples of operation include selecting a menu option, pushing a certain button, issuing a verbal command, issuing a command via a gesture, and issuing a command via thought (which may be detected by measuring brainwave activity). In some embodiments, a step may describe a certain operation performed as part of an interaction with a software system. Optionally, a step may include a description of a response by the instance of the software system to the operation (e.g., a response indicating success or failure of the operation).

In some embodiments, a step describing an aspect of an interaction with an instance of a software system may include a description of a message generated by the instance (e.g., as response to executing a certain transaction, performing an operation, etc.). Additionally, the step may include one or more other system-generated messages, such as status messages generated by an operating system and/or a network device.

A step belonging to a stream comprising steps performed as part of an interaction with an instance of a software system may be associated with one or more values that are related to the interaction. Optionally, storing the step and/or a stream to which the step belongs involves storage of the one or more values associated with the step. In one embodiment, a step may be associated with at least one of the following values: a time the step was performed (i.e., a timestamp), an identifier of a user who performed the step, an identifier of the organization to which the user belongs, an identifier of the instance of the software system, and an identifier of the software system. It is to be noted that the timestamp may refer to various times in different embodiments, such as the time the step began and/or the time the step ended. In another embodiment, a step may be associated with an identifier (a BP ID) of the BP of whose execution the step is a part. Optionally, the BP ID may include a name, a code, and/or number, which identify the BP and/or variant of the BP. In one example, the identifier of the BP is provided by the system (e.g., a user may execute the BP by pushing a button or selecting it from a menu). In another example, a user may label certain steps, and/or steps performed during a certain time, as belonging to an execution of the BP.

It is to be noted that in some embodiments, the term “step” may be considered similar to the term “event” which is often used in the literature. In particular, a step that appears in a log file may be considered similar to an event in an “event log”. Additionally, execution of a BP may be considered similar to a “business process instance”, a “process instance”, or simply “case” as the terms are often used in the literature. Therefore, in some embodiments, steps may be associated with an identifier of the case (“case ID”) to which they belong (i.e., an identifier of the execution of which they are a part). In other embodiments, some steps may be unlabeled, which means there may be no indication of which case they belong to (i.e., they may have no associated case ID).

Interactions with modern software systems may, in many cases, involve generation and/or communication of very large quantities of data. This data may undergo various forms of processing and/or filtering in order to make its analysis more efficient, or even tractable. Those skilled in the art will recognize that various techniques may be utilized to convert “raw” monitoring data to streams of steps. This process is sometimes referred to in data science using the phrase “Extract, Transform, and Load” (ETL) is used to describe the process that involves: extracting data from outside sources, transforming it to fit operational needs (e.g., dealing with syntactical and semantical issues while ensuring predefined quality levels), and loading it into the target system, e.g., by providing it to other modules (e.g., as the streams of steps mentioned herein) and/or storing it, e.g., in a data warehouse or relational database. In one example, logs may be examined to identify executions of certain transactions and/or programs (which may then be represented as steps). In another example, machine learning-based algorithms may be trained and utilized to identify certain steps based on patterns in data obtained by monitoring (e.g., certain patterns in network traffic and/or in messages generated by a program run by a packaged application or an operating system); optionally, some steps may be indicative of the presence of such patterns.

In some embodiments, data collected by monitoring may be processed in order to remove data that may be considered private (e.g., proprietary data of an organization and/or clients). In one example, certain values in the data may be removed (e.g., social security numbers, bank account numbers, etc.) In another example, certain values in the data may be replaced by “dummy” values (e.g., fictitious records) and/or hash values of the data, which may assist in determining when two fields have the same certain value without the need to know what the certain value is.

In some embodiments, generating streams of steps may involve merging various sources of data (e.g., data from various monitoring agents). The different sources may have different levels of abstractions and/or use different formats. Merging such data may require changing the format and/or level of abstraction of data from some of the sources. The reference Raichelson, et al. “Merging Event Logs with Many to Many Relationships.” International Conference on Business Process Management. Springer International Publishing, 2014, describes some approaches that may be applies for merging monitoring data from multiple sources. Additionally, approaches for generating different levels of abstraction for data obtained from monitoring are discussed in Baier et al. “Bridging abstraction layers in process mining: Event to activity mapping.” Enterprise, Business-Process and Information Systems Modeling. Springer Berlin Heidelberg, 2013. 109-123. Approaches for bringing different sources to a common format are discussed in U.S. Pat. No. 6,347,374 filed Jun. 5, 1998, and titled “Event Detection”.

It is to be noted that the use of the term “stream” is not intended to imply a certain scope and/or medium of storage of steps derived from monitoring interactions with one or more instances of one or more software systems. Rather, the term stream may be interpreted as having steps accessible in a way that allows evaluation of aspects of the monitored interactions. Thus, in different embodiments, a stream of steps may represent different types of data and/or may be stored in different ways, as described in the following examples.

In one embodiment, a stream of steps may include steps derived from monitoring of interactions of a certain entity (e.g., a user or a program) with an instance of a certain software system (e.g., an ERP).

In another embodiment, a stream of steps may include steps derived from monitoring of interactions of a certain entity (e.g., a user or a program) with multiple instances of software systems. For example, the stream may include steps performed on an instance of an ERP system and some other steps performed on a separate CRM system. Optionally, when a stream includes steps performed on various instances, at least some of the instances may belong to different organizations.

In yet another embodiment, a stream of steps may include steps derived from monitoring of interactions of various entities (e.g., users or programs) with instances of a software system. For example, the stream may include steps performed by various users in an organization with an instance of a certain software system (e.g., an SCM system). In another example, the stream may include steps performed by various users (possibly belonging to different organizations) with an instance of a software system via a certain website that is accessed by the various users.

And in still another embodiment, a stream of steps may include steps derived from monitoring of interactions of various entities (e.g., users or programs) with multiple instances of a software system. For example, the stream may include steps performed in an organization, which involves multiple users interacting with multiple instances of software systems. In another example, the steam may include cross-organizational interactions, which include steps performed by various users from various organizations on different instances of software systems.

In some embodiments, a stream of steps is stored in computer readable memory (e.g., on a hard-drive, flash memory, or RAM). Optionally, a stream is stored in a contiguous region of memory. However, use of the term “stream” herein is not meant to imply that the data comprised in a stream (steps) are stored in a single file or location. In some embodiments, a stream may be stored distributedly, in multiple files, databases, and/or storage sites (e.g., a stream may be stored in cloud storage or stored distributedly utilizing a blockchain).

In some embodiments, a stream of steps is not stored as a logical unit, but rather is generated on the fly when it is requested. For example, monitoring data may be stored in one or more databases, and a request for a stream is translated into a query that retrieves the required data from the one or more databases and presents it as a stream of steps. Optionally, the required data may be “raw” data obtained from monitoring, and a representation as steps is created by processing the data following the query.

In other embodiments, a stream of steps me be received and processed essentially as it is generated. For example, steps in the stream are analyzed within minutes of the occurrence of the events to which they correspond. Optionally, this enables at least some of the data generated from monitoring to be discarded without requiring its long-term storage.

A stream of steps may be stored, in some embodiments, in a way that enables it to be viewed at different resolutions. For example, when used for a certain application, such as identifying which BPs were run, the stream may be represented with less details (e.g., the stream may identify describe transactions were executed on an instance of a software system). However, when used for another application, such as when the stream is evaluated to discover a cause of an error and offer an alternative set of operations to perform, the stream may be viewed at a higher resolution and contain more details. Optionally, when viewed in such a higher resolution, the stream may contain more steps (with multiple “little” steps corresponding to a single “lower resolution” step, which may be a transaction).

Data collected through monitoring of interactions with an instance of a software system may be stored in different streams, in some embodiments. This may be done to separate data collected at different times. For example, in one embodiment, steps performed during interactions with the instance of the software system during a certain day may be stored in one stream, while steps performed during interactions with the instance of the software system on another day are stored in another stream.

To efficiently store and/or analyze steps, in some embodiments, each step belonging to a stream is represented by a symbol belonging to a set of symbols. Typically, certain symbols may represent multiple steps in the stream (i.e., steps performed at different times), thus the number of symbols in the set of symbols is smaller than the number of steps in the stream. In one example, most of the symbols in the set of symbols are used to represent at least two different steps that appear in a stream of steps. Utilizing a symbol representation for steps may enable, in some embodiments, efficient searching of streams (e.g., to identify patterns) and/or efficient, less space consuming storage.

5—Selecting Sequences from Streams

Some of the embodiments described in this disclosure involve extracting (also referred to as “selecting” or “parsing”) sequences of steps from one or more streams. When steps in streams include an identifier indicative of what BP they belong to (e.g., a “BP ID”, and/or to which execution of a BP they belong to (e.g., “a case ID”), selecting sequences from the streams may be relatively straightforward and involve collection of steps that have a certain value for the identifier (e.g., steps corresponding to events with the same case ID). This typically happens with Process Aware Information Systems (PAIS) in which the system executes BPs according to known models. However, in some embodiments, steps in streams may not have such an identifier that enables a straightforward identification of the execution to which they correspond. For example, data collected by an interface monitoring agent may not be complete and may lack certain pieces of information that would be known to the user but not to a 3rd party observer who examines the user's screen. In another example, a user may be performing a certain set of operations that do not correspond to a known BP. In this example, the set of operations may correspond to a new BP or new variant of a known BP.

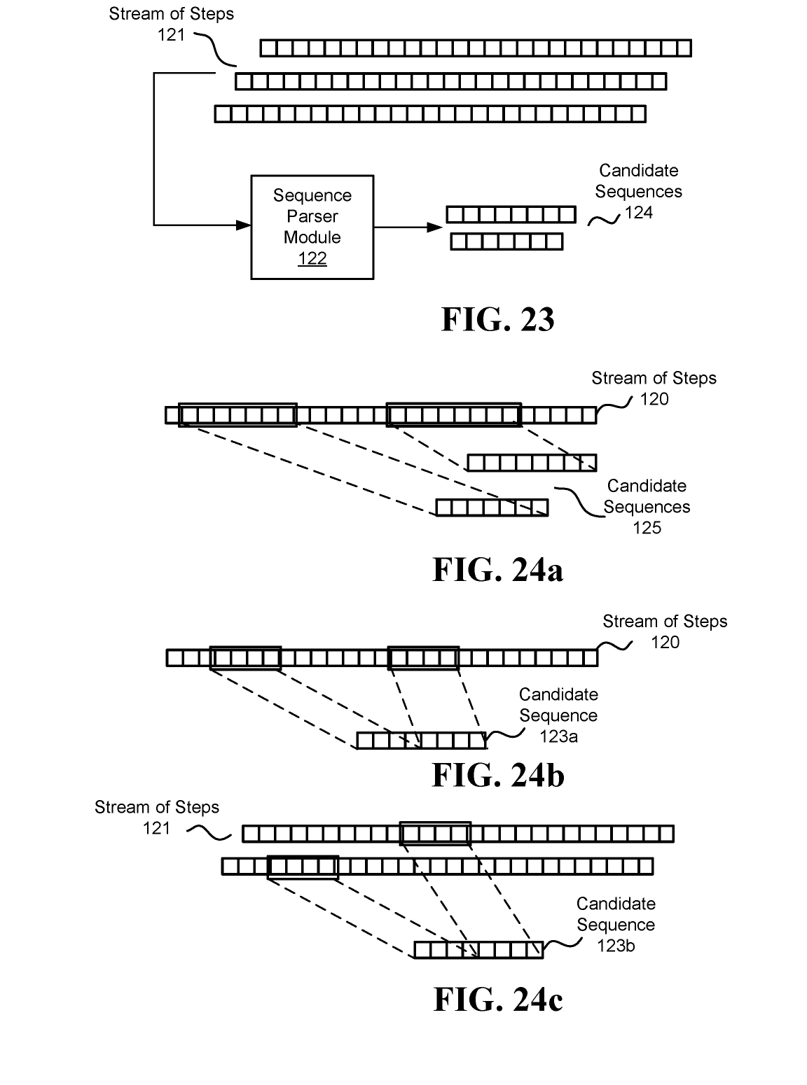

Given one or more streams of steps generated via monitoring (e.g., by a plurality of internal monitoring agents and/or interface monitoring agents), in some embodiments, sequences are selected from the one or more streams. Optionally, this is done utilizing a module referred to herein as a “sequence parser module”, which is configured to receive the streams of steps and to select, from among the streams, a plurality of sequences of steps. Selected sequences of steps may be forwarded for further analysis, such as using models of BPs to identify for each sequence whether there is a BP to which the sequence corresponds. FIG. 22 illustrates an example of how this selection may be performed in some embodiments. The user 101 interacts with the server 105 that runs an instance of a software system. Monitoring agent 102, which may be for example any of the monitoring agents 102a to 102d, generates one or more streams 120 that includes steps performed during an interaction of the user 101 with the instance of the software system. The one or more streams 120 are forwarded to sequence parser module 122 that selects, from among the steps belonging to the one or more streams, candidate sequences 124. It is to be noted that in some embodiments, the sequence parser module 122 may receive multiple streams of steps from among which the candidate sequences may be selected. This is illustrated in FIG. 23, where streams of steps 121 are provided to the sequence parser module 122, and from which the candidate sequence 124 are selected.

Depending on how the sequences are selected, the sequences of steps may have various properties. In particular, in some embodiments, at least some sequences of steps selected from one or more streams may be consecutive sequences of steps, which are sequences in which all the steps are consecutive steps. Herein, consecutive steps are steps that are performed directly one after the other (i.e., they are consecutively performed). In one example, if a sequence comprising consecutive steps includes first and second steps such that, in the sequence, the second step appears directly following the first step, then the first and second steps also appear that way in a certain stream from which they were taken. That is, in the certain stream, the second step comes directly after the first step, and there is no third step in between the two. FIG. 24a is a schematic illustration of selection of consecutively performed sequences of steps. The figure illustrates how sequences from among candidate sequences 125 appear as consecutive sequences of steps within a stream of steps from among the one or more streams 120.

In some embodiments, at least some sequences of steps selected from one or more streams may not be consecutive sequences of steps (also referred to as “nonconsecutive sequences of steps”). Such sequences include first and second steps, such that the second step appears in the sequence directly after the first step, but the first and second step are not consecutively performed.

In one embodiment, the first and second steps may belong to a certain stream, but in the certain stream, there is at least a third step, which is performed after the first step is performed, but before the second step is performed (and the third step does not belong to the sequence). Parsing this type of sequence is illustrated in FIG. 24b in which candidate sequence 123a appears to comprise to subsequences from a stream of steps from among the one or more streams 120, where between the two subsequences there are steps that do not belong to the candidate sequence 123a.

In another embodiment, the first step comes from a first stream and the second step comes from a second stream. This is illustrated in FIG. 24c in which candidate sequence 123b comprises two subsequences that come from two different streams of steps from among the streams of steps 121. There may be various options when steps from different streams are combined into a sequence of steps. In one example, a sequence of steps, from among the selected sequences, comprises a first step performed on a first instance of a first software system from among a plurality of software systems, and a second step performed on a second instance of a second software system from among the plurality of software systems, which is different from the first software system. Optionally, the first and second steps involve executing different transactions. In another example, a sequence of steps, from among the selected sequences, comprises a first step performed by a first user and a second step performed by a second user, who is different from the first user. Optionally, the first and second steps involve executing different transactions. And in yet another example, a sequence of steps, from among the selected sequences, comprises: (i) a first step generated by a first monitoring agent that is used to monitor a first instance of a first software system from among the one or more software systems, and (ii) a second step generated by a second monitoring agent that is used to monitor a second instance of a second software system from among the one or more software systems. In this example, the first monitoring agent is an internal monitoring agent, the second monitoring agent is an interface monitoring agent, and the first software system is different from the second software system.

Since it may not be known to which BP or execution of a BP each step corresponds, it is possible that in some embodiments, a sequence of steps selected from one or more streams may include steps belonging to different executions of the same BP and/or steps belonging to different executions of different BPs. It is to be noted that in some embodiments, a sequence of steps may be considered to correspond to an execution of a certain BP even if the sequence includes some steps that are not involved in the execution of the certain BP (in this case the execution may be considered a nonconsecutive execution). Optionally, a sequence of steps may be considered to correspond to an execution of a certain BP if it includes most of the steps involved in an execution of the certain BP. Optionally, a sequence of steps may be considered to correspond to an execution of a certain BP if it includes all of the steps involved in an execution of the certain BP.

Selecting sequences of steps from among one or more streams of steps may be done utilizing various approaches, as described in the discussion below.

In some embodiments in which steps are associated with identifiers of the executions to which they belong (e.g., case IDs), the sequence parser module 122 may involve a straightforward implementation in which steps from one or more streams are aggregated and sequences are generated by grouping together steps having the same execution identifier and optionally ordering the steps in each sequence (e.g., according to time stamps associated with the steps). In other embodiments, selecting sequences by the sequence parser module 122 may be done in other ways, as described below.

In other embodiments, selecting sequences may be done based on values of an Execution-Dependent Attribute (EDA). For example, the sequence parser module 122 may be configured to identify a value of the EDA, and at least some of the steps comprised in each selected sequence are associated with the same value of the EDA. Optionally, for at least some executions of a BP, steps belonging to the different executions are associated with different values of the same EDA. Some examples of the types of values to which the EDA may correspond include the following types of values: a mailing address, a Universal Resource Locator (URL) address, an Internet Protocol (IP) address, a phone number, an email address, a social security number, a driving license number, an address on a certain blockchain, an identifier of a digital wallet, an identifier of a client, an identifier of an employee, an identifier of a patient, an identifier of an account, and an order number.

In yet other embodiments, the sequence parser module 122 is configured to utilize a model to select, from among the streams, a plurality of sequences of steps. The model is trained based on a plurality of sequences corresponding to executions of a plurality of BPs. Thus, by receiving examples of sequences of steps corresponding to executions of various BPs, the model may be trained to identify properties of sequences that represent a complete execution of a “generic” BP. Optionally, the plurality of sequences used to generate the model comprise at least a first sequence corresponding to an execution of a first BP, which was executed on an instance of a certain software system belonging to a first organization, and a second sequence corresponding to an execution of a second BP, which was executed on an instance of the certain software system belonging to a second organization.

In still other embodiment, the sequence parser module 122 is configured to utilize links between pairs of steps belonging to the streams, and to utilize the links to select the sequences. Optionally, for each pair of consecutive steps in a sequence at least one of the following is true: the pair is a pair of consecutive steps in a stream from among the streams, and the pair is linked by at least one of the links. Utilization of this approach by the sequence parser module 122 is described in further detail in the discussion regarding embodiments illustrated in FIG. 17.

And in still other embodiments, the sequence parser module 122 is configured to identify occurrences of sequence seeds in the streams and to select the sequences by extending the sequence seeds. Optionally, a sequence seed comprises one or more consecutively performed steps from a certain stream. In one example, at least some of the sequence seeds are prefixes of sequences that may correspond to executions of one or more BPs. In this example, the sequence parser extends the seeds by adding additional steps, from the streams, to appear in the sequences after the prefixes. In another example, at least some of the sequence seeds are suffixes of sequences that correspond to executions of one or more BPs. In this example, the sequence parser extends the seeds by adding additional steps, from the streams, to appear in the sequences before the suffixes. In yet another example, at least some of the sequence seeds are prefixes of sequences that correspond to executions of one or more BPs and at least some of the sequence seeds are suffixes of sequences that correspond to executions of one or more BPs. In this example, the sequence parser module 122 may extend the seeds by adding, from the streams, additional steps to appear in the sequences between a prefix and a suffix. Utilization of this approach by the sequence parser module 122 is described in further detail in the discussion regarding embodiments illustrated in FIG. 19.

6—Models of BPs

Much of an organization's activity may involve execution of various Business Processes (BPs). Each execution of a BP may involve a sequence of related, structured activities and/or tasks, which may be represented as a sequence of steps, which produce a specific service and/or product to serve a particular goal of the organization. A BP may be described by one or more models of the BP.

Herein, a model of a BP may be used, in some embodiments, for at least one of the following purposes: (i) the model may serve as a template according to which the BP may be run (executed), and (ii) the model may be used to identify an execution of the BP (e.g., identify an execution of the BP in a sequence of steps obtained from monitoring). It is to be noted that while a model of a BP that is utilized as a template for running the BP can typically also be utilized to identify an execution of the BP (since it recites steps to be performed when running the BP), the converse is not necessarily true; some models described herein may be used to identify an execution of a BP, but cannot be easily utilized as a template for executing the BP.

There are various ways in which a model of a BP may be generated in embodiments described herein. In some embodiments, a model of a BP may be manually generated, e.g., users and/or experts may describe one or more sequences of steps that may be involved in the execution of the BP (e.g., the may describe one or more patterns mentioned below). Various modeling tools are known in the art, which may be utilized to generate a model for the BP utilizing on or more of various forms of notation. In some examples, a model of a BP may be specified using Business Process Modeling Notation (BPMN), which is a standardized graphical notation for drawing business processes in a workflow. BPMN was developed by the Business Process Management Initiative (BPMI), and is intended to serve as common language to bridge the communication gap that frequently occurs between business process design and implementation. In another example, a BP model may be described using the Web Services Business Process Execution Language OASIS Standard WS-BPEL 2.0, WS-BPEL (or “BPEL” for short), which is a language for specifying business process behavior, e.g., based on web services. Processes in BPEL can export and import functionality by using web service interfaces. In still another example, a model of a BP may be described via extensible markup language (XML). And in yet another example, a model of a BP may be described via a graphical representation (graph) such as a Petri net or a depiction of a BPMN model.

In other embodiments, a model of a BP may be automatically generated from documentation (e.g., utilizing various tool for process mapping and/or process discovery). Optionally, automated tool may be utilized to convert the documentation and/or model specified using an industry-standard notation or language (e.g., BPMN, BPEL, or XML, mentioned above) into a sequence of steps describing a sequence of operations to be executed by a user and/or a computer.

In addition to the approaches described above, or instead of them, in some embodiments, a model of a certain BP may be generated based on monitoring data. Generating the model of the certain BP based on monitoring data involves utilizing sequences of steps corresponding to executions of the BP, which are obtained from the monitoring data. In some embodiments, additional sequences of steps, which do not represent executions of the certain BP, can also be utilized to generate the model of the certain BP. Optionally, these sequences may serve as negative examples required for some of the learning procedures utilized for generating the model of the certain BP. In one example, the additional sequences may be sequences of steps corresponding to executions of other BPs (which are not the certain BP). In another example, the additional sequences may be sequences of steps that are unidentified. And in still another example, the additional sequences may include randomly selected steps from streams, randomly generated steps, and/or shuffled sequences of steps. Thus, the additional sequences may include steps utilized in executions of other BPs and even possibly steps included in executions of the certain BP, but not in the correct order.

There are many approaches known in the art for generating models from monitoring data. These approaches typically are based on mining event logs generated from interactions with instances of software systems. In recent years, several vendors released dedicated process mining tools (e.g., Celonis, Disco, EDS, Fujitsu, Minit, myInvenio, Perceptive, PPM, QPR, Rialto, and SNP). A comprehensive overview of some of the approaches that may be utilized for this task are given in Chapter 7 in van der Aalst, Wil. Process Mining: Data Science in Action. Springer, 2016.

There are various types of models that may be used to describe a BP. In some embodiments, a model of a BP may be considered to comprise one or more of the following: (i) a pattern describing one or more sequences of steps corresponding to executions of the BP (also referred to as a “pattern of the BP”), (ii) a graphical representation of one or more sequences of steps that correspond to an execution of the BP (e.g., a transition system, a Petri net, a BPMN model, or a UML model), (iii) an automaton that accepts sequences of steps corresponding to executions of the BP, and (iv) machine learning-based model that may be utilized to identify sequences of steps corresponding to executions of the BP.

A model that includes a pattern of a BP may be used to identify the BP as well, in some embodiments, serve as a template to execute the BP. Typically such a model is trained based on a set of sequences of steps corresponding to executions of the BP. A model that includes an automaton and/or a machine learning-based model may typically be used to identify executions of a BP. Parameters of an automaton are typically learned from positive and negative sets of sequences, which includes sequences corresponding to executions of the BP and sequences that do not correspond to executions of the BP. Similarly, a machine learning-based model is typically generated using positive and negative sets (as described above), when the machine learning model is utilized to determine whether a sequence of steps corresponds to an execution of a BP or not.

In some embodiments, the machine learning-based model may be a model of a classifier, in which case, it is typically trained based on multiple sets of sequences corresponding to multiple BPs (and optionally a set of sequences that do not correspond to an execution of a BP). In this case, the classifier is utilized to assign a sequence to a class from among multiple classes corresponding to the different BPs.

Following is a more detailed discussion some of the various types of models that may be used for a model of a BP. These types of models include: (i) patterns of sequences, (ii) graphical representation, (iii) automata, and (iv) machine learning-based models. Following is an explanation of some of the features of the different types of models.

(I) Patterns. A model of a BP may include a pattern describing a sequence of steps involved in the execution of the BP. Optionally, the pattern is represented by a regular expression that corresponds to the plurality of sequences (i.e., there are a plurality of different sequences that match the regular expression). Optionally, each of the steps in the sequence describes one or more operations that are to be performed as part of an interaction with an instance of a certain software system. For example, at least some of the steps may identify a transaction and/or operation to perform.

In one embodiment, a model of a BP comprising a pattern corresponding to the BP is generated based on sequences selected from among streams of steps performed during interactions with instances of one or more software systems. Each of these sequences comprises steps, from one or more of the streams, which are involved in an execution of the BP.

There may be different criteria that characterize, in embodiments described herein, the relationship between a pattern of a BP and the sequences upon which is was based. In one embodiment, each step belonging to the sequence described by the pattern is included in at least 50% of the sequences upon which the patterns is based. In another embodiment, each step belonging to the sequence described by the pattern is included in all of the sequences upon which the patterns is based. In yet another embodiment, an average of a distance between the sequence of steps described by the pattern and each of the sequences upon which the patterns is based is below a threshold.

In one example, the distance is based on a similarity between pairs of steps. Optionally, similarity between a pair of steps is determined based on one or more of the following values: identifiers of transactions executed in each step of the pair, identifiers of screens presented in each step of the pair, identifiers of fields accessed in each steps of the pair, identifiers of operations performed in each step of the pair, values entered in a certain field in each step of the pair, and values associated with returned system messages in each step of the pair.

In another example, the distance is computed utilizing a machine learning-based algorithm that is trained based on data comprising examples of similar sequences and examples of dissimilar sequences.

A pattern describing a BP may be utilized to identify executions of the BP in data obtained by monitoring interactions with instances of one or more software systems. In some embodiments, one or more candidate sequences of steps selected from among one or more streams of steps may be compared to the pattern in order to determine which (if any) of the candidate sequences corresponds to an execution of the BP. In one embodiment, a candidate sequence is considered an execution of the BP if it matches a sequence of steps described by the pattern. In other embodiments, an imperfect match between a candidate sequence and a sequence described by the pattern may suffice to identify a candidate sequence as corresponding to an execution of the BP. For example, if a distance between a candidate sequence and a sequence described by the patterns is below a threshold, the candidate sequence is identified as corresponding to an execution of the BP. Optionally, calculating the distance is done utilizing an alignment function.

It is to be noted that as typically presumed herein, when sequences of steps are compared, e.g., in order to calculate a distance between a pattern and a candidate sequence, the comparison typically involves comparison of a primary attribute of each step (which is typically the same in all performances of the step) and does not involve comparison of associated data (which is often different in different performances of the step). For example, a first sequence of steps includes steps that each describe a transaction that is executed (so together they describe a series of transaction). If a second sequence includes a similar number of steps describing the same series of transactions (i.e., the same order), then the first sequence may be considered to be similar to the second sequence (possibly there may be a distance of zero between the two). In some embodiments, these two sequences may even be considered to include the same steps. This being despite the fact that the steps in the first sequence may have different associated data than the steps belonging to the second sequence. For example, the steps in the first sequence may have different timestamps than the steps in the second sequence, or a step in the first sequence may have a first value for a certain EDA (e.g., a certain customer number), while the equivalent step in the second sequence may have a second value for the EDA (e.g., a different customer number). However, for the purpose of comparison, e.g., for determining whether both sequences are similar and/or whether both sequences correspond to executions of the same BP, the answer may be positive, despite the difference in the two sequences steps' associated data.

(II) Graphical representation. A model of a BP may be described via a graphical representation (graph) such as a Petri net or a depiction of a BPMN model. For example, Petri nets have a strong theoretical basis and can capture concurrency well. Thus, for example, a Petri net may describe situations in which some steps may be performed concurrently, so when written as a single sequence, may have an arbitrary order. An extension of Petri nets that may be used in some embodiments are Colored Petri nets (CPNs), which are the most widely used Petri-net based formalism that can deal with data-related and time-related aspects. Graphical representations of a model often offer a succinct overview of a BP for a human observer, who can grasp from the model the various execution paths and/or activities that may be involved in an execution of the BP.

In some embodiments, such a model may describe one or more paths of execution that correspond to executions of the BP. Optionally, each of the one or more paths may correspond to an execution of the BP that involves a possibly different sequence of steps. Optionally, each of the one or more paths may correspond to an execution of a different variant of the BP.

(III) Automata. A model of a BP may include parameters of an automaton that is configured to accept sequences of steps corresponding to executions of the BP. In one example, the automaton may be configured to identify sequences in which all the steps are involved in an execution of the BP. In another embodiment, the automaton may be configured to identify sequences of steps that include the steps involved in an execution of the BP, and possibly other steps too (e.g., steps involved in execution of another BP). In one example, the parameters of the automaton may include parameters describing the following elements: a finite set of states (Q), a finite set of symbols (the alphabet of the automaton E), a transition function (δ: Q× Σ →Q), a start state (q0), and a set of accepting states (F). Optionally, the parameters of the automaton describe a Deterministic Finite Automaton (DFA). Optionally, the parameters of the automaton describe a Nondeterministic Finite Automaton (NFA).

In one embodiment, parameters describing an automaton that accepts sequences corresponding to executions of a BP are generated based on a positive set of sequences and a negative set of sequences. Optionally, the positive and negative sets of sequences of steps comprise sequences selected from among streams of steps performed during interactions with instances of one or more software systems; most of the sequences in the positive set comprise executions of the BP and most of the sequences in the negative set do not comprise executions of the BP. Optionally, a sequence comprises an execution of a BP if it comprises all of the steps involved in the execution of the BP. The reference Cook, Jonathan E., and Alexander L. Wolf “Discovering models of software processes from event-based data”, in ACM Transactions on Software Engineering and Methodology (TOSEM) 7.3 (1998): 215-249, mentions some approaches for generating an automaton based on such positive and negative sets.

In one embodiment, a model of a BP comprising parameters of an automaton is utilized to identify executions of the BP. In one example, an execution of the automaton is simulated, when it is provided a candidate sequence as input. If the execution of the automaton reaches an accepting state, then the steps between the first step of the sequence and the step at which the accepting state is reached may be considered to include steps comprised in an execution of the BP. Depending on the implementation, the automaton may be fed individual candidate sequences or a stream of steps which may include many candidate sequences.

(IV) Machine Learning-based models. A model of a BP may include parameters of a machine learning-based model that may be utilized to identify executions of the BP. In these embodiments, a sequence of steps is converted to feature values (e.g., a vector of feature values) which represent properties of the sequence. Optionally, each feature represents a certain property of the sequence. In one example, the feature values representing a sequence of steps are indicative of one or more of the following: a certain transaction executed in one or more of the steps, a certain order of transactions executed in the steps, a certain screen presented in one or more of the steps, a certain order of screens presented in the steps, a certain field accessed in at least one of the steps, a certain order of accessing fields in one or more of the steps, a certain value entered in a field in at least one of the steps, a certain message received from a system as part of at least one of the steps. In another example, the feature values representing a sequence of steps are indicative of one or more of the following: the number of steps in the sequence, the duration it took to perform the steps in the sequence, an identity of a user who performed a step from among the steps, an identity of a system on which one of the steps was performed, an identity of an organization to which belongs a user who performed one of the steps, and an identity of an organization to which belongs a system on which one of the steps was performed.

In one embodiment, parameters machine learning-based model that may be utilized to identify executions of the BP are generated based on a training set generated based on a positive set of sequences and a negative set of sequences, utilizing one or more training algorithms. The positive set includes sequences of steps corresponding to executions of the BP and the negative set includes sequences of steps that do not correspond to executions of the BP (e.g., sequences of steps corresponding to executions of other BPs). Examples of training algorithms may include algorithms for learning parameters of: regression models, neural networks, support vector machines, decision trees, and other forms of classifiers. In another embodiment, multiple sets of sequences, each corresponding to executions of a certain BP from among multiple BPs, may be utilized to train a classifier. In this embodiment, the classifier may be used to classify a given sequence of steps to one or more classes, each class corresponding to executions of a BP from among the multiple BPs.

In one embodiment, a model of a BP comprising parameters of a machine learning-based model may be utilized to identify executions of the BP. In one example, a candidate sequence is converted to features values and provided to a module that utilizes the model to determine whether the candidate sequence corresponds to an execution of the BP or to which (if any) of multiple BPs the candidate sequence corresponds (e.g., in a case in which the machine learning-based model was for a classifier).

In some embodiments, a BP may be considered to be a compound BP, which is a BP that involves a plurality of subprocesses. Each subprocess involves performing one or more steps. In some embodiments, each subprocess may be considered a BP in its own right and be described by a model such as the models mentioned above (e.g., a pattern, an automaton, or a machine learning-based model). Thus, in some embodiments, a model of a compound BP may include a plurality of models of BPs corresponding to the subprocesses that may be part of the compound BP. Optionally, the model of the compound BP includes data describing an order of execution of at least some of the subprocesses. Optionally, the model of the compound BP describes a graph; paths in the graph represent different combinations (and orders) of executing subprocesses that make up the compound BP. Optionally, the graph may indicate that an order of execution of some subprocess may be arbitrary and/or that some of the subprocesses may be executed concurrently. The reference Conforti, et al. “BPMN Miner: Automated discovery of BPMN process models with hierarchical structure”, in Information Systems 56 (2016): 284-303, describes some approaches that may be utilized to discover models of compound BPs from monitoring data.

Is some embodiments, a BP may be considered to have different variants, each corresponding to a slightly different sequence of steps. Optionally, each variant of the BP may be described by a model of the variant, which may be any one of the models of a BP described above. Typically, the difference between sequences corresponding to executions of different variants of a BP is smaller than the difference between sequences corresponding to different BPs. In one example, the difference between a first and second variant of a BP may amount to one or more steps that are performed as part of executions of the first variant, and are not performed as part of executions of the second variant. Optionally, when using a distance function (e.g., an alignment based distance function), the average distance between pairs sequences of steps corresponding to executions of the same variant of a BP is smaller than the average distance between pairs of sequences of steps corresponding to executions of different variants of the BP.

Identifying different variants of a BP may be done using clustering of sequences of steps corresponding to executions of the BP, with each of the clusters comprising sequences corresponding to executions of a certain variant of the BP. Optionally, the number of clusters (variants) may be pre-selected and/or may be pre-determined based on the number of sequences being clustered. Optionally, the number of clusters may be determined based on various criteria known in the art, relying on various criteria known in the art such as criteria that are based on intra-cluster vs. inter-cluster distances.

In some embodiments, a model of a BP may be generated based primarily on sequences of steps corresponding to executions of the BP, which are associated with a certain organization. As such, the model may represent how the BP is executed at the certain organization (e.g., the model may correspond to certain variants used at the certain organization). However, in other embodiments, the model of the BP may be generated based on training data comprising a plurality of executions of the BP, which are associated with a plurality of organizations. For example, the plurality of executions of the BP comprises at least a first execution of the BP associates with a first organization and the second execution of the BP associated with a second organization that is different from the first organization. When a model is generated based on executions associated with multiple organizations, it may be considered a “crowd-based” model. A crowd-based model of the BP may capture various general aspects of how the BP is executed, which may be common for many organizations. Optionally, the crowd-based model of the BP may also reduce the influence of various organization-specific aspects of executing the BP, which for many organizations, are not part of executions the BP. Thus, crowd-based models sometimes have an advantage that they are general, and often suitable for detecting many variants of the BP that may be used in different organizations. This may be helpful when the model is provided to a new organization in order to detect executions of the BP in streams of steps generated from monitoring activity of the new organization. Using a general model of the BP may make it possible to identify executions of the BP associated with the new organization, even if the new organization's method of executing the BP does not accurately conform to any single organization's method of executing the BP (from among the organizations that contributed to the training set used to generate the model).

7—Additional Considerations

FIG. 25 is a schematic illustration of a computer 400 that is able to realize one or more of the embodiments discussed herein. The computer 400 may be implemented in various ways, such as, but not limited to, a server, a client, a personal computer, a set-top box (STB), a network device, a handheld device (e.g., a smartphone), and/or any other computer form capable of executing a set of computer instructions. Further, references to a computer include any collection of one or more computers that individually or jointly execute one or more sets of computer instructions utilized to perform any one or more of the disclosed embodiments.

The computer 400 includes one or more of the following components: processor 401, memory 402, computer readable medium 403, user interface 404, communication interface 405, and bus 406. In one example, the processor 401 may include one or more of the following components: a general-purpose processing device, a microprocessor, a central processing unit, a complex instruction set computing (CISC) microprocessor, a reduced instruction set computing (RISC) microprocessor, a very long instruction word (VLIW) microprocessor, a special-purpose processing device, an application specific integrated circuit (ASIC), a field programmable gate array (FPGA), a digital signal processor (DSP), a distributed processing entity, and/or a network processor. Continuing the example, the memory 402 may include one or more of the following memory components: CPU cache, main memory, read-only memory (ROM), dynamic random access memory (DRAM) such as synchronous DRAM (SDRAM), flash memory, static random access memory (SRAM), and/or a data storage device. The processor 401 and the one or more memory components may communicate with each other via a bus, such as bus 406.

Still continuing the example, the communication interface 405 may include one or more components for connecting to one or more of the following: LAN, Ethernet, intranet, the Internet, a fiber communication network, a wired communication network, and/or a wireless communication network. Optionally, the communication interface 405 is used to connect with the network 408. Additionally or alternatively, the communication interface 405 may be used to connect to other networks and/or other communication interfaces. Still continuing the example, the user interface 404 may include one or more of the following components: (i) an image generation device, such as a video display, an augmented reality system, a virtual reality system, and/or a mixed reality system, (ii) an audio generation device, such as one or more speakers, (iii) an input device, such as a keyboard, a mouse, a gesture based input device that may be active or passive, and/or a brain-computer interface.

Functionality of various embodiments may be implemented in hardware, software, firmware, or any combination thereof. If implemented at least in part in software, implementing the functionality may involve a computer program that includes one or more instructions or code stored or transmitted on a computer-readable medium and executed by one or more processors. Computer-readable media may include computer-readable storage media, which corresponds to a tangible medium such as data storage media, or communication media including any medium that facilitates transfer of a computer program from one place to another. Computer-readable medium may be any media that can be accessed by one or more computers to retrieve instructions, code and/or data structures for implementation of the described embodiments. A computer program product may include a computer-readable medium.

In one example, the computer-readable medium 403 may include one or more of the following: RAM, ROM, EEPROM, optical storage, magnetic storage, biologic storage, flash memory, or any other medium that can store computer readable data. Additionally, any connection is properly termed a computer-readable medium. For example, if instructions are transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of a medium. It should be understood, however, that computer-readable medium does not include connections, carrier waves, signals, or other transient media, but are instead directed to non-transient, tangible storage media.

A computer program (also known as a program, software, software application, script, program code, or code) can be written in any form of programming language, including compiled or interpreted languages, declarative or procedural languages. The program can be deployed in any form, including as a standalone program or as a module, component, subroutine, object, or another unit suitable for use in a computing environment. A computer program may correspond to a file in a file system, may be stored in a portion of a file that holds other programs or data, and/or may be stored in one or more files that may be dedicated to the program. A computer program may be deployed to be executed on one or more computers that are located at one or more sites that may be interconnected by a communication network.

Computer-readable medium may include a single medium and/or multiple media (e.g., a centralized or distributed database, and/or associated caches and servers) that store the one or more sets of instructions. In various embodiments, a computer program, and/or portions of a computer program, may be stored on a non-transitory computer-readable medium. The non-transitory computer-readable medium may be implemented, for example, via one or more of a volatile computer memory, a non-volatile memory, a hard drive, a flash drive, a magnetic data storage, an optical data storage, and/or any other type of tangible computer memory to be invented that is not transitory signals per se. The computer program may be updated on the non-transitory computer-readable medium and/or downloaded to the non-transitory computer-readable medium via a communication network such as the Internet. Optionally, the computer program may be downloaded from a central repository.

At least some of the methods described in this disclosure, which may also be referred to as “computer-implemented methods”, are implemented on a computer, such as the computer 400. When implementing a method from among the at least some of the methods, at least some of the steps belonging to the method are performed by the processor 401 by executing instructions. Additionally, at least some of the instructions for running methods described in this disclosure and/or for implementing systems described in this disclosure may be stored on a non-transitory computer-readable medium.

Some of the embodiments described herein include a number of modules. Modules may also be referred to herein as “components” or “functional units”. Additionally, modules and/or components may be referred to as being “computer executed” and/or “computer implemented”; this is indicative of the modules being implemented within the context of a computer system that typically includes a processor and memory. Generally, a module is a component of a system that performs certain operations towards the implementation of a certain functionality.

The following is a general comment about the use of reference numerals in this disclosure. It is to be noted that in this disclosure, as a general practice, the same reference numeral is used in different embodiments for a module when the module performs the same functionality (e.g., when given essentially the same type/format of data). Thus, as typically used herein, the same reference numeral may be used for a module that processes data even though the data may be collected in different ways and/or represent different things in different embodiments. For example, the reference numeral 126 is used to denote the BP-identifier module in various embodiments described herein. The functionality may be the essentially the same in each of the different embodiments—the BP-identifier module 126 identifies sequences of steps corresponding to executions of a BP; however, in each embodiment, the sequences that are evaluated may be different and/or a model used to evaluate the sequences may be different. For example, in one embodiment, the sequences may be based on interactions of users from a certain organization with instances of a certain software system, and in another embodiment, the sequences may be based on interactions of users from a plurality of organizations interacting with instances of more than one software system.

It is to be further noted that though the use of the convention described above that involves using the same reference numeral for modules is a general practice in this disclosure, it is not necessarily implemented with respect to all embodiments described herein. Modules referred to by different reference numerals may perform the same (or similar) functionality, and the fact that they are referred to in this disclosure by a different reference numeral does not necessarily mean that they might not have the same functionality.

Executing modules included in embodiments described in this disclosure typically involves hardware. For example, a computer system such as the computer system illustrated in FIG. 25 may be used to implement one or more modules. In another example, a module may comprise dedicated circuitry or logic that is permanently configured to perform certain operations (e.g., as a special-purpose processor, or an application-specific integrated circuit (ASIC)). Additionally or alternatively, a module may comprise programmable logic or circuitry (e.g., as encompassed within a general-purpose processor or a field programmable gate array (FPGA)) that is temporarily configured by software/firmware to perform certain operations.

In some embodiments, a processor implements a module by executing instructions that implement at least some of the functionality of the module. Optionally, a memory may store the instructions (e.g., as computer code), which are read and processed by the processor, causing the processor to perform at least some operations involved in implementing the functionality of the module. Additionally or alternatively, the memory may store data (e.g., measurements of affective response), which is read and processed by the processor in order to implement at least some of the functionality of the module. The memory may include one or more hardware elements that can store information that is accessible to a processor. In some cases, at least some of the memory may be considered part of the processor or on the same chip as the processor, while in other cases, the memory may be considered a separate physical element than the processor. Referring to FIG. 25 for example, one or more processors 401, may execute instructions stored in memory 402 (that may include one or more memory devices), which perform operations involved in implementing the functionality of a certain module.

The one or more processors 401 may also operate to support performance of the relevant operations in a “cloud computing” environment. Additionally or alternatively, some of the embodiments may be practiced in the form of a service, such as infrastructure as a service (IaaS), platform as a service (PaaS), software as a service (SaaS), and/or network as a service (NaaS). For example, at least some of the operations involved in implementing a module, may be performed by a group of computers accessible via a network (e.g., the Internet) and/or via one or more appropriate interfaces (e.g., application program interfaces (APIs)). Optionally, some of the modules may be executed in a distributed manner among multiple processors. The one or more processors 401 may be located in a single geographic location (e.g., within a home environment, an office environment, or a server farm), and/or distributed across a number of geographic locations. Optionally, some modules may involve execution of instructions on devices that belong to the users and/or are adjacent to the users. For example, procedures that involve data preprocessing and/or presentation of results may run, in part or in full, on processors belonging to devices of the users (e.g., smartphones and/or wearable computers). In this example, preprocessed data may further be uploaded to cloud-based servers for additional processing. Additionally, preprocessing and/or presentation of results for a user may be performed by a software agent that operates on behalf of the user.

In some embodiments, modules may provide information to other modules, and/or receive information from other modules. Accordingly, such modules may be regarded as being communicatively coupled. Where multiple of such modules exist contemporaneously, communications may be achieved through signal transmission (e.g., over appropriate circuits and buses). In embodiments in which modules are configured and/or instantiated at different times, communications between such modules may be achieved, for example, through the storage and retrieval of information in memory structures to which the multiple modules have access. For example, one module may perform an operation and store the output of that operation in a memory device to which it is communicatively coupled. A different module may then, at a later time, access the memory device to retrieve and process the stored output.

It is to be noted that in the claims, when a dependent system claim is formulated according to a structure similar to the following: “further comprising module X configured to do Y”, it is to be interpreted as: “the memory is further configured to store module X, the processor is further configured to execute module X, and module X is configured to do Y”.

Modules and other system elements (e.g., databases or models) are typically illustrated in figures in this disclosure as geometric shapes (e.g., rectangles) that may be connected via lines. A line between two shapes typically indicates a relationship between the two elements the shapes represent, such as a communication that involves an exchange of information and/or control signals between the two elements. This does not imply that in every embodiment there is such a relationship between the two elements, rather, it serves to illustrate that in some embodiments such a relationship may exist. Similarly, a directional connection (e.g., an arrow) between two shapes may indicate that, in some embodiments, the relationship between the two elements represented by the shapes is directional, according the direction of the arrow (e.g., one element provides the other with information). However, the use of an arrow does not indicate that the exchange of information between the elements cannot be in the reverse direction too.

The illustrations in this disclosure depict some, but not necessarily all, the connections between modules and/or other system element. Thus, for example, a lack of a line connecting between two elements does not necessarily imply that there is no relationship between the two elements, e.g., involving some form of communication between the two. Additionally, the depiction in an illustration of modules as separate entities is done to emphasize different functionalities of the modules. In some embodiments, modules that are illustrated and/or described as separate entities may in fact be implemented via the same software program, and in other embodiments, a module that is illustrates and/or described as being a single element may in fact be implemented via multiple programs and/or involve multiple hardware elements, possibly at different locations.

With respect to computer systems described herein, various possibilities may exist regarding how to describe systems implementing a similar functionality as a collection of modules. For example, what is described as a single module in one embodiment may be described in another embodiment utilizing more than one module. Such a decision on separation of a system into modules and/or on the nature of an interaction between modules may be guided by various considerations. One consideration, which may be relevant to some embodiments, involves how to clearly and logically partition a system into several components, each performing a certain functionality Thus, for example, hardware and/or software elements that are related to a certain functionality may belong to a single module. Another consideration that may be relevant for some embodiments, involves grouping hardware elements and/or software elements that are utilized in a certain location together. For example, elements that operate at the user end may belong to a single module, while other elements that operate on a server side may belong to a different module. Still another consideration, which may be relevant to some embodiments, involves grouping together hardware and/or software elements that operate together at a certain time and/or stage in the lifecycle of data.

As used herein, any reference to “one embodiment” or “an embodiment” means that a particular element, feature, structure, or characteristic described in connection with the embodiment is included in at least one embodiment. Moreover, separate references to “one embodiment” or “some embodiments” in this description do not necessarily refer to the same embodiment. Additionally, references to “one embodiment” and “another embodiment” may not necessarily refer to different embodiments, but may be terms used, at times, to illustrate different aspects of an embodiment. Similarly, references to “some embodiments” and “other embodiments” may refer, at times, to the same embodiments.

Herein, a predetermined value, such as a threshold, a predetermined rank, or a predetermined level, is a fixed value and/or a value determined any time before performing a calculation that compares a certain value with the predetermined value. Optionally, a first value may be considered a predetermined value when the logic (e.g., circuitry, computer code, and/or algorithm), used to compare a second value to the first value, is known before the computations used to perform the comparison are started.

Some embodiments may be described using the verb “indicating”, the adjective “indicative”, and/or using variations thereof. Herein, sentences in the form of “X is indicative of Y” mean that X includes information correlated with Y, up to the case where X equals Y. Additionally, sentences in the form of “provide/receive an indication indicating whether X happened” refer herein to any indication method, including but not limited to: sending/receiving a signal when X happened and not sending/receiving a signal when X did not happen, not sending/receiving a signal when X happened and sending/receiving a signal when X did not happen, and/or sending/receiving a first signal when X happened and sending/receiving a second signal X did not happen.

As used herein, the terms “comprises,” “comprising,” “includes,” “including,” “has,” “having”, or any other variation thereof, indicate an open claim language that does not exclude additional limitations. As used herein “a” or “an” are employed to describe “one or more”, and reference to an element in the singular is not intended to mean “one and only one” unless specifically so stated, but rather “one or more”. Additionally, the phrase “based on” is intended to mean “based, at least in part, on”. For example, stating that feature values are generated “based on a sequence” means that generation of at least some of the feature values may utilize, in addition to information derived from the sequence, additional data that is not in the sequence, such as contextual data that involves prior activity (e.g., execution of various BPs by an organization).

Though this disclosure in divided into sections having various titles, this partitioning is done just for the purpose of assisting the reader and is not meant to be limiting in any way. In particular, embodiments described in this disclosure may include elements, features, components, steps, and/or modules that may appear in various sections of this disclosure that have different titles. Furthermore, section numbering and/or location in the disclosure of subject matter are not to be interpreted as indicating order and/or importance. For example, a method may include steps described in sections having various numbers. These numbers and/or the relative location of the section in the disclosure are not to be interpreted in any way as indicating an order according to which the steps are to be performed when executing the method.

It is to be noted that essentially the same embodiments may be described in different ways. In one example, a first description of a computer system may include descriptions of modules used to implement it. A second description of essentially the same computer system may include a description of operations that a processor is configured to execute (which implement the functionality of the modules belonging to the first description). The operations recited in the second description may be viewed, in some cases, as corresponding to steps of a method that performs the functionality of the computer system. In another example, a first description of a computer-readable medium may include a description of computer code, which when executed on a processor performs operations corresponding to certain steps of a method. A second description of essentially the same computer-readable medium may include a description of modules that are to be implemented by a computer system having a processor that executes code stored on the computer-implemented medium. The modules described in the second description may be viewed, in some cases, as producing the same functionality as executing the operations corresponding to the certain steps of the method.

While the methods disclosed herein may be described and shown with reference to particular steps performed in a particular order, it is understood that these steps may be combined, sub-divided, and/or reordered to form an equivalent method without departing from the teachings of some of the embodiments. Accordingly, unless specifically indicated herein, the order and grouping of the steps is not a limitation of the embodiments. Furthermore, methods and mechanisms of some of the embodiments will sometimes be described in singular form for clarity. However, some embodiments may include multiple iterations of a method or multiple instantiations of a mechanism unless noted otherwise.

Embodiments described in conjunction with specific examples are presented by way of example, and not limitation. Moreover, it is evident that many alternatives, modifications, and variations will be apparent to those skilled in the art. It is to be understood that other embodiments may be utilized and structural changes may be made without departing from the scope of the appended claims and their equivalents.

We claim:

1. A system configured to utilize an automaton to identify a sequence corresponding to an execution of a Business Processes (BP), comprising:
memory configured to store computer executable modules; and
one or more processors configured to execute the computer executable modules; the computer executable modules comprising:
a monitoring agent configured to generate a stream of steps that were performed during interactions with an instance of a software system belonging to a certain organization; and
a simulation module configured to simulate a running of an automaton on an input comprising a sequence of steps;
wherein parameters that define a behavior of the automaton are generated based on previously identified sequences of steps corresponding to executions of the BP, which comprise at least first and second sequences that correspond to executions of the BP associated with first and second organizations, respectively;
wherein responsive to running the automaton on the stream, the automaton arrives at an accepting state at least once following a certain subsequence of steps, and the simulation module generates an indication indicative of a detection of an execution of the BP;
and wherein the certain subsequence corresponds to a nonconsecutive execution of the BP and comprises first, second, and third steps; the first step is performed before the second step, the second step is performed before the third step, the first and third step are involved in the execution of the BP, while the second step is not involved in the execution of the BP.

2. The system of claim 1, further comprising:
an example collector module configured to select a positive set comprising sequences of steps belonging to one or more streams of steps performed during interactions with instances of one or more software systems; wherein most of the sequences in the positive set correspond to executions of the BP; and wherein a sequence corresponds to an execution of the BP if it comprises all of the steps involved in an execution of the BP; and
an automaton generator module configured to generate an automaton based on the positive and set and a negative set of sequences; wherein most of the sequences in the negative set do not correspond to executions of the BP; and wherein the automaton recognizes most of the sequences belonging to the positive set and does not recognize most of the sequences belonging to the negative set.

3. The system of claim 2, wherein the negative set comprises sequences of steps corresponding to executions of BPs that are different from the BP.

4. The system of claim 1, wherein the simulation module is further configured to simulate the running of the automaton by sequentially evaluating the steps in the input, and performing a state transition following each evaluation of each step in the input; and wherein most steps in the stream, following evaluation of each step of the most of the steps, the automaton does not arrive at an accepting state.

5. The system of claim 1, wherein the first and third steps are both associated with a certain value of an execution-dependent attribute (EDA) and the second step is not associated with the certain value of the EDA; and wherein the EDA corresponds to one or more of the following types of values: a mailing address, a Universal Resource Locator (URL) address, an Internet Protocol (IP) address, a phone number, an email address, a social security number, a driving license number, an address on a certain blockchain, an identifier of a digital wallet, an identifier of a client, an identifier of an employee, an identifier of a patient, an identifier of an account, and an order number.

6. The system of claim 1, wherein an execution of a BP is associated with an organization if at least one of the following statements is true: (i) at least some steps involved in the execution of the BP are performed by a user belonging to the organization, and (ii) at least some steps involved in the execution of the BP are executed on a certain instance of a software system belonging to the organization.

7. The system of claim 1, wherein a step belonging to a stream comprising steps performed as part of an interaction with an instance of the software system describes one or more of the following: a certain transaction that is executed, a certain screen that is displayed during the interaction, a certain form that is accessed during the interaction, a certain field that is accessed during the interaction, a certain value entered in a field belonging to a form, a certain operation performed from within a form, and a certain message returned by the software system during the interaction or following the interaction.

8. The system of claim 1, further comprising a sequence parser module configured to select, from among the steps belonging to the stream, a plurality of sequences of steps; and wherein the simulation module is further configured to simulate the running of the automaton on each of the plurality of sequences.

9. A method for utilizing an automaton to identify a sequence corresponding to an execution of a Business Processes (BP), comprising:
monitoring interactions with an instance of a software system belonging to a certain organization and generating a stream of steps performed during the interactions;
simulating, by a system comprising a processor and memory, a running of an automaton on an input comprising the stream; wherein the automaton is configured to arrive at an accepting state following detection of an occurrence, in the input, of a subsequence corresponding to an execution of the BP; and wherein parameters that define a behavior of the automaton are generated based on previously identified sequences of steps corresponding to executions of the BP, which comprise at least first and second sequences that correspond to executions of the BP associated with first and second organizations, respectively; and
responsive to arrival at an accepting state following a certain subsequence of steps in the stream which corresponds to a nonconsecutive execution of the BP, generating an indication indicative of a detection of an execution of the BP; wherein the certain subsequence comprises first, second, and third steps; the first step is performed before the second step, the second step is performed before the third step, the first and third step are involved in the execution of the BP, while the second step is not involved in the execution of the BP.

10. The method of claim 9, further comprising:
selecting, by a system comprising a processor and memory, a positive set comprising sequences of steps belonging to one or more streams of steps performed during interactions with instances of one or more software systems; wherein most of the sequences in the positive set correspond to executions of the BP; and wherein a sequence corresponds to an execution of the BP if it comprises all of the steps involved in an execution of the BP;
receiving a negative set of sequences of steps; wherein most of the sequences in the negative set do not correspond to executions of the BP; and
generating the automaton based on the positive and negative sets; wherein the automaton recognizes most of the sequences belonging to the positive set and does not recognize most of the sequences belonging to the negative set.

11. The method of claim 10, further comprising:
receiving an indication indicative of steps in the one or more streams that are involved in a certain execution of the BP; and
selecting the steps involved in the certain execution from the one or more streams in order to form a that is added to the positive set.

12. The method of claim 9, further comprising:
selecting, from among the steps belonging to the stream, candidate sequences of steps; and
simulating the running of the automaton on each of the candidate sequences.

13. The method of claim 12, further comprising identifying values of an execution-dependent attribute (EDA) in at least some of the steps comprised in the stream and selecting the candidate sequences such that for each candidate sequence, the steps belonging to the candidate sequence are associated with the same value of the EDA; and wherein the EDA corresponds to one or more of the following types of values: a mailing address, a Universal Resource Locator (URL) address, an Internet Protocol (IP) address, a phone number, an email address, a social security number, a driving license number, an address on a certain blockchain, an identifier of a digital wallet, an identifier of a client, an identifier of an employee, an identifier of a patient, an identifier of an account, and an order number.

14. The method of claim 12, further comprising:
generating links between pairs of steps that are among steps belonging to the stream; wherein at least some of the links are between pairs of steps that are not consecutively performed steps in the same stream; and
selecting the candidate sequences utilizing the links; wherein for each pair of consecutive steps in a candidate sequence at least one of the following is true: the pair is a pair consecutive steps in a stream from among the streams, and the pair is linked by at least one of the links.

15. A non-transitory computer-readable medium having instructions stored thereon that, in response to execution by a system including a processor and memory, causes the system to perform steps comprising:
monitoring interactions with an instance of a software system belonging to a certain organization and generating a stream of steps performed during the interactions;
simulating a running of an automaton on an input comprising the stream; wherein the automaton is configured to arrive at an accepting state following detection of an occurrence, in the input, of a subsequence corresponding to an execution of a Business Process (BP); and wherein parameters that define a behavior of the automaton are generated based on previously identified sequences of steps corresponding to executions of the BP, which comprise at least first and second sequences that correspond to executions of the BP associated with first and second organizations, respectively; and
responsive to arrival at an accepting state following a certain subsequence of steps in the stream which corresponds to a nonconsecutive execution of the BP, generating an indication indicative of a detection of an execution of the BP; wherein the certain subsequence comprises first, second, and third steps; the first step is performed before the second step, the second step is performed before the third step, the first and third step are involved in the execution of the BP, while the second step is not involved in the execution of the BP.

16. The non-transitory computer-readable medium of claim 15, further comprising instructions defining the following steps:
selecting, by a system comprising a processor and memory, a positive set comprising sequences of steps belonging to one or more streams of steps performed during interactions with instances of one or more software systems; wherein most of the sequences in the positive set correspond to executions of the BP; and wherein a sequence corresponds to an execution of the BP if it comprises all of the steps involved in an execution of the BP;
receiving a negative set of sequences of steps; wherein most of the sequences in the negative set do not correspond to executions of the BP; and
generating the automaton based on the positive and negative sets; wherein the automaton recognizes most of the sequences belonging to the positive set and does not recognize most of the sequences belonging to the negative set.

17. The non-transitory computer-readable medium of claim 16, further comprising instructions defining the following steps:
receiving an indication indicative of steps in the one or more streams that are involved in a certain execution of the BP; and
selecting the steps involved in the certain execution from the one or more streams in order to form a that is added to the positive set.

18. The non-transitory computer-readable medium of claim 15, further comprising instructions defining the following steps:
selecting, from among the steps belonging to the stream, candidate sequences of steps; and
simulating the running of the automaton on each of the candidate sequences.

19. The non-transitory computer-readable medium of claim 18, further comprising instructions defining a step of identifying values of an execution-dependent attribute (EDA) in at least some of the steps comprised in the stream and selecting the candidate sequences such that for each candidate sequence, the steps belonging to the candidate sequence are associated with the same value of the EDA; wherein the EDA corresponds to one or more of the following types of values: a mailing address, a Universal Resource Locator (URL) address, an Internet Protocol (IP) address, a phone number, an email address, a social security number, a driving license number, an address on a certain blockchain, an identifier of a digital wallet, an identifier of a client, an identifier of an employee, an identifier of a patient, an identifier of an account, and an order number.

20. The non-transitory computer-readable medium of claim 18, further comprising instructions defining the following steps:
generating links between pairs of steps that are among steps belonging to the stream; wherein at least some of the links are between pairs of steps that are not consecutively performed steps in the same stream; and
selecting the candidate sequences utilizing the links; wherein for each pair of consecutive steps in a candidate sequence at least one of the following is true: the pair is a pair consecutive steps in a stream from among the streams, and the pair is linked by at least one of the links.
